(19) United States
(12) Patent Application Publication
(10) Pub. No.: US 2014/0336392 A1
(43) Pub. Date: Nov. 13, 2014

(54) NOVEL ORGANIC ELECTROLUMINESCENT COMPOUNDS AND ORGANIC ELECTROLUMINESCENT DEVICE USING THE SAME

(71) Applicant: Rohm and Haas Electronic Materials Korea Ltd., Chungcheongnam-do (KR)

(72) Inventors: Young-Gil Kim, Gyeonggi-do (KR); Young-Jun Cho, Gyeonggi-do (KR); So-Mi Park, Gyeonggi-do (KR); Hyuck-Joo Kwon, Seoul (KR); Kyung-Joo Lee, Seoul (KR); Bong-Ok Kim, Seoul (KR)

(21) Appl. No.: 14/363,301

(22) PCT Filed: Dec. 4, 2012
(86) PCT No.: PCT/KR2012/010412

§ 371 Date: Jun. 5, 2014

(30) Foreign Application Priority Data
Dec. 5, 2011 (KR) 10-2011-0128935

(51) Int. Cl. H01L 51/00

(52) U.S. Cl. CPC H01L 51/0054; H01L 51/0072; H01L 51/5012
USPC 548/440

(57) ABSTRACT

The present invention relates to a novel organic electroluminescent compound and an organic electroluminescent device containing the same. Using the organic electroluminescent compounds of the present invention, it is possible to manufacture an OLED device with a long operating lifespan and high luminous efficiency. In addition, the compounds can improve the power efficiency of the device and reduce overall power consumption.

### TECHNICAL FIELD The present invention relates to novel organic electroluminescent compounds and organic electroluminescent device using the same.

### BACKGROUND ART

An electroluminescent (EL) device is a self-light-emitting device which has advantages over other types of display devices in that it provides a wider viewing angle, a greater contrast ratio, and a faster response time. An organic EL device was first developed by Eastman Kodak, by using small aromatic diamine molecules, and aluminum complexes as materials for forming a light-emitting layer [Appl. Phys. Lett. 51, 913, 1987].

The most important factor determining luminous efficiency in an organic EL device is the light-emitting material. Until now, fluorescent materials have been widely used as a light-emitting material. However, in view of electroluminescent mechanisms, since phosphorescent materials theoretically enhance luminous efficiency by four (4) times compared to fluorescent materials, development of phosphorescent light-emitting materials are widely being researched. Indium(III) complexes have been widely known as phosphorescent materials, including bis(2-(2′-benzothienyl)-pyridinato-N,C3′)iridium(acetylacetonate) ((acac)Ir(btp)₂), tris(2-phenylpyridine)iridium (Ir(ppy)₃) and bis(4,6-difluorophenylpyridinato-N,C2)picolinate iridium (Firpic) as red, green and blue materials, respectively.

Until now, 4,4′-N,N′-dicarbazol-biphenyl (CBP) was the most widely known host material for phosphorescent substances in conventional technologies. Further, an organic EL device using bathocuproine (BCP) and aluminum(III)bis(2-methyl-8-quinolinate)(4-phenylphenolate) (BAIq) for a hole blocking layer is also known, and Pioneer (Japan) et al. developed a high performance organic EL device employing a derivative of BAIq as a host material.

Though these materials provide good light-emitting characteristics, they have the following disadvantages: (1) Due to their low glass transition temperature and poor thermal stability, degradation may occur during a high-temperature deposition process in a vacuum. (2) The power efficiency of an organic EL device is given by [(Tr/voltage) x current efficiency], and power efficiency is inversely proportional to voltage. An organic EL device comprising phosphorescent host materials provides a higher current efficiency (cd/A) than one comprising fluorescent materials. However, it has a higher driving voltage, and thus, there is less advantages in terms of power efficiency (Im/W). (3) Further, the operating lifespan of the organic EL device is short, and luminous efficiency still needs improvement.

International Patent Publication No. WO 2011/081423 discloses a carbazole compound substituted with a triphenylene group and a fluorene group. However, the compound requires high driving voltage, and so is not suitable for commercialization.

### DISCLOSURE OF THE INVENTION

### Technical Problem

The objective of the present invention is to provide an organic electroluminescent compound imparting high luminous efficiency and a long operating lifespan to a device, and having suitable color coordinate; and an organic electroluminescent device having high efficiency and a long lifespan, using said compound as a light-emitting material.

### Solution to Problem

The present inventors found that the objective above is achievable by an organic electroluminescent compound represented by the following formula 1:

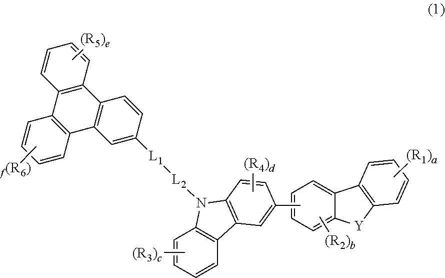

wherein

L₁ and L₂ each independently represent a single bond, a substituted or unsubstituted 3- to 30-membered heteroarylene group, or a substituted or unsubstituted (C6-C30)arylene group, provided that L₁ and L₂ are not simultaneously single bonds;

Y represents —O—, —S—, —CR₇R₈— or —NR₉—;

R₁ to R₉ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, a (C6-C30)cycloalkyl group fused with one or more aromatic rings, —NR₁₀R₁₁, —SR₁₂, —OR₁₃ or —SiR₁₄R₁₅R₁₆;

R₁₀ to R₁₆ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group;

a, c, e and f each independently represent an integer of 1 to 4; where a, c, e and f are integers of 2 or more, each of R₁, R₃, R₅ and R₆ is the same or different;

b and d each independently represent an integer of 1 to 3; where b and d are integers of 2 or more, each of R₂ and R₄ is the same or different; and

the heterocycloalkyl group, the heteroarylene group and the heteroaryl group contain at least one hetero atom selected from B, N, O, S, P(═O), Si and P.

### ADVANTAGEOUS EFFECTS OF INVENTION

The organic electroluminescent compounds according to the present invention have high luminous efficiency and good lifespan characteristics, and thus could provide an organic electroluminescent device having long operating lifespan.

In addition, the present invention makes it possible to manufacture a device free from crystallization since the organic electroluminescent compounds used in the present invention are highly efficient in transporting electrons. Further, the compounds have good layer formability and improve the current characteristics of the device. Therefore, it is possible to produce an organic electroluminescent device having lowered driving voltages and enhanced power efficiency.

### MODE FOR THE INVENTION

Hereinafter, the present invention will be described in detail. However, the following description is intended to explain the invention, and is not meant in any way to restrict the scope of the invention.

The present invention relates to an organic electroluminescent compound represented by formula 1, above, an organic electroluminescent material comprising the compound, and an organic electroluminescent device comprising the material.

Hereinafter, The organic electroluminescent compound represented by the above formula 1 will be described in detail.

Herein, “alkyl” includes methyl, ethyl, n-propyl, isopropyl, n-butyl, isobutyl, tert-butyl, etc.; “alkenyl” includes vinyl, 1-propenyl, 2-propenyl, 1-butenyl, 2-butenyl, 3-butenyl, 2-methylbut-2-enyl, etc.; “alkynyl” includes ethynyl, 1-propynyl, 2-propynyl, 1-butynyl, 2-butynyl, 3-butynyl, 1-methylpent-2-ynyl, etc.; “cycloalkyl” includes cyclopropyl, cyclobutyl, cyclopentyl, cyclohexyl, etc.; “5- to 7-membered heterocycloalkyl” is a cycloalkyl having at least one heteroatom selected from B, N, O, S, P(═O), Si and P, preferably O, S and N, and 5 to 7 ring backbone atoms, and includes tetrahydrofuran, pyrrolidine, thiolan, tetrahydropyran, etc.; “aryl(ene)” is a monocyclic or fused ring derived from an (C6-C30)aromatic hydrocarbon, and includes phenyl, biphenyl, terphenyl, naphthyl, binaphthyl, phenyl naphthyl, naphthyl phenyl, fluorenyl, phenyl fluorenyl, benzofluorenyl, dibenzofluorenyl, phenanthrenyl, phenyl phenanthrenyl, anthracenyl, indenyl, triphenylenyl, pyrenyl, tetracenyl, perylenyl, chrysenyl, naphthacenyl, fluoranthenyl, etc.; “3- to 30-membered heteroaryl(ene)” is an aryl group having at least one, preferably 1 to 4 heteroatom selected from the group consisting of B, N, O, S, P(═O), Si and P, and 3 to 30 ring backbone atoms; is a monocyclic ring, or a fused ring condensed with at least one benzene ring; may be partially saturated; may be one formed by linking at least one heteroaryl or aryl group to a heteroaryl group via a single bond(s); and includes a monocyclic ring-type heteroaryl including furyl, thiophenyl, pyrrolyl, imidazolyl, pyrazolyl, thiazolyl, thiadiazolyl, isothiazolyl, isoxazolyl, oxazolyl, oxadiazolyl, triazinyl, tetrazinyl, triazolyl, tetrazolyl, furazanyl, pyridyl, pyrazinyl, pyrimidinyl, pyridazinyl, etc., and a fused ring-type heteroaryl including benzofuranyl, benzothiophenyl, isobenzofuranyl, dibenzofuranyl, dibenzothiophenyl, benzoimidazolyl, benzothiazolyl, benzoisothiazolyl, benzoisoxazolyl, benzoxazolyl, isoindolyl, indolyl, indazolyl, benzothiadiazolyl, quinolyl, isoquinolyl, cinnolinyl, quinazolinyl, quinoxalinyl, carbazolyl, phenoxazinyl, phenanthridinyl, benzodioxolyl, etc. Further, “Halogen” includes F, Cl, Br and I.

Herein, “substituted” in the expression “substituted or unsubstituted” means that a hydrogen atom in a certain functional group is replaced with another atom or group, i.e., a substituent.

The aryl(ene), heteroaryl(ene), alkyl, cycloalkyl, heterocycloalkyl, arylamino, trialkylsilyl and triarylsilyl groups in L₁, L₂, and R₁ to R₁₆ of formula 1, can be further substituted with at least one selected from the group consisting of: deuterium; a halogen; a (C1-C30)alkyl group substituted or unsubstituted with a halogen; a (C6-C30)aryl group substituted or unsubstituted with a halogen; a 3- to 30-membered heteroaryl group substituted or unsubstituted with a (C1-C30)alkyl or a (C6-C30)aryl; a (C3-C30)cycloalkyl group; a (C6-C30)cycloalkyl group fused with one or more aromatic rings; a 5- to 7-membered heterocycloalkyl group; RₐR_{b}R_{c}Si—; a carbazolyl group; —NR_{d}Rₑ; —BR_{f}R_{g}; —PRₕRᵢ; —P(═O)RⱼRₖ; a (C6-C30)aryl(C1-C30)alkyl group; a (C1-C30)alkyl(C6-C30)aryl group; a (C1-C30)alkoxy group; and a (C6-C30)aryloxy group, wherein Rₐ to Rₖ each independently represent a (C1-C30)alkyl group, a (C6-C30)aryl group, or a 3- to 30-membered heteroaryl group, preferably are at least one selected from the group consisting of deuterium, a halogen, a (C1-C10)alkyl group, a (C6-C20)aryl group, a halo(C6-C20)aryl group, and a 5- to 20-membered heteroaryl group, more preferably are at least one selected from the group consisting of deuterium, a halogen, a (C1-C6)alkyl group, a (C6-C12)aryl group, a halo(C6-C12)aryl group, and a 5- to 12-membered heteroaryl group.

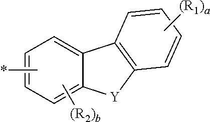

The moiety, in formula 1, above, is selected from the following structures, but not limited thereto:

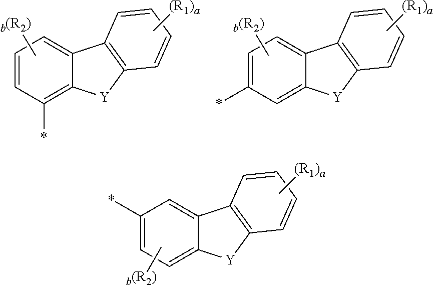

wherein R₁, R₂, Y, a and b are as defined in formula 1.

In formula 1, above, L₁ and L₂ each independently represent a single bond, a substituted or unsubstituted 3- to 30-membered heteroarylene group, or a substituted or unsubstituted (C6-C30)arylene group, provided that L₁ and L₂ are not simultaneously single bonds, preferably a single bond, a substituted or unsubstituted 5- to 20-membered heteroarylene group, or a substituted or unsubstituted (C6-C20)arylene group, more preferably a single bond; a 5- to 12-membered heteroarylene group unsubstituted or substituted with a (C6-C12)aryl group or a halo(C6-C12)aryl group; or a (C6-C10)arylene group unsubstituted or substituted with a (C1-C6)alkyl group or a 5- to 12-membered heteroaryl group.

Y represents —O—, —S—, —CR₇R₈— or —NR₉—;

R₁ to R₉ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, a (C6-C30)cycloalkyl group fused with one or more aromatic rings, —NR₁₀R₁₁, —SR₁₂, —OR₁₃ or —SiR₁₄R₁₅R₁₆, preferably hydrogen, a halogen, a substituted or unsubstituted (C1-C10)alkyl group, a substituted or unsubstituted (C6-C20)aryl group, or a substituted or unsubstituted 5- to 20-membered heteroaryl group, more preferably hydrogen; a halogen; an unsubstituted (C1-C6)alkyl group; a (C6-C10)aryl group unsubstituted or substituted with deuterium; or an unsubstituted 5- to 10-membered heteroaryl group.

R₁₀ to R₁₆ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group.

According to one embodiment of the present invention in formula 1 above, L₁ and L₂ each independently represent a single bond, a substituted or unsubstituted 5- to 20-membered heteroarylene group, or a substituted or unsubstituted (C6-C20)arylene group, provided that L₁ and L₂ are not simultaneously single bonds; Y represents —O—, —S—, —CR₇R₈— or —NR₉−; R₁ to R₉ each independently represent hydrogen, a halogen, a substituted or unsubstituted (C6-C10)alkyl group, a substituted or unsubstituted (C6-C20)aryl group, or a substituted or unsubstituted 5- to 20-membered heteroaryl group.

According to another embodiment of the present invention in formula 1 above, L₁ and L₂ each independently represent a single bond; a 5- to 12-membered heteroarylene group unsubstituted or substituted with a (C6-C12)aryl group or a halo(C6-C12)aryl group; or a (C6-C10)arylene group unsubstituted or substituted with a (C1-C6)alkyl group or a 5- to 12-membered heteroaryl group, provided that L₁ and L₂ are not simultaneously single bonds, Y represents —O—, —S—, —CR₇R₈— or —NR₉—, R₁ to R₉ each independently represent hydrogen; a halogen; an unsubstituted (C1-C6)alkyl group; a (C6-C10)aryl group unsubstituted or substituted with deuterium; or an unsubstituted 5- to 10-membered heteroaryl group.

Specifically, L₁ and L₂ can each independently represent a single bond, a substituted or unsubstituted 3- to 30-membered heteroarylene group, or a substituted or unsubstituted (C6-C30)arylene group, provided that L₁ and L₂ are not simultaneously single bonds; Y represents —O—, —S—, —CR₇R₈— or —NR₉—; R₁ to R₉ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group; and the heteroarylene and arylene groups in L₁ and L₂, and the alkyl, aryl and heteroaryl groups in R₁ to R₉ can be further substituted with at least one selected from the group consisting of deuterium; a halogen; a (C1-C30)alkyl group substituted or unsubstituted with a halogen; a (C6-C30)aryl group substituted or unsubstituted with a halogen; a 3- to 30-membered heteroaryl group substituted or unsubstituted with a (C1-C30)alkyl or a (C6-C30)aryl; a (C6-C30)aryl(C1-C30)alkyl group; and a (C1-C30)alkyl(C6-C30)aryl group.

More specifically, L₁ can represent a single bond, a phenylene, a biphenylene, a terphenylene, a fluorenylene, a triphenylenylene, a pyrenylene, a perylenylene, a fluoranthenylene, a thiophenylene, a pyrrolylene, a pyrazolylene, a thiazolylene, an oxazolylene, an oxadiazolylene, a triazinylene, a tetrazinylene, a triazolylene, a furazanylene, a pyridylene, a pyrimidylene, a quinolylene, an isoquinolylene, a quinazolylene, a benzofuranylene, a benzothiophenylene, an indolylene, a benzoimidazolylene, a benzothiazolylene, a benzoisothiazolylene, a benzoisoxazolylene, a benzoxazolylene, a benzothiadiazolylene, a dibenzofuranylene or a dibenzothiophenylene, provided that L₁ and L₂ are not simultaneously single bonds; R₁ to R₉ each independently represent: hydrogen, deuterium, a fluorine, a methyl, an ethyl, an n-propyl, an i-propyl, an n-butyl, an i-butyl, a t-butyl, an n-pentyl, an i-pentyl, an n-hexyl, an n-heptyl, an n-octyl, a 2-ethylhexyl, an n-nonyl, a decyl, a dodecyl, a hexadecyl, a trifluoromethyl, a perfluoroethyl, a trifluoroethyl, a perfluoropropyl, a perfluorobutyl, a phenyl, a biphenyl, a fluorenyl, a fluoranthenyl, a triphenylenyl, a pyrenyl, a chrysenyl, a naphthacenyl, a perylenyl, a pyridyl, a pyrrolyl, a furanyl, a thiophenyl, an imidazolyl, a benzoimidazolyl, an indenyl, a pyrazinyl, a pyrimidyl, a pyridazinyl, a quinolyl, an isoquinolyl, a triazinyl, a benzofuranyl, a dibenzofuranyl, a benzothiophenyl, a dibenzothiophenyl, a pyrazolyl, an indolyl, a carbazolyl, a thiazolyl, an oxazolyl, a benzothiazolyl, a benzoxazolyl, a phenanthrolinyl, or an N-carbazolyl; and the substituents in L₁, L₂ and R₁ to R₉ can be further substituted with at least one selected from the group consisting of: deuterium, a chlorine, a fluorine, a methyl, an ethyl, an n-propyl, an i-propyl, an n-butyl, an i-butyl, a t-butyl, an n-pentyl, an i-pentyl, an n-hexyl, an n-heptyl, an n-octyl, a 2-ethylhexyl, an n-nonyl, a decyl, a dodecyl, a hexadecyl, a trifluoromethyl, a perfluoroethyl, a trifluoroethyl, a perfluoropropyl, a perfluorobutyl, a phenyl, a biphenyl, a fluorenyl, a 9,9-dimethylfluorenyl, a fluoranthenyl, a triphenylenyl, a fluorophenyl, a difluorophenyl, a trifluorophenyl, a tetrafluorophenyl, a pentafluorophenyl, a pyridyl, a pyrimidyl, a benzothiophenyl, an imidazolyl, a benzothiazolyl, a benzoimidazolyl, a pyrenyl, a perylenyl, a quinolyl and an isoquinolyl.

The representative organic electroluminescent compounds of the present invention include the following compounds, but not limited thereto:

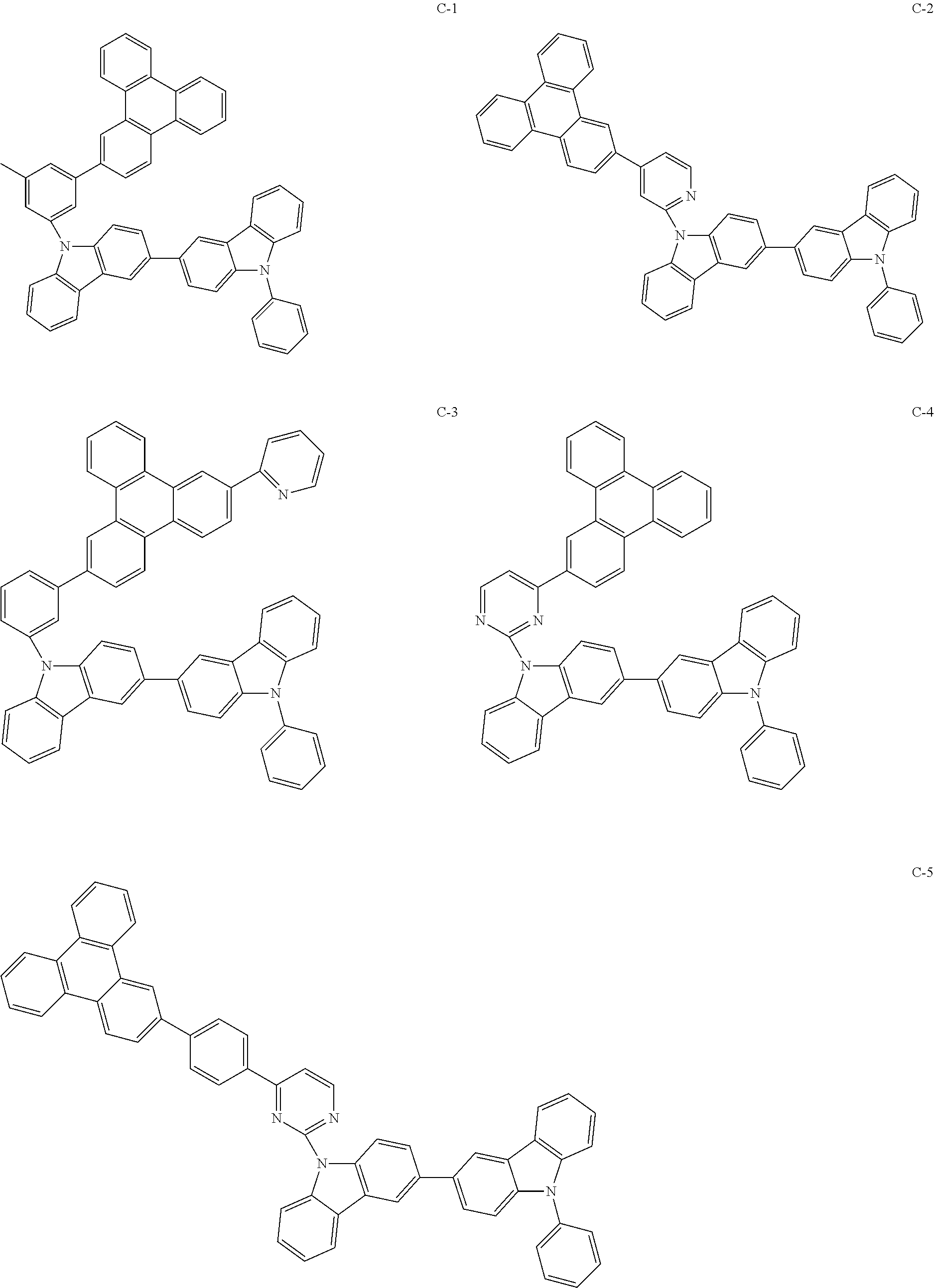 [SMILES: Cc1cc(-c2ccc3c4ccccc4c4ccccc4c3c2)cc(-n2c3ccccc3c3cc(-c4ccc5c(c4)c4ccccc4n5-c4ccccc4)ccc32)c1 ; c1ccc(-n2c3ccccc3c3cc(-c4ccc5c(c4)c4ccccc4n5-c4cc(-c5ccc6c7ccccc7c7ccccc7c6c5)ccn4)ccc32)cc1 ; c1ccc(-n2c3ccccc3c3cc(-c4ccc5c(c4)c4ccccc4n5-c4cccc(-c5ccc6c7ccc(-c8ccccn8)cc7c7ccccc7c6c5)c4)ccc32)cc1 ; c1ccc(-n2c3ccccc3c3cc(-c4ccc5c(c4)c4ccccc4n5-c4nccc(-c5ccc6c7ccccc7c7ccccc7c6c5)n4)ccc32)cc1 ; c1ccc(-n2c3ccccc3c3cc(-c4ccc5c(c4)c4ccccc4n5-c4nccc(-c5ccc(-c6ccc7c8ccccc8c8ccccc8c7c6)cc5)n4)ccc32)cc1]

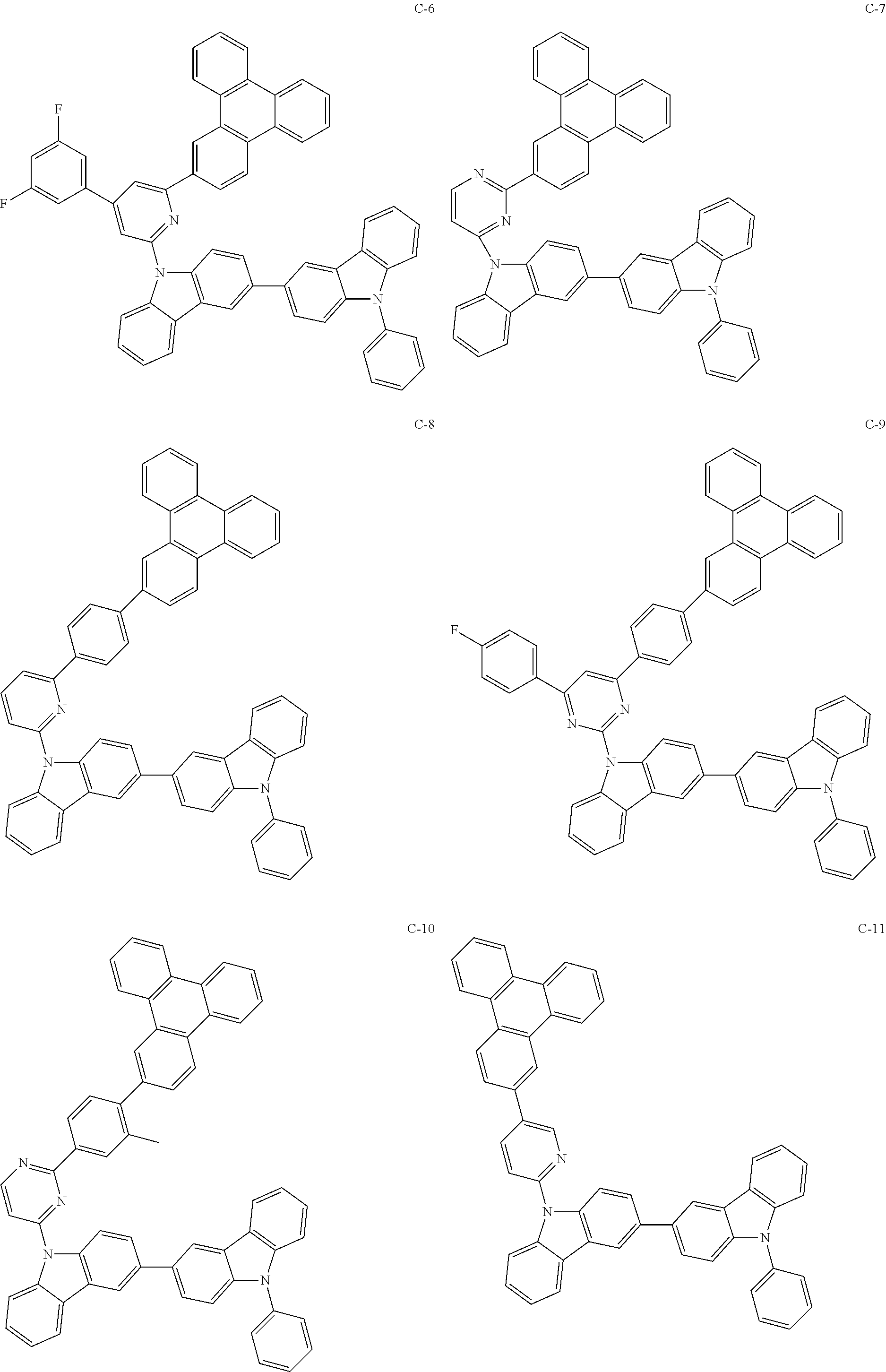

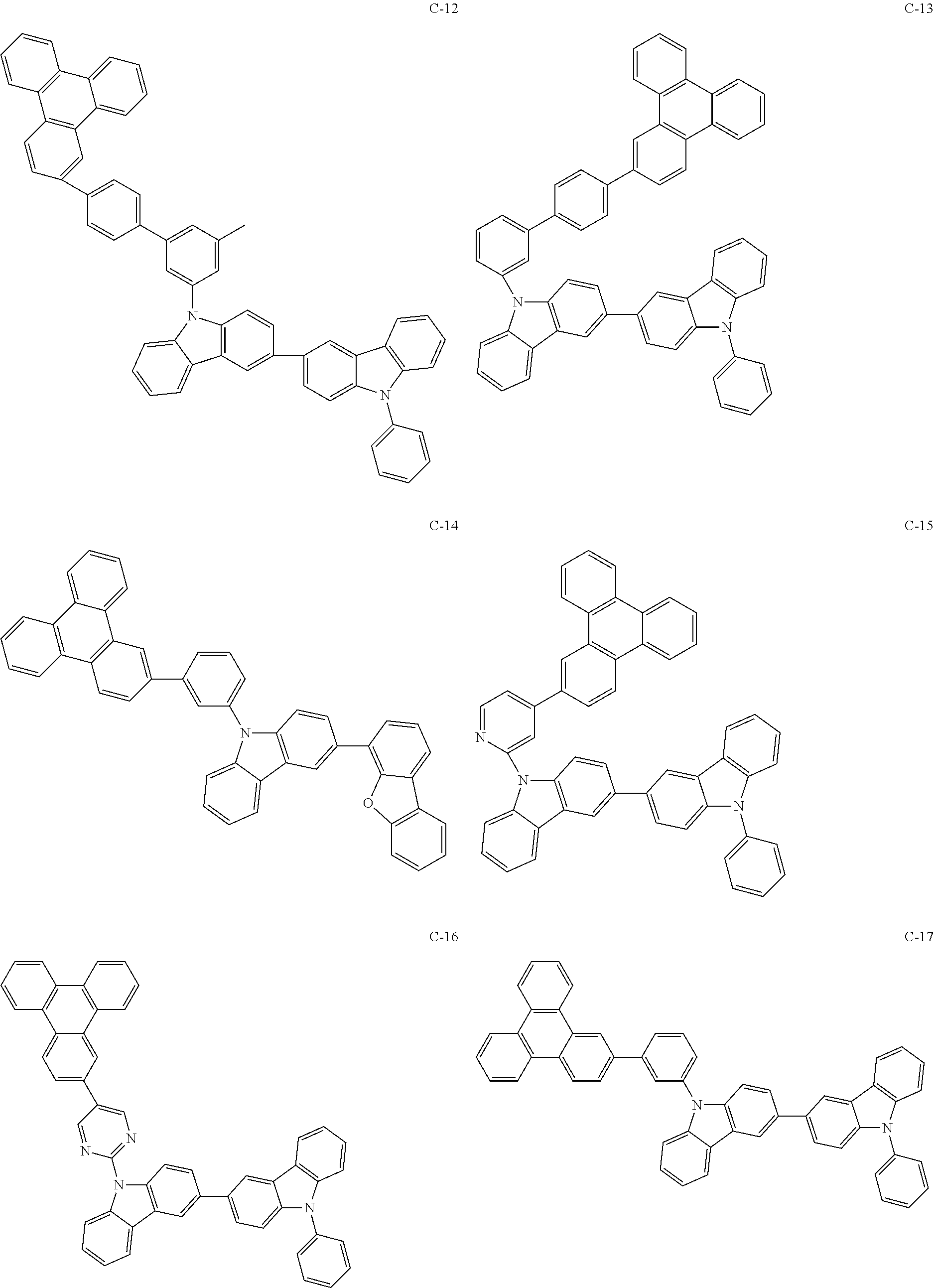

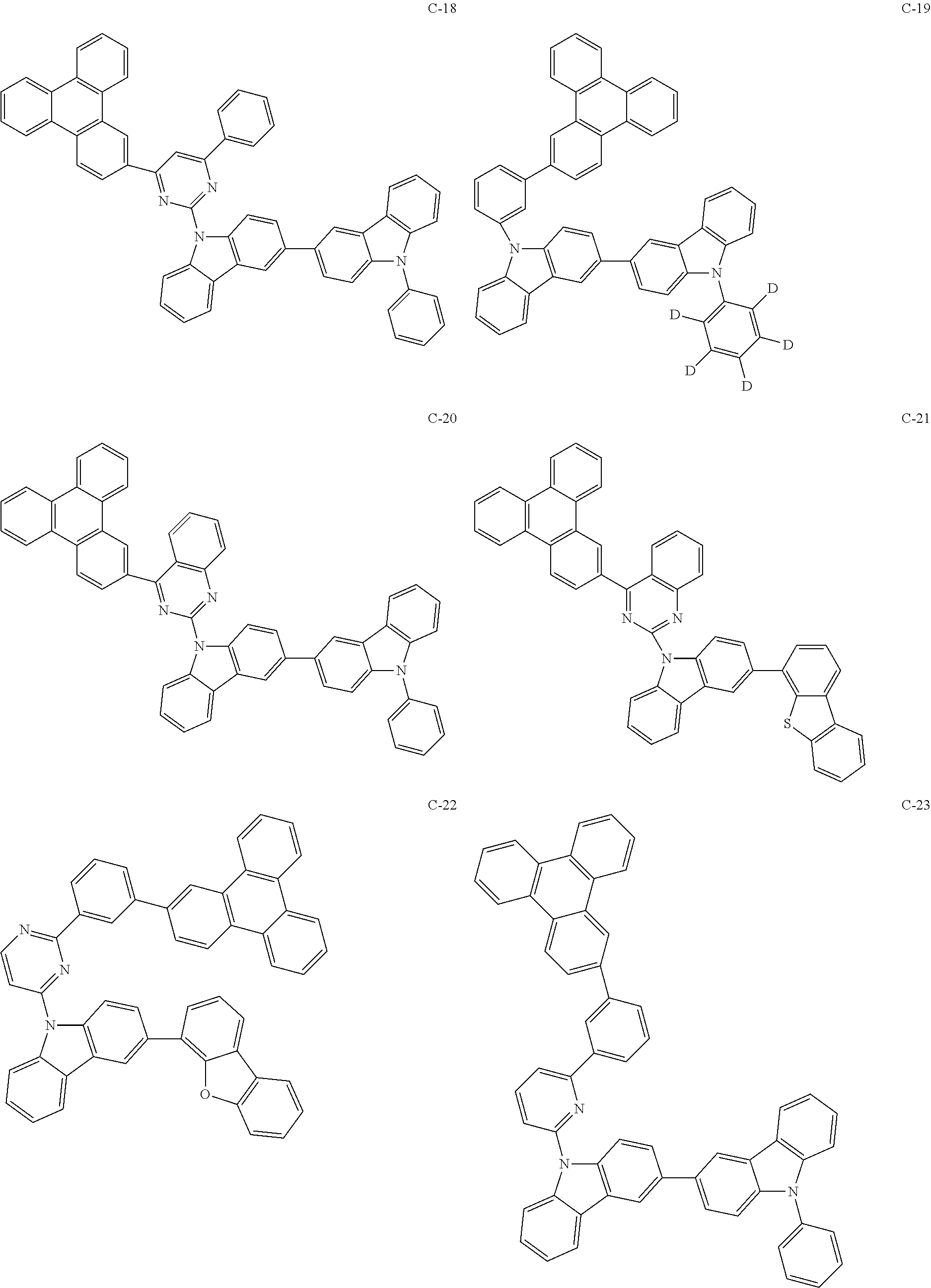

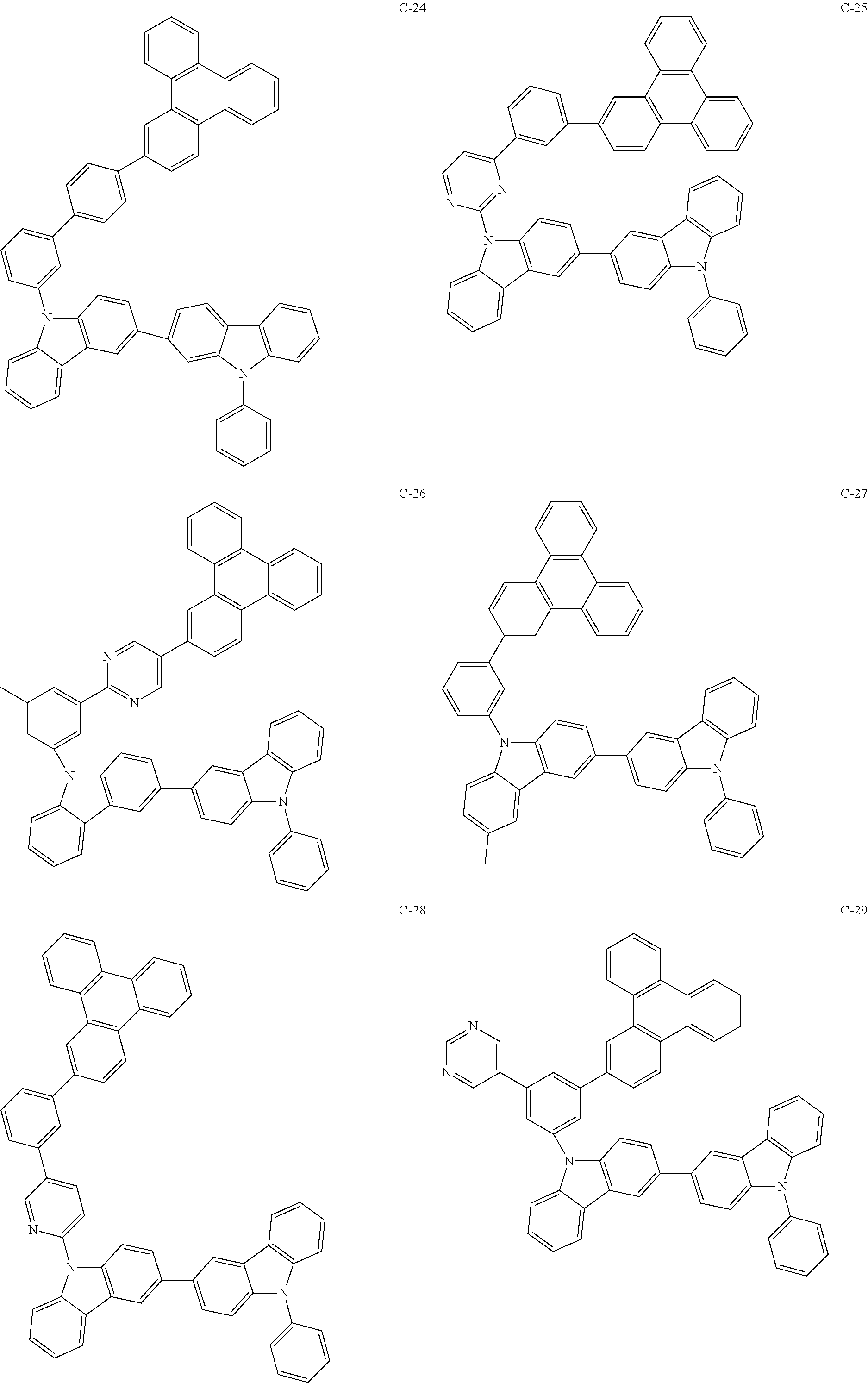

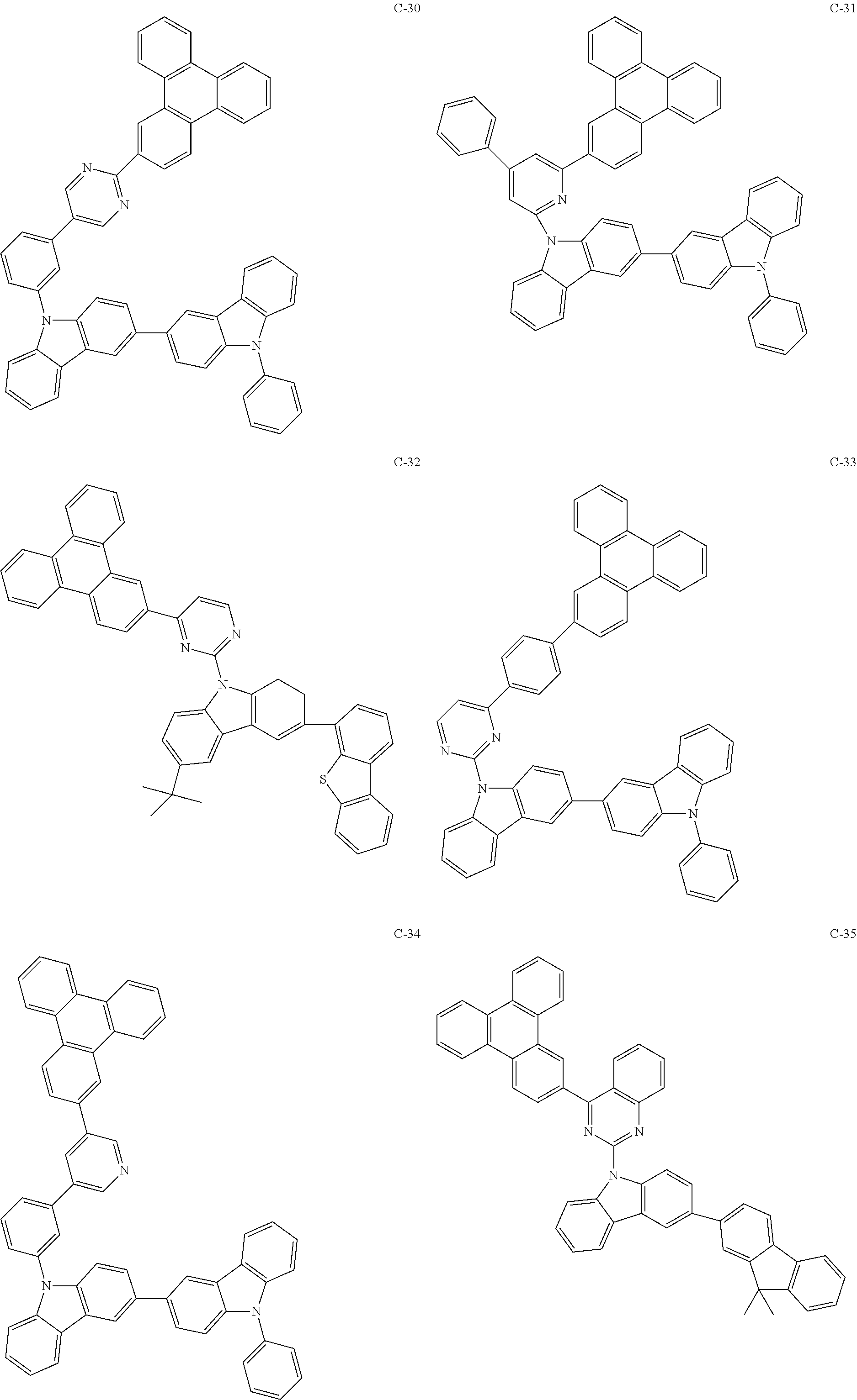

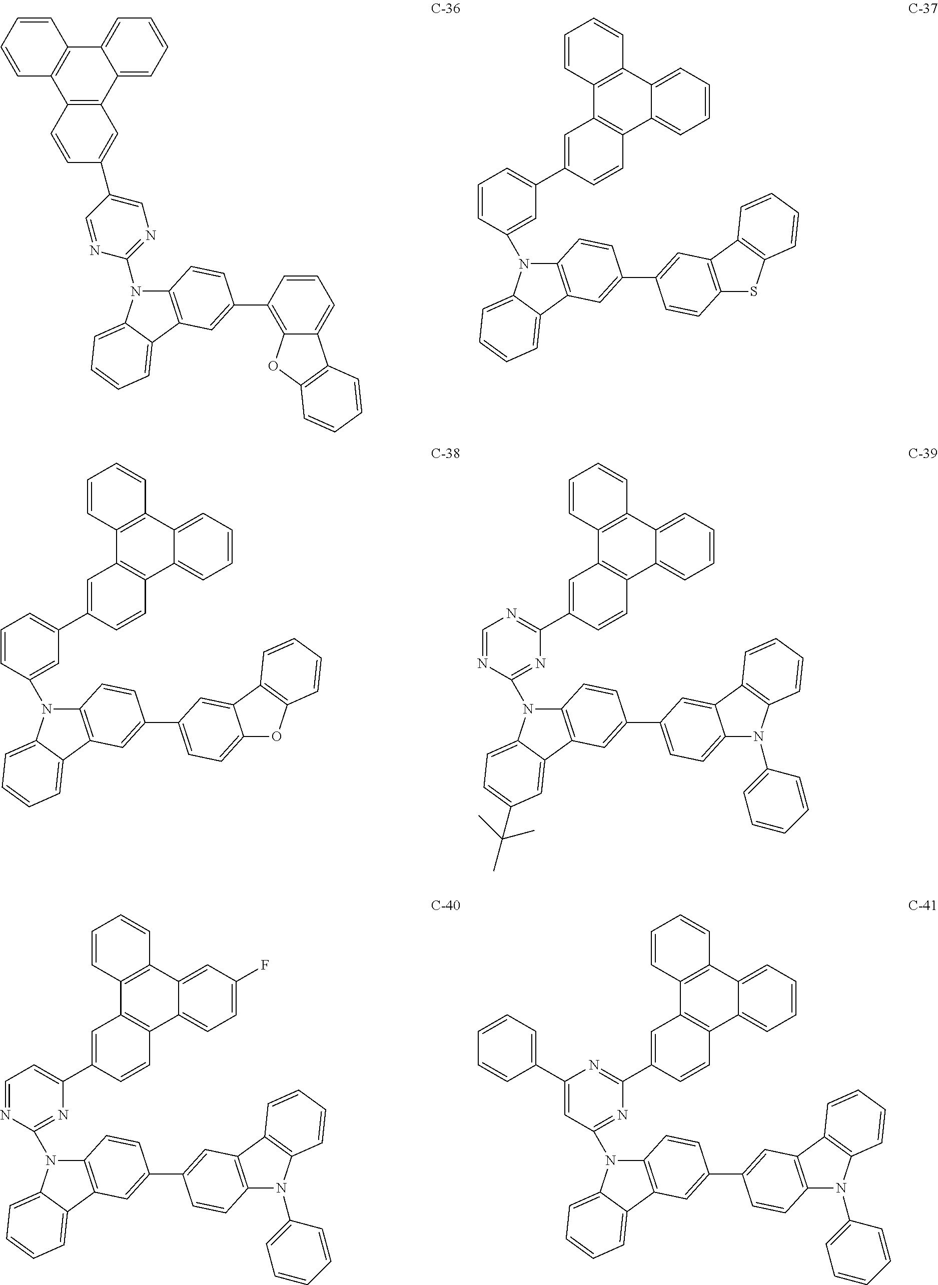

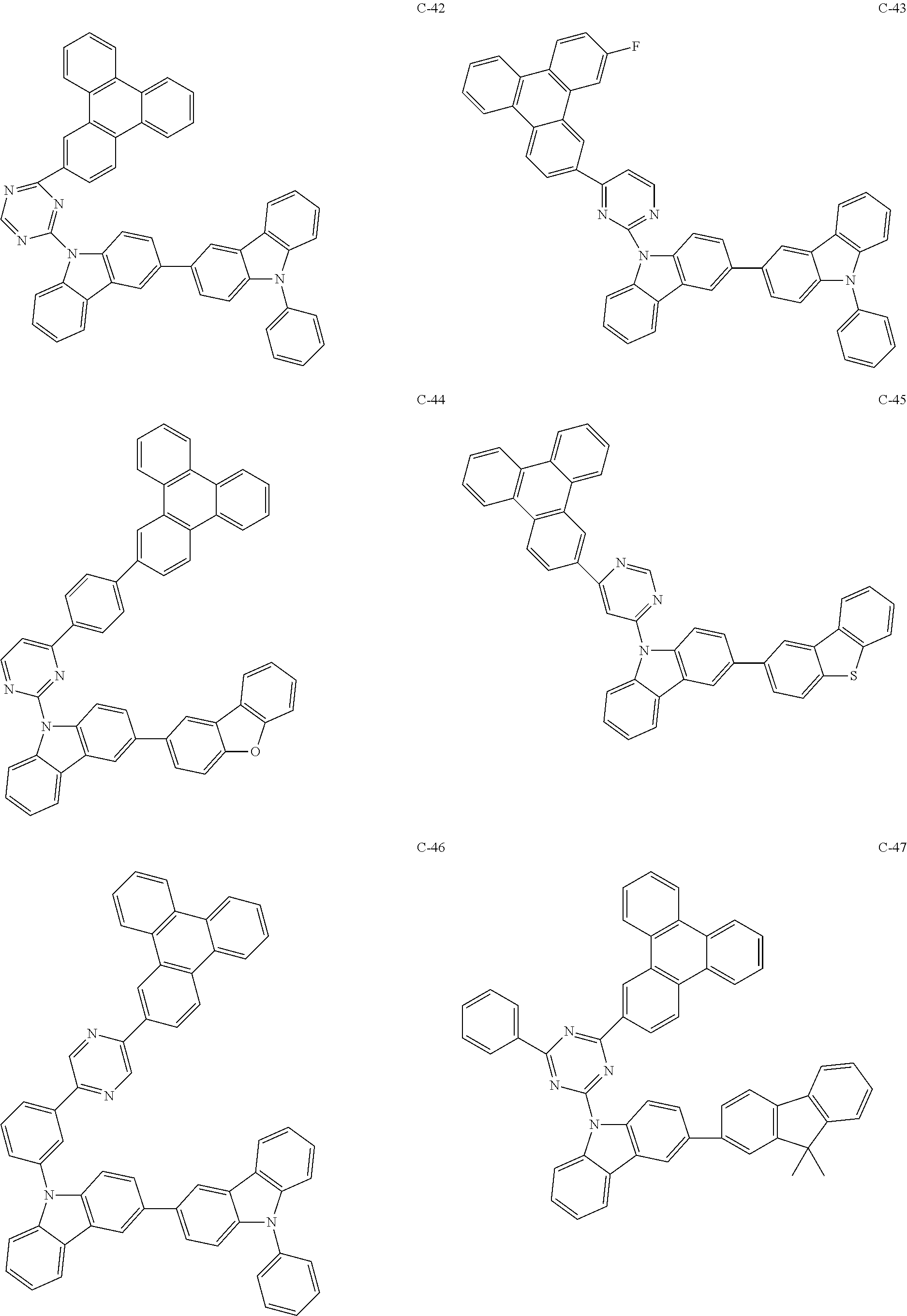

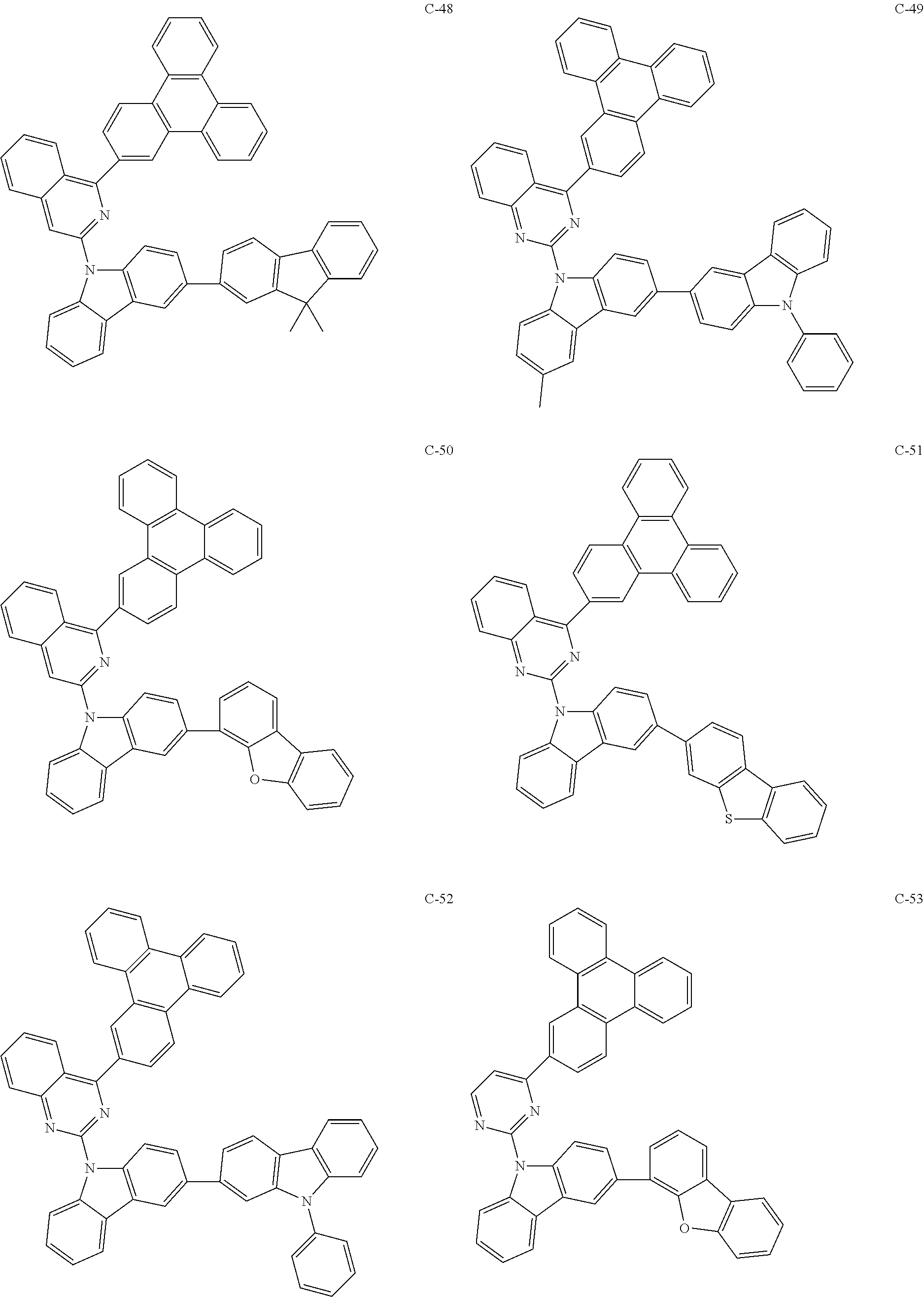

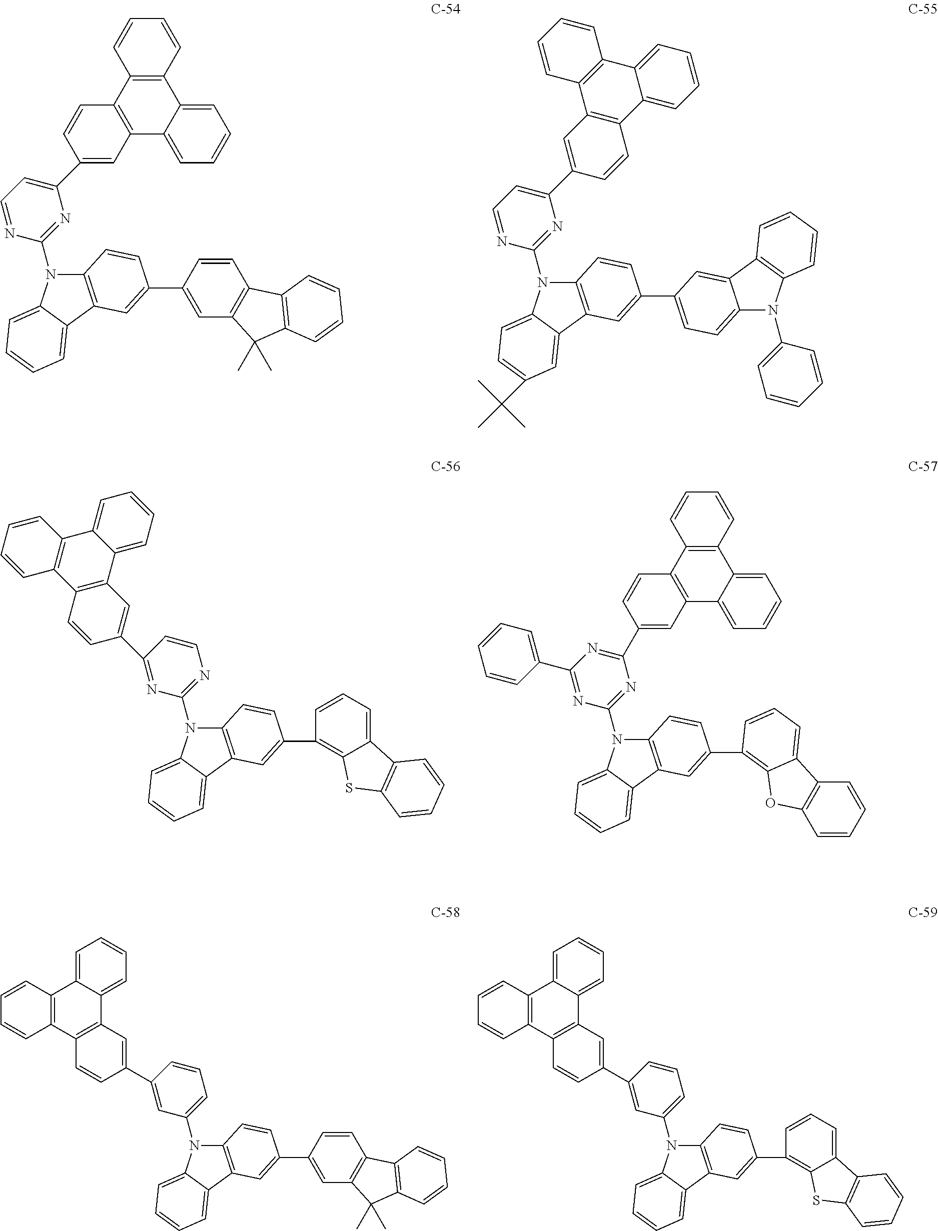

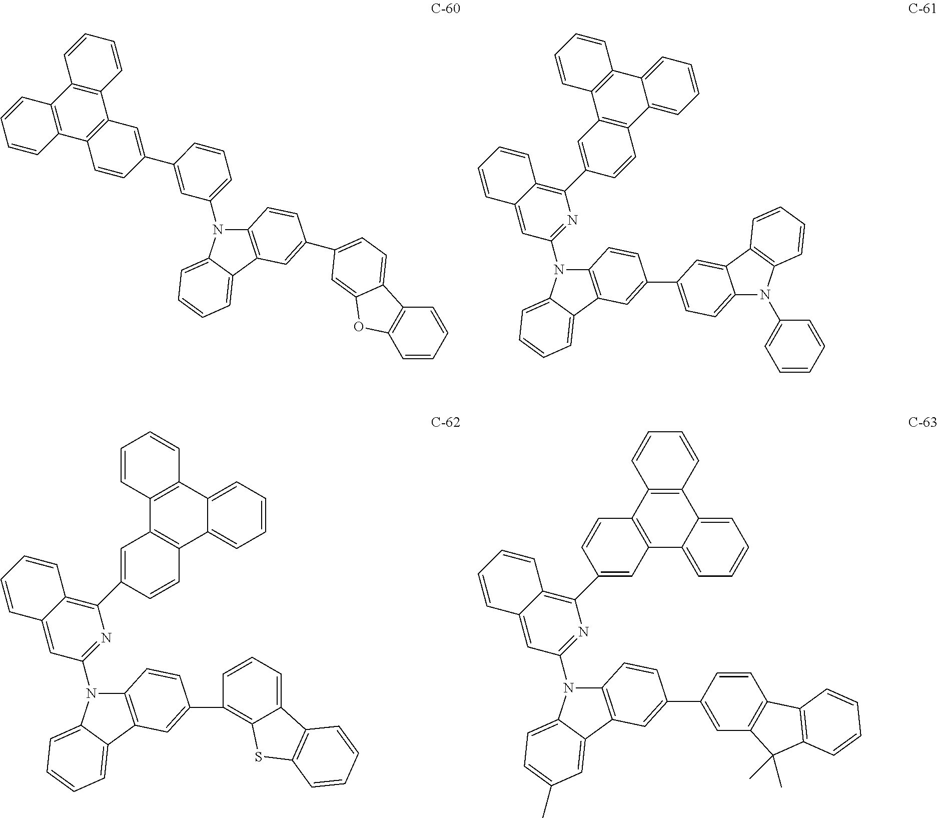 [SMILES: c1cc(-c2ccc3c4ccccc4c4ccccc4c3c2)cc(-n2c3ccccc3c3cc(-c4ccc5c(c4)oc4ccccc45)ccc32)c1 ; c1ccc(-n2c3ccccc3c3cc(-c4ccc5c(c4)c4ccccc4n5-c4cc5ccccc5c(-c5ccc6c7ccccc7c7ccccc7c6c5)n4)ccc32)cc1 ; c1ccc2c(-c3ccc4c5ccccc5c5ccccc5c4c3)nc(-n3c4ccccc4c4cc(-c5cccc6c5sc5ccccc56)ccc43)cc2c1 ; Cc1ccc2c(c1)c1cc(-c3ccc4c(c3)C(C)(C)c3ccccc3-4)ccc1n2-c1cc2ccccc2c(-c2ccc3c4ccccc4c4ccccc4c3c2)n1]

The organic electroluminescent compounds of the present invention can be prepared according to the following reaction scheme.

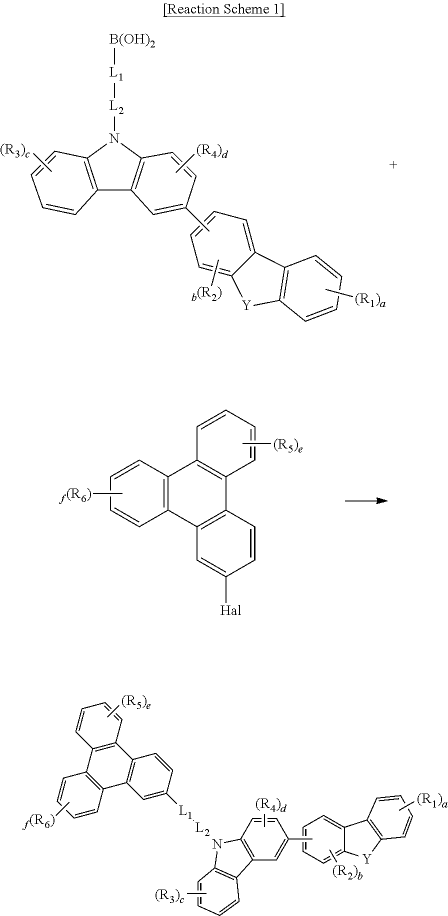

wherein L₁, L₂, R₁ to R₆, Y, a, b, c, d, e and f are as defined in formula 1 above, and Hal represents a halogen.

In addition, the present invention provides an organic electroluminescent material comprising the organic electroluminescent compound of formula 1, and an organic electroluminescent device comprising the material.

The above material can be comprised of the organic electroluminescent compound according to the present invention alone, or can further include conventional materials generally used in organic electroluminescent materials.

Said organic electroluminescent device comprises a first electrode, a second electrode, and at least one organic layer between said first and second electrodes. Said organic layer may comprise at least one organic electroluminescent compound of formula 1 according to the present invention, or an organic electroluminescent material comprising the compound.

One of the first and second electrodes is an anode, and the other is a cathode. The organic layer comprises a light-emitting layer, and at least one layer selected from the group consisting of a hole injection layer, a hole transport layer, an electron transport layer, an electron injection layer, an interlayer, a hole blocking layer and an electron blocking layer.

The organic electroluminescent compound according to the present invention can be comprised of in the light-emitting layer. Where used in the light-emitting layer, the organic electroluminescent compound according to the present invention can be comprised as a host material.

The light-emitting layer can further comprise at least one dopant and, if needed, another compound as a second host material in addition to the organic electroluminescent compound according to the present invention, wherein the ratio of the organic electroluminescent compound according to the present invention (a first host material) to the second host material can be in the range of 1:99 to 99:1.

The second host material can be from any of the known phosphorescent dopants. Specifically, the phosphorescent dopant selected from the group consisting of the compounds of formula 2 to 6 below is preferable in view of luminous efficiency.

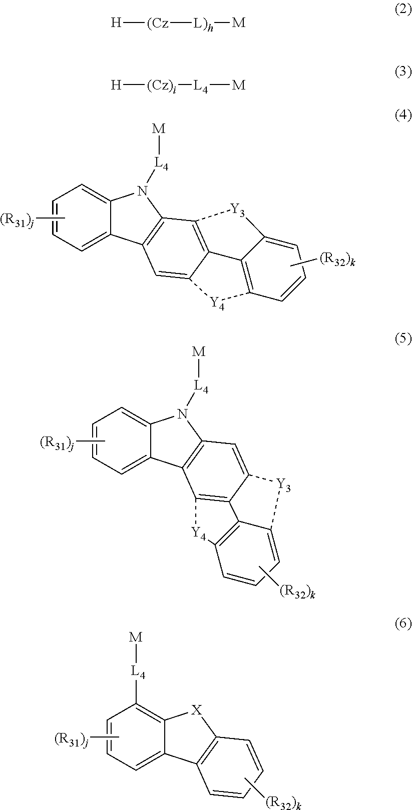

wherein Cz represents the following structure;

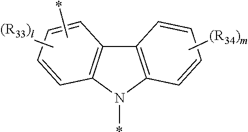

X represents O or S;

R₃₁ to R₃₄ each independently represent hydrogen, deuterium, a halogen, a substituted or unsubstituted (C1-C30)alkyl group, a substituted of unsubstituted (C6-C30)aryl group, a substituted or unsubstituted 3- to 30-membered heteroaryl group, or R₃₅R₃₆R₃₇Si—; R₃₅ to R₃₇ each independently represent a substituted or unsubstituted (C1-C30)alkyl group, or a substituted or unsubstituted (C6-C30)aryl group; L₄ represents a single bond, a substituted or unsubstituted (C6-C30)arylene group, or a substituted or unsubstituted 3- to 30-membered heteroarylene group; M represents a substituted or unsubstituted (C6-C30)arylgroup, or a substituted or unsubstituted 3- to 30-membered heteroaryl group; Y₃ and Y₄ represent —O—, —S—, —N(R₄₁)— or —C(R₄₂)(R₄₃)—, provided that Y₃ and Y₄ do not simultaneously exist; R₄₁ to R₄₃ each independently represent a substituted or unsubstituted (C1-C30)alkyl group, a substituted or unsubstituted (C6-C30)aryl group, or a substituted or unsubstituted 3- to 30-membered heteroaryl group, and R₄₂ and R₄₃ are the same or different; h and i each independently represent an integer of 1 to 3; j, k, l and m each independently represent an integer of 0 to 4; and where h, i, j, k, l or m is an integer of 2 or more, each of (Cz-L₄), each of (Cz), each of R₃₁, each of R₃₂, each of R₃₃ or each of R₃₄ is the same or different.

Specifically, preferable examples of the second host material are as follows:

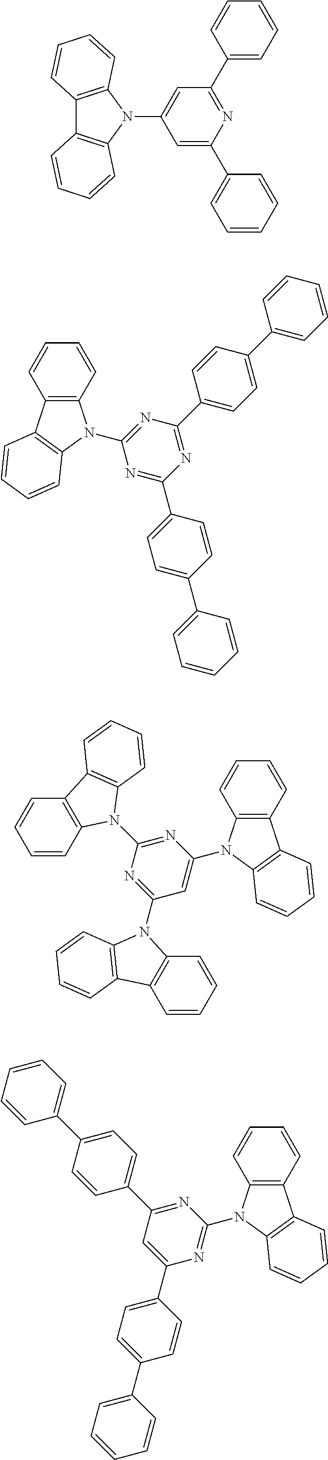 [SMILES: c1ccc(-c2cc(-n3c4ccccc4c4ccccc43)cc(-c3ccccc3)n2)cc1 ; c1ccc(-c2ccc(-c3nc(-c4ccc(-c5ccccc5)cc4)nc(-n4c5ccccc5c5ccccc54)n3)cc2)cc1 ; c1ccc2c(c1)c1ccccc1n2-c1cc(-n2c3ccccc3c3ccccc32)nc(-n2c3ccccc3c3ccccc32)n1 ; c1ccc(-c2ccc(-c3cc(-c4ccc(-c5ccccc5)cc4)nc(-n4c5ccccc5c5ccccc54)n3)cc2)cc1]

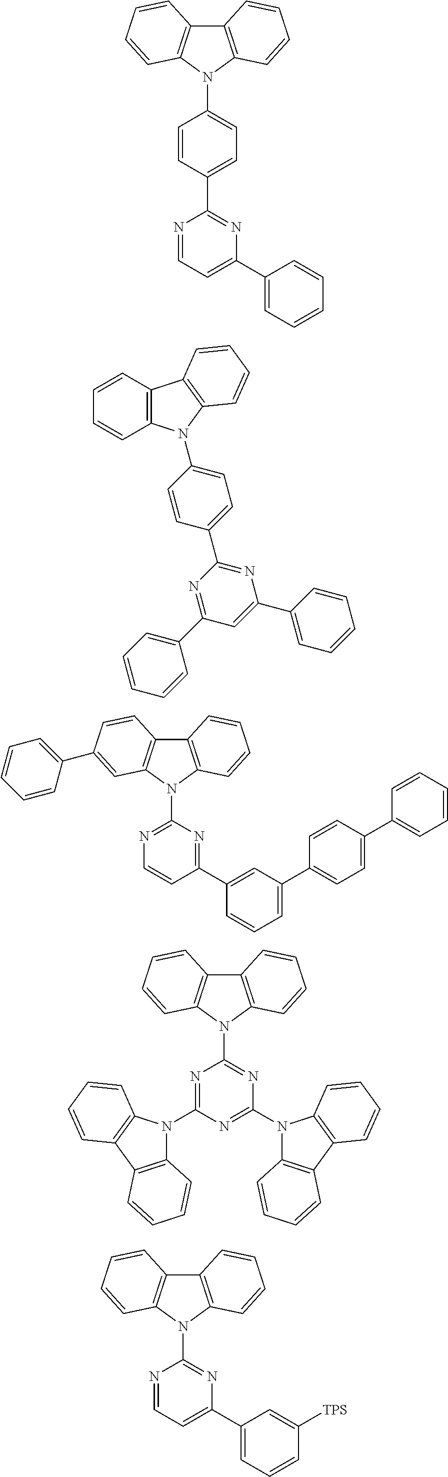

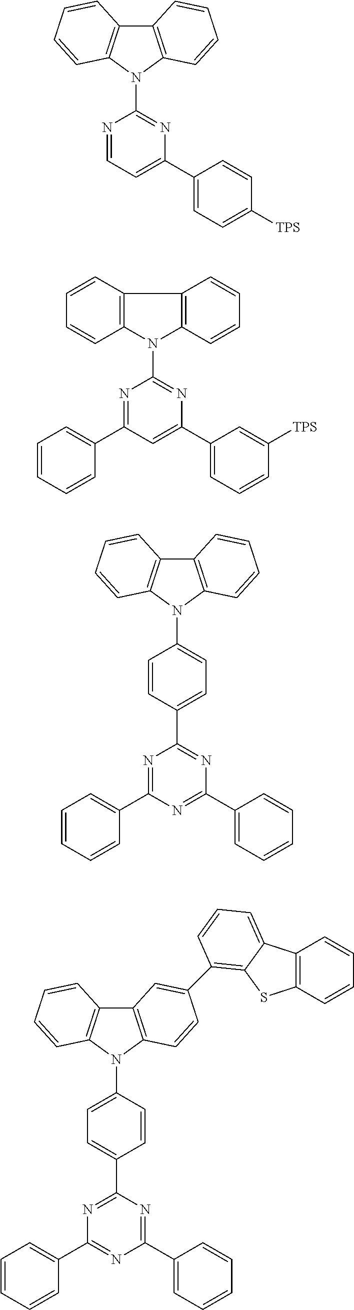

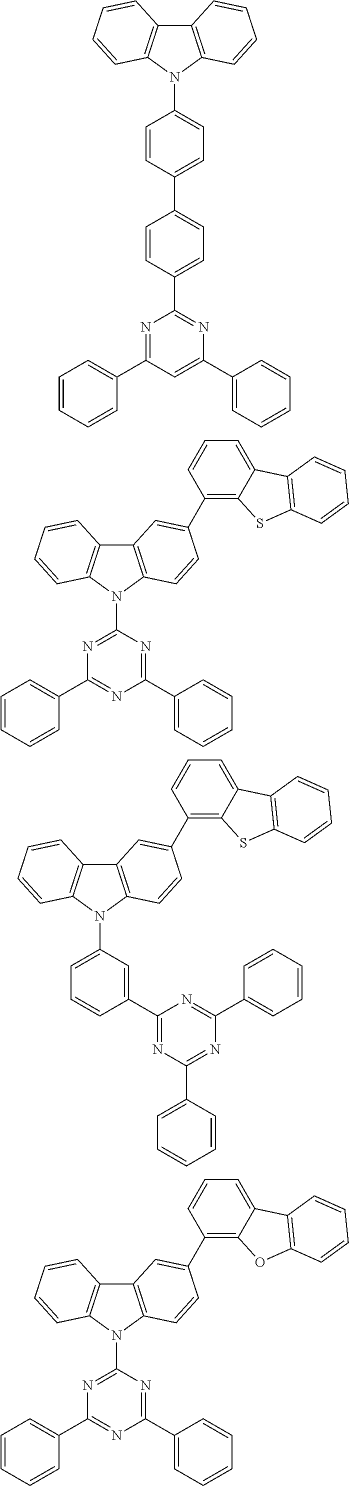

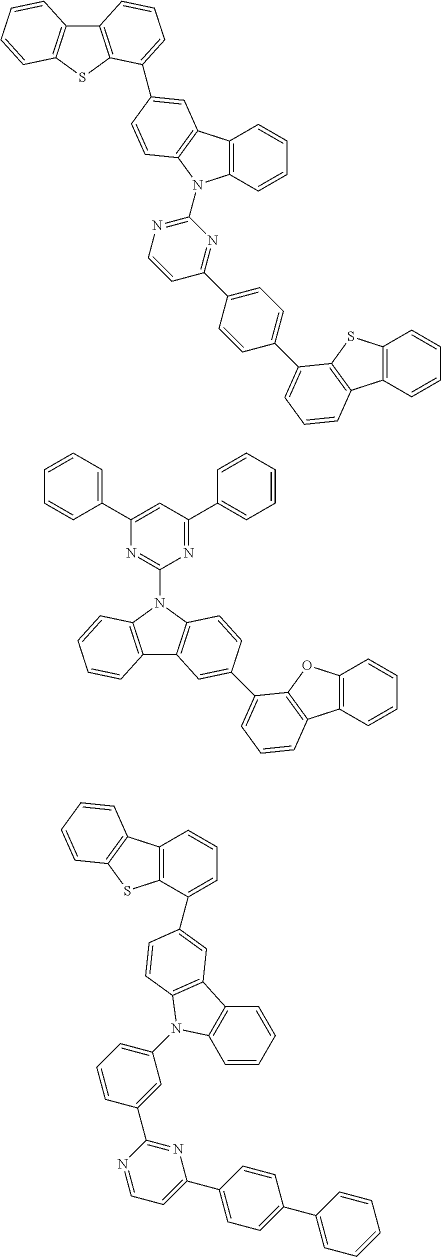 [SMILES: c1ccc2c(c1)sc1c(-c3ccc(-c4ccnc(-n5c6ccccc6c6cc(-c7cccc8c7sc7ccccc78)ccc65)n4)cc3)cccc12 ; c1ccc(-c2cc(-c3ccccc3)nc(-n3c4ccccc4c4cc(-c5cccc6c5oc5ccccc56)ccc43)n2)cc1 ; c1ccc(-c2ccc(-c3ccnc(-c4cccc(-n5c6ccccc6c6cc(-c7cccc8c7sc7ccccc78)ccc65)c4)n3)cc2)cc1]

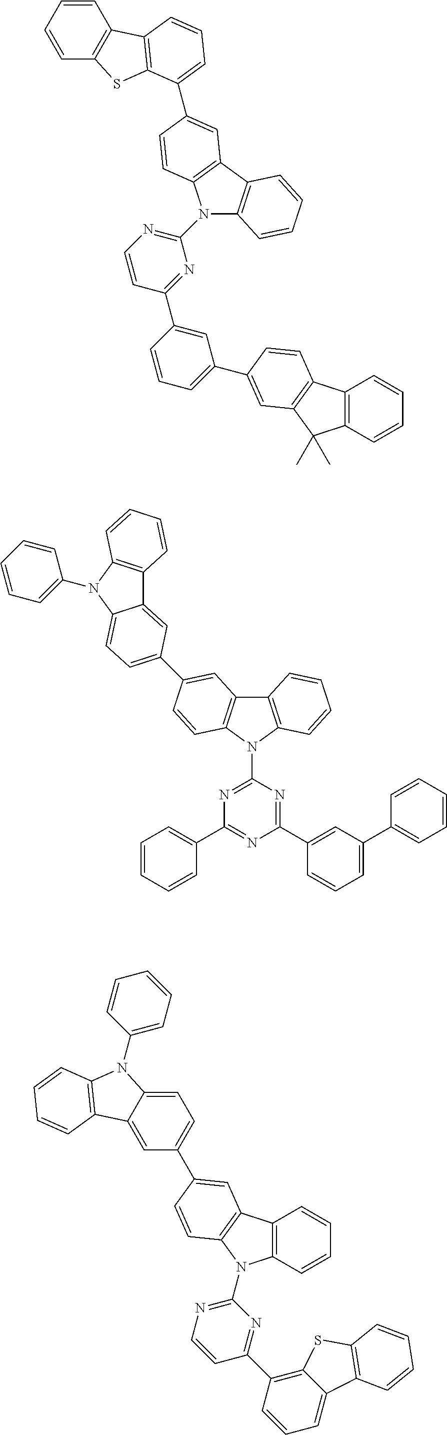 [SMILES: CC1(C)c2ccccc2-c2ccc(-c3cccc(-c4ccnc(-n5c6ccccc6c6cc(-c7cccc8c7sc7ccccc78)ccc65)n4)c3)cc21 ; c1ccc(-c2cccc(-c3nc(-c4ccccc4)nc(-n4c5ccccc5c5cc(-c6ccc7c(c6)c6ccccc6n7-c6ccccc6)ccc54)n3)c2)cc1 ; c1ccc(-n2c3ccccc3c3cc(-c4ccc5c(c4)c4ccccc4n5-c4nccc(-c5cccc6c5sc5ccccc56)n4)ccc32)cc1]

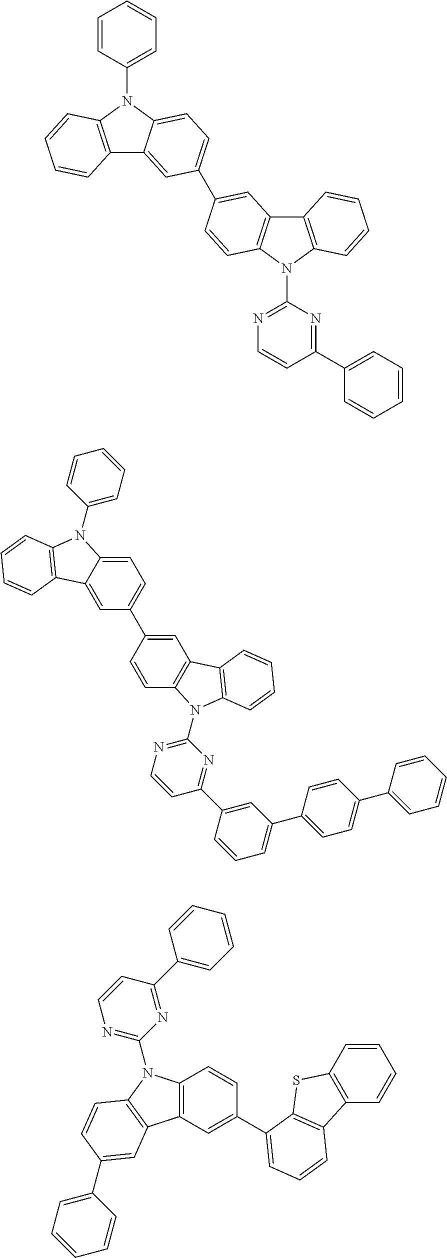 [SMILES: c1ccc(-c2ccnc(-n3c4ccccc4c4cc(-c5ccc6c(c5)c5ccccc5n6-c5ccccc5)ccc43)n2)cc1 ; c1ccc(-c2ccc(-c3cccc(-c4ccnc(-n5c6ccccc6c6cc(-c7ccc8c(c7)c7ccccc7n8-c7ccccc7)ccc65)n4)c3)cc2)cc1 ; c1ccc(-c2ccc3c(c2)c2cc(-c4cccc5c4sc4ccccc45)ccc2n3-c2nccc(-c3ccccc3)n2)cc1]

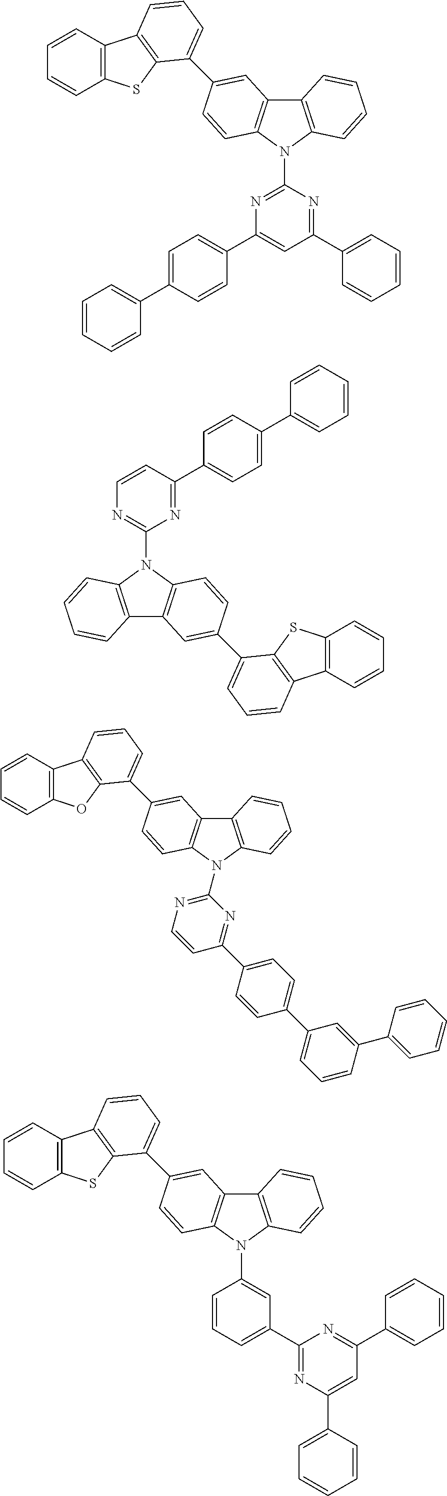 [SMILES: c1ccc(-c2ccc(-c3cc(-c4ccccc4)nc(-n4c5ccccc5c5cc(-c6cccc7c6sc6ccccc67)ccc54)n3)cc2)cc1 ; c1ccc(-c2ccc(-c3ccnc(-n4c5ccccc5c5cc(-c6cccc7c6sc6ccccc67)ccc54)n3)cc2)cc1 ; c1ccc(-c2cccc(-c3ccc(-c4ccnc(-n5c6ccccc6c6cc(-c7cccc8c7oc7ccccc78)ccc65)n4)cc3)c2)cc1 ; c1ccc(-c2cc(-c3ccccc3)nc(-c3cccc(-n4c5ccccc5c5cc(-c6cccc7c6sc6ccccc67)ccc54)c3)n2)cc1]

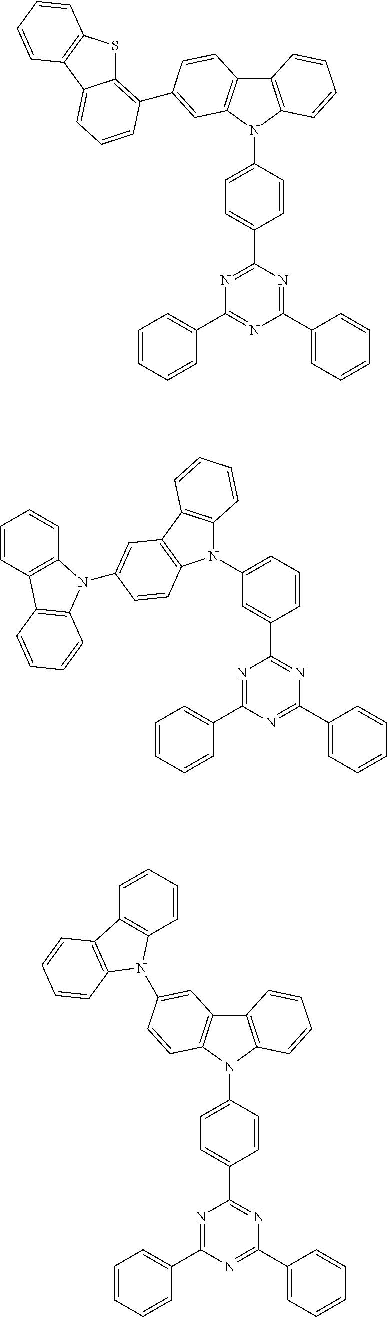 [SMILES: c1ccc(-c2nc(-c3ccccc3)nc(-c3ccc(-n4c5ccccc5c5ccc(-c6cccc7c6sc6ccccc67)cc54)cc3)n2)cc1 ; c1ccc(-c2nc(-c3ccccc3)nc(-c3cccc(-n4c5ccccc5c5cc(-n6c7ccccc7c7ccccc76)ccc54)c3)n2)cc1 ; c1ccc(-c2nc(-c3ccccc3)nc(-c3ccc(-n4c5ccccc5c5cc(-n6c7ccccc7c7ccccc76)ccc54)cc3)n2)cc1]

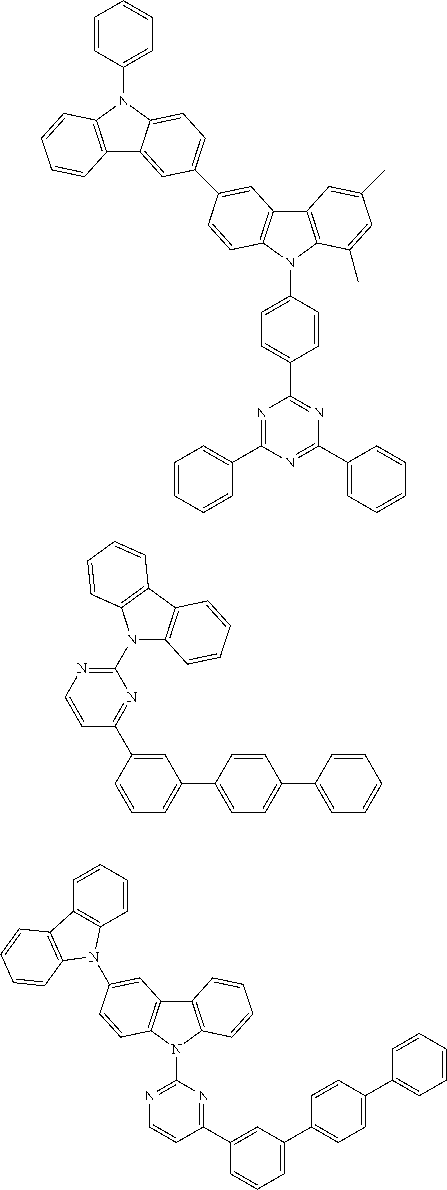 [SMILES: Cc1cc(C)c2c(c1)c1cc(-c3ccc4c(c3)c3ccccc3n4-c3ccccc3)ccc1n2-c1ccc(-c2nc(-c3ccccc3)nc(-c3ccccc3)n2)cc1 ; c1ccc(-c2ccc(-c3cccc(-c4ccnc(-n5c6ccccc6c6ccccc65)n4)c3)cc2)cc1 ; c1ccc(-c2ccc(-c3cccc(-c4ccnc(-n5c6ccccc6c6cc(-n7c8ccccc8c8ccccc87)ccc65)n4)c3)cc2)cc1]

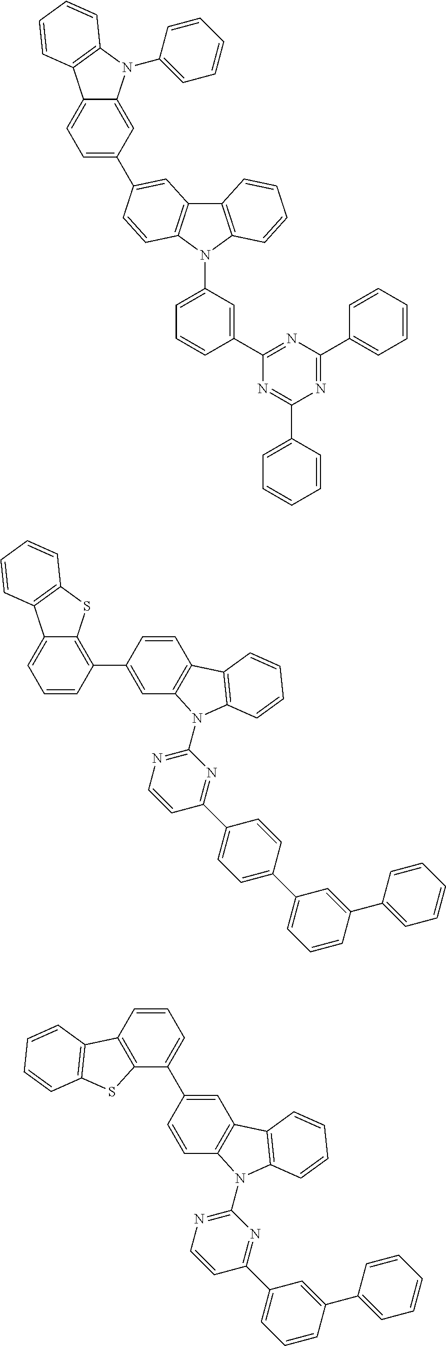 [SMILES: c1ccc(-c2nc(-c3ccccc3)nc(-c3cccc(-n4c5ccccc5c5cc(-c6ccc7c8ccccc8n(-c8ccccc8)c7c6)ccc54)c3)n2)cc1 ; c1ccc(-c2cccc(-c3ccc(-c4ccnc(-n5c6ccccc6c6ccc(-c7cccc8c7sc7ccccc78)cc65)n4)cc3)c2)cc1 ; c1ccc(-c2cccc(-c3ccnc(-n4c5ccccc5c5cc(-c6cccc7c6sc6ccccc67)ccc54)n3)c2)cc1]

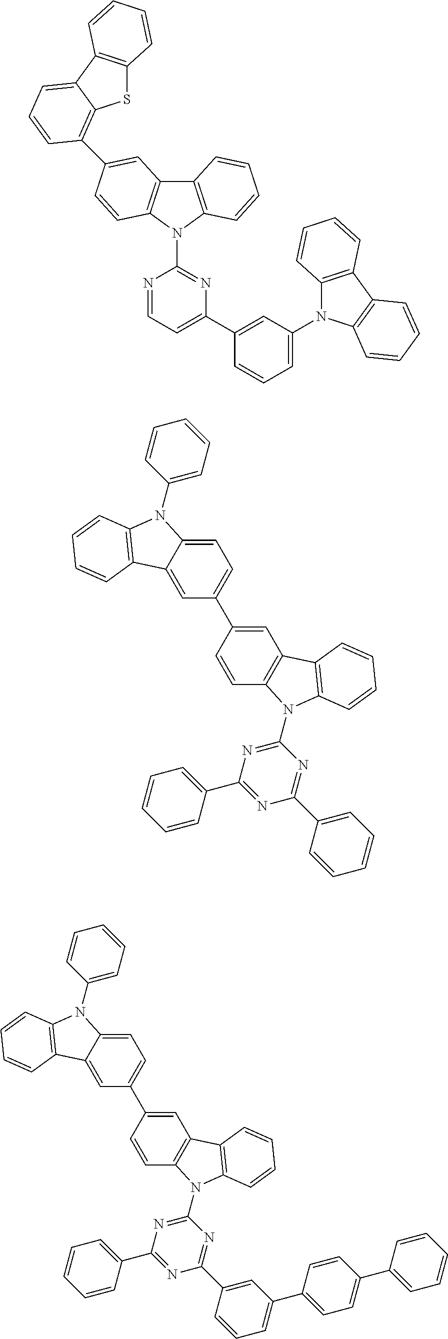 [SMILES: c1cc(-c2ccnc(-n3c4ccccc4c4cc(-c5cccc6c5sc5ccccc56)ccc43)n2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2ccc(-c3cccc(-c4nc(-c5ccccc5)nc(-n5c6ccccc6c6cc(-c7ccc8c(c7)c7ccccc7n8-c7ccccc7)ccc65)n4)c3)cc2)cc1]

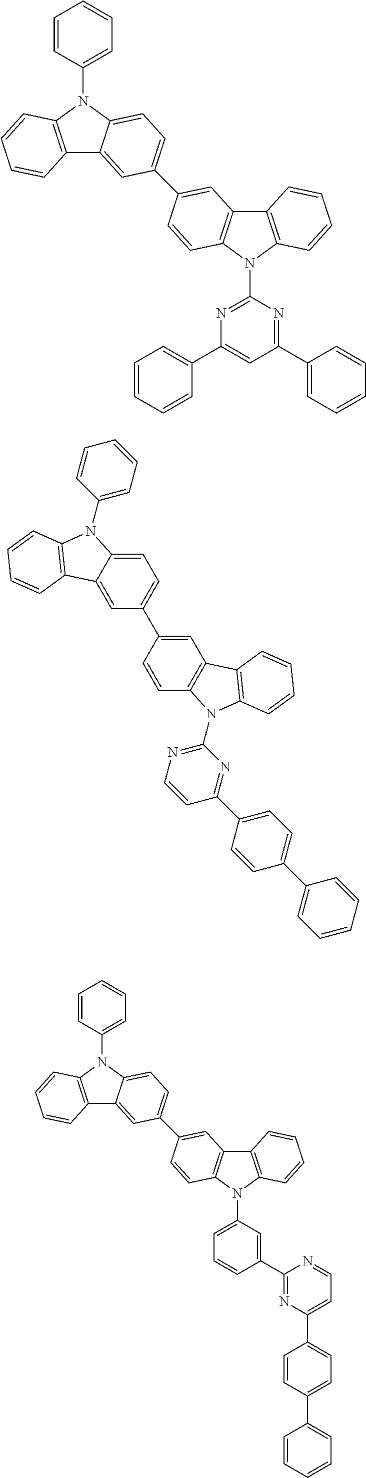 [SMILES: c1ccc(-c2cc(-c3ccccc3)nc(-n3c4ccccc4c4cc(-c5ccc6c(c5)c5ccccc5n6-c5ccccc5)ccc43)n2)cc1 ; c1ccc(-c2ccc(-c3ccnc(-n4c5ccccc5c5cc(-c6ccc7c(c6)c6ccccc6n7-c6ccccc6)ccc54)n3)cc2)cc1 ; c1ccc(-c2ccc(-c3ccnc(-c4cccc(-n5c6ccccc6c6cc(-c7ccc8c(c7)c7ccccc7n8-c7ccccc7)ccc65)c4)n3)cc2)cc1]

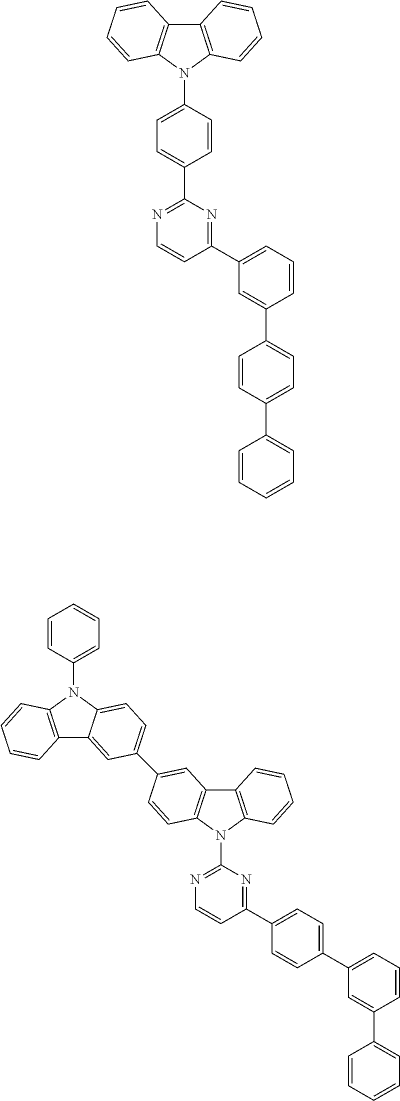 [SMILES: c1ccc(-c2ccc(-c3cccc(-c4ccnc(-c5ccc(-n6c7ccccc7c7ccccc76)cc5)n4)c3)cc2)cc1 ; c1ccc(-c2cccc(-c3ccc(-c4ccnc(-n5c6ccccc6c6cc(-c7ccc8c(c7)c7ccccc7n8-c7ccccc7)ccc65)n4)cc3)c2)cc1]

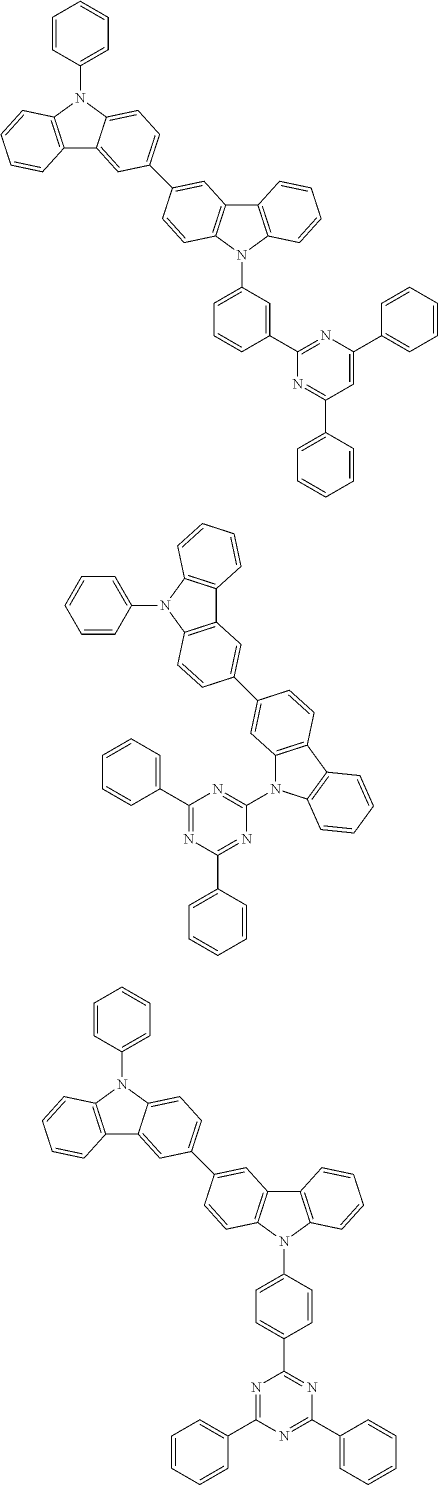 [SMILES: c1ccc(-c2cc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

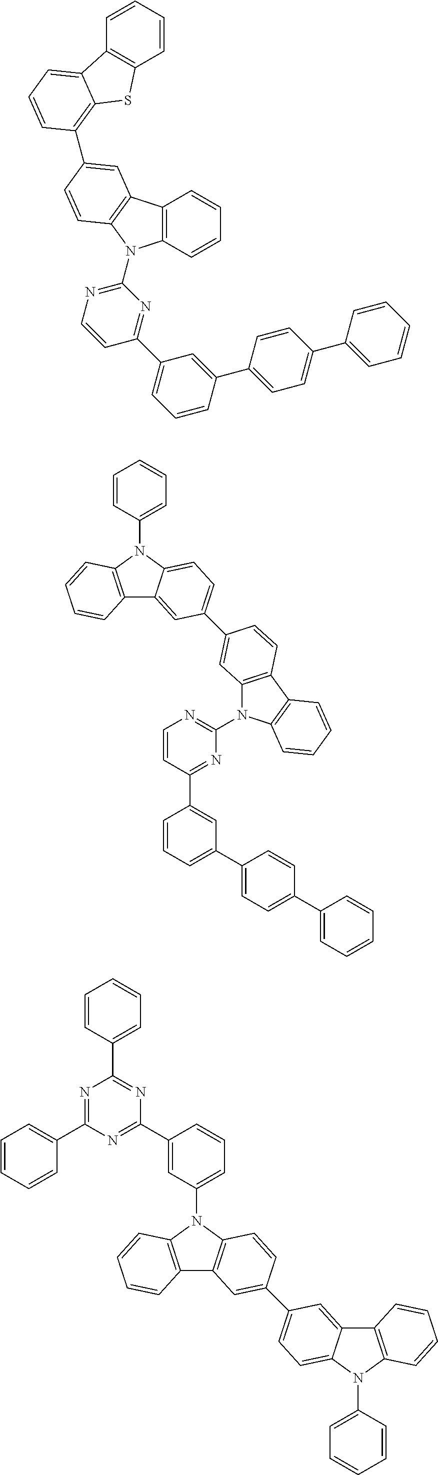 [SMILES: c1ccc(-c2ccc(-c3cccc(-c4ccnc(-n5c6ccccc6c6cc(-c7cccc8c7sc7ccccc78)ccc65)n4)c3)cc2)cc1 ; c1ccc(-c2ccc(-c3cccc(-c4ccnc(-n5c6ccccc6c6ccc(-c7ccc8c(c7)c7ccccc7n8-c7ccccc7)cc65)n4)c3)cc2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

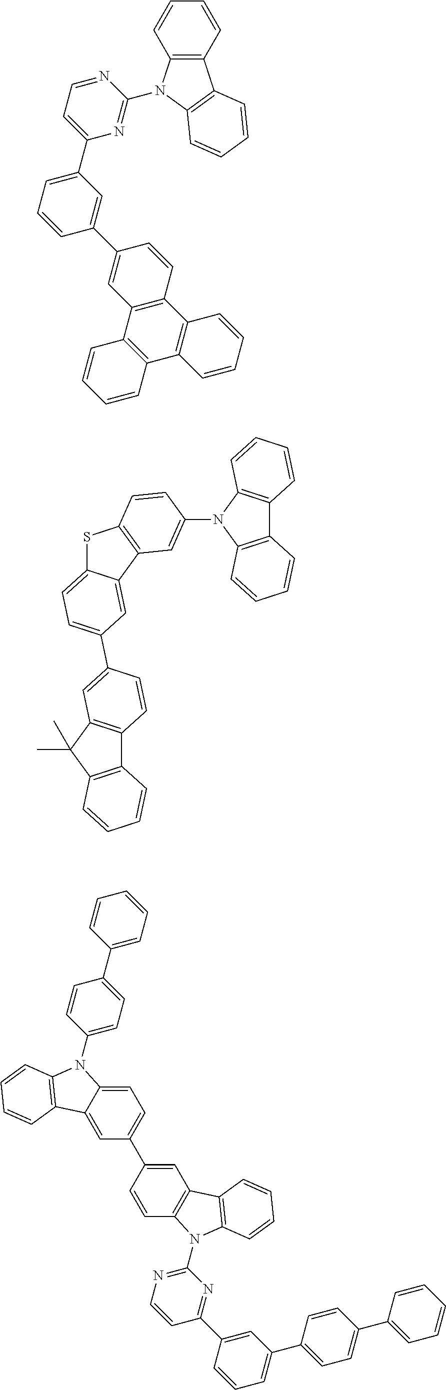 [SMILES: c1cc(-c2ccc3c4ccccc4c4ccccc4c3c2)cc(-c2ccnc(-n3c4ccccc4c4ccccc43)n2)c1 ; CC1(C)c2ccccc2-c2ccc(-c3ccc4sc5ccc(-n6c7ccccc7c7ccccc76)cc5c4c3)cc21 ; c1ccc(-c2ccc(-c3cccc(-c4ccnc(-n5c6ccccc6c6cc(-c7ccc8c(c7)c7ccccc7n8-c7ccc(-c8ccccc8)cc7)ccc65)n4)c3)cc2)cc1]

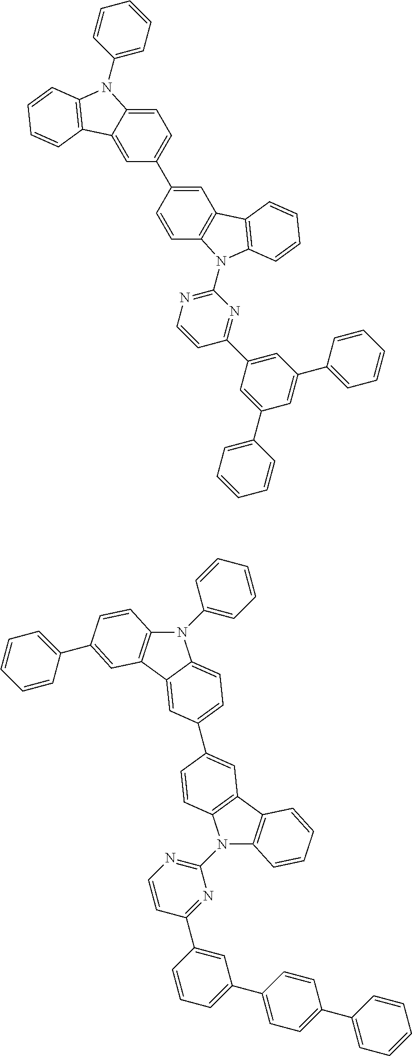 [SMILES: c1ccc(-c2cc(-c3ccccc3)cc(-c3ccnc(-n4c5ccccc5c5cc(-c6ccc7c(c6)c6ccccc6n7-c6ccccc6)ccc54)n3)c2)cc1 ; c1ccc(-c2ccc(-c3cccc(-c4ccnc(-n5c6ccccc6c6cc(-c7ccc8c(c7)c7cc(-c9ccccc9)ccc7n8-c7ccccc7)ccc65)n4)c3)cc2)cc1]

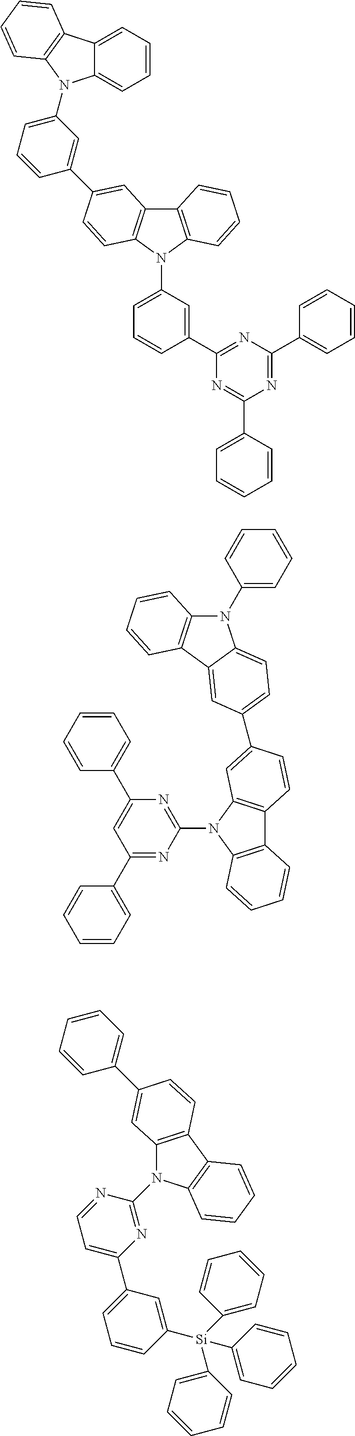

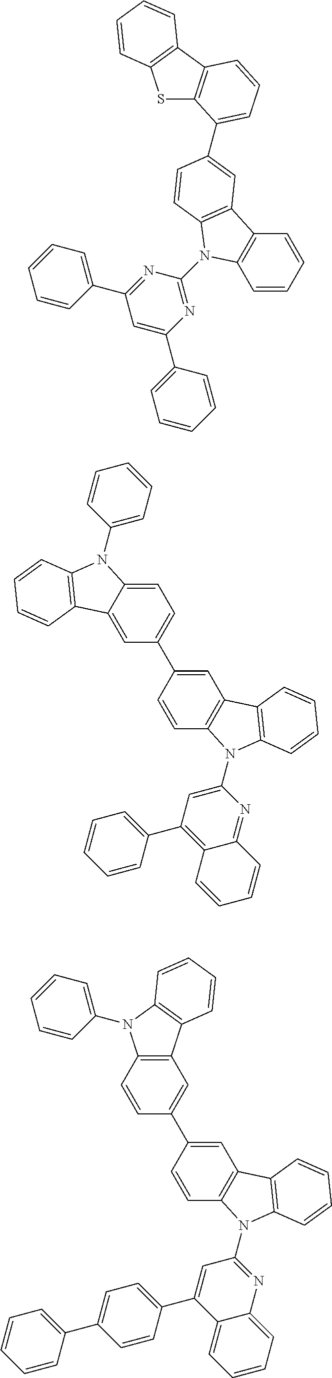 [SMILES: c1ccc(-c2cc(-c3ccccc3)nc(-n3c4ccccc4c4cc(-c5cccc6c5sc5ccccc56)ccc43)n2)cc1 ; c1ccc(-c2cc(-n3c4ccccc4c4cc(-c5ccc6c(c5)c5ccccc5n6-c5ccccc5)ccc43)nc3ccccc23)cc1 ; c1ccc(-c2ccc(-c3cc(-n4c5ccccc5c5cc(-c6ccc7c(c6)c6ccccc6n7-c6ccccc6)ccc54)nc4ccccc34)cc2)cc1]

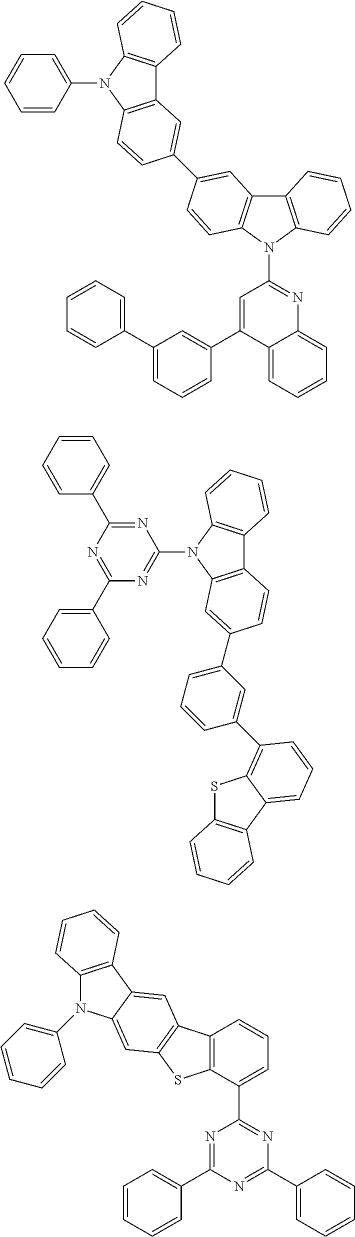 [SMILES: c1ccc(-c2cccc(-c3cc(-n4c5ccccc5c5cc(-c6ccc7c(c6)c6ccccc6n7-c6ccccc6)ccc54)nc4ccccc34)c2)cc1 ; c1ccc(-c2nc(-c3ccccc3)nc(-n3c4ccccc4c4ccc(-c5cccc(-c6cccc7c6sc6ccccc67)c5)cc43)n2)cc1 ; c1ccc(-c2nc(-c3ccccc3)nc(-c3cccc4c3sc3cc5c(cc34)c3ccccc3n5-c3ccccc3)n2)cc1]

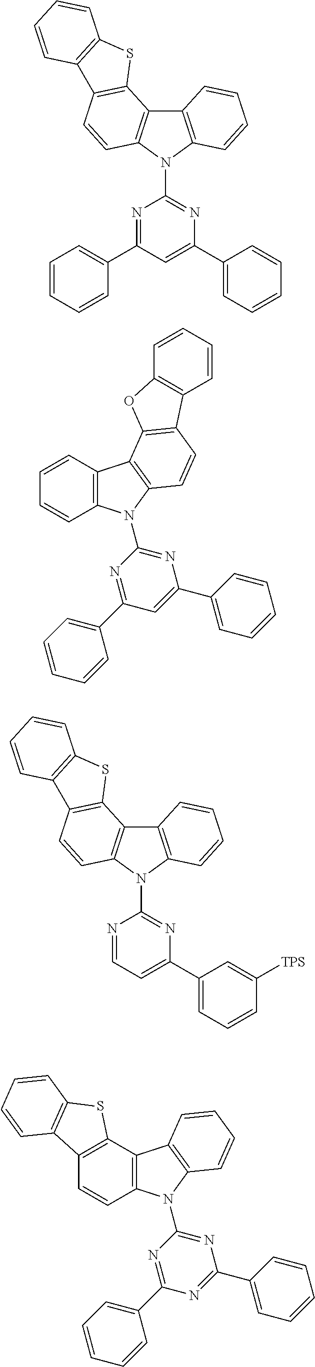

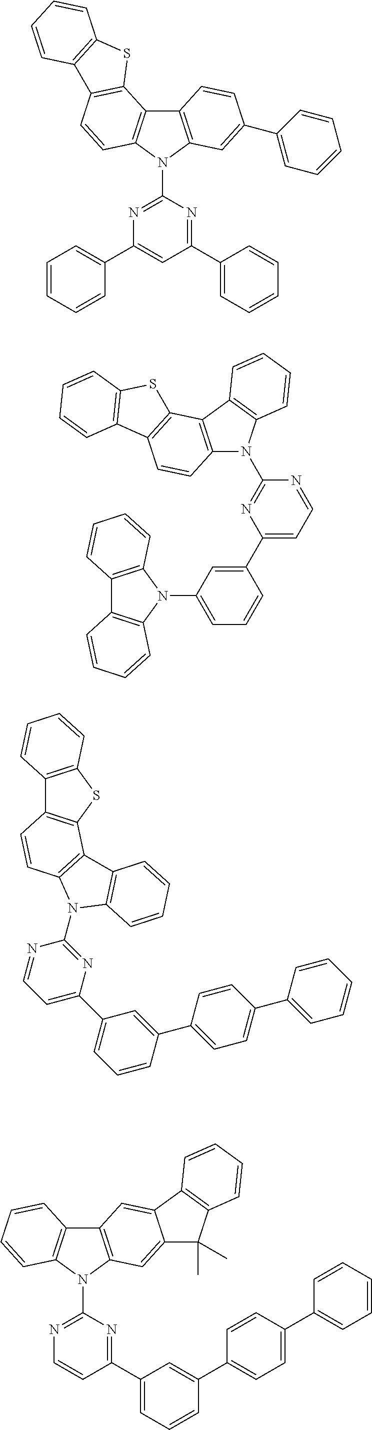

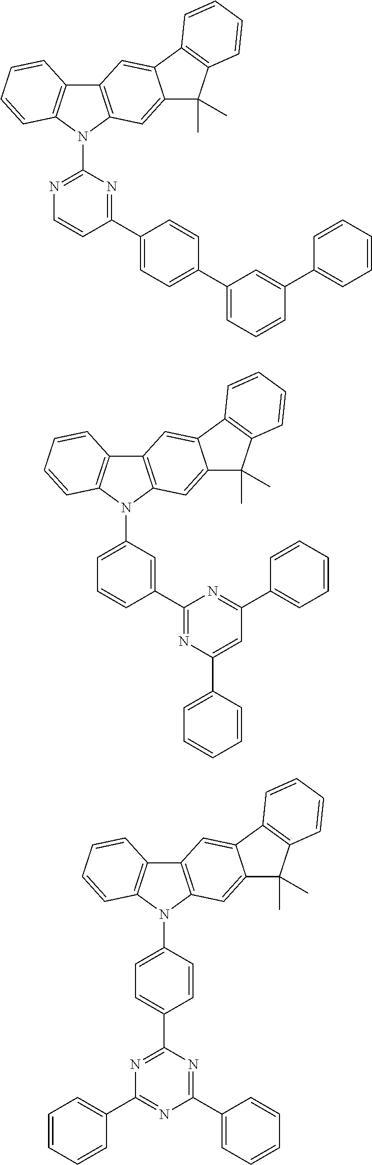

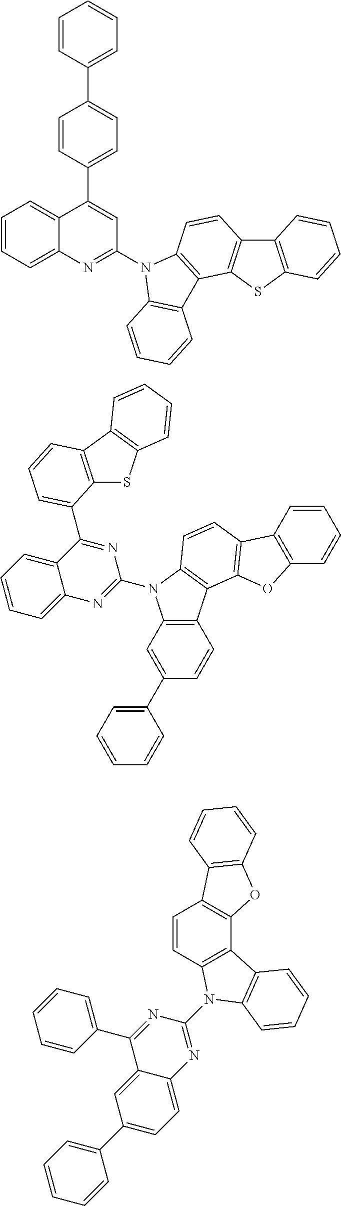

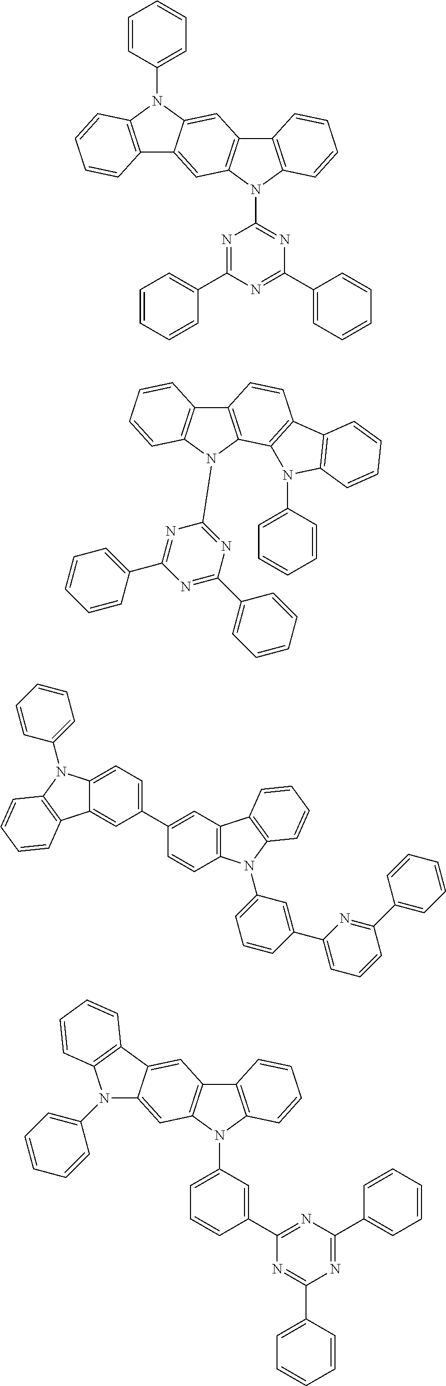

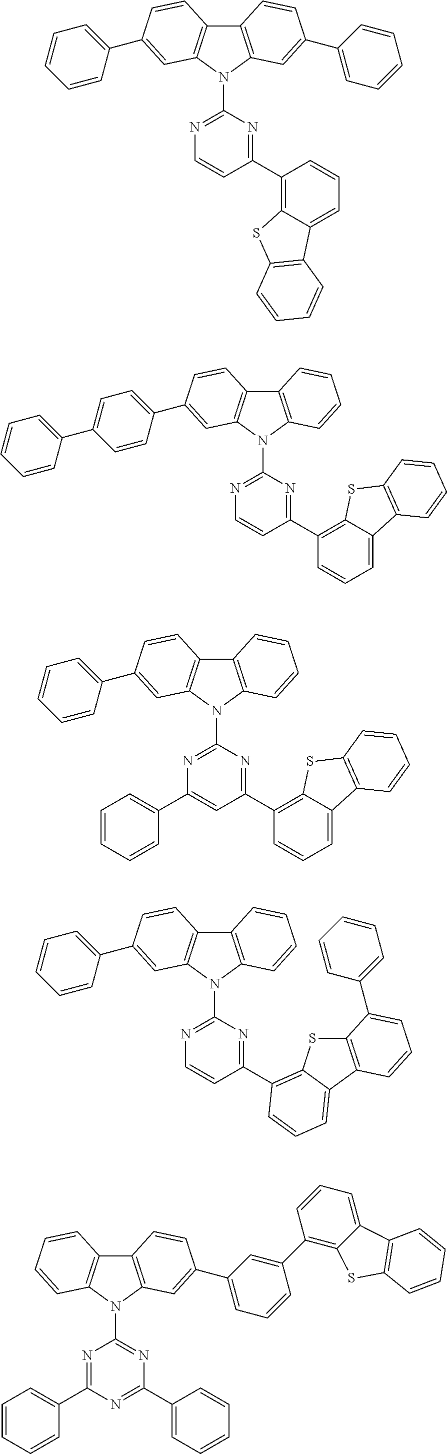 [SMILES: c1ccc(-c2ccc3c4ccc(-c5ccccc5)cc4n(-c4nccc(-c5cccc6c5sc5ccccc56)n4)c3c2)cc1 ; c1ccc(-c2ccc(-c3ccc4c5ccccc5n(-c5nccc(-c6cccc7c6sc6ccccc67)n5)c4c3)cc2)cc1 ; c1ccc(-c2ccc3c4ccccc4n(-c4nc(-c5ccccc5)cc(-c5cccc6c5sc5ccccc56)n4)c3c2)cc1 ; c1ccc(-c2ccc3c4ccccc4n(-c4nccc(-c5cccc6c5sc5c(-c7ccccc7)cccc56)n4)c3c2)cc1 ; c1ccc(-c2nc(-c3ccccc3)nc(-n3c4ccccc4c4ccc(-c5cccc(-c6cccc7c6sc6ccccc67)c5)cc43)n2)cc1]

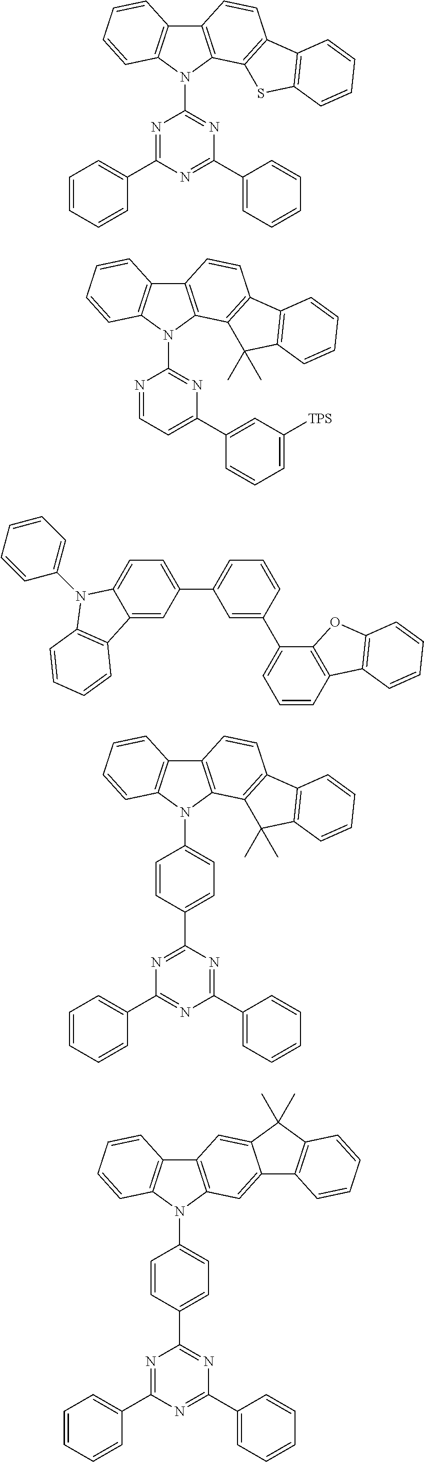

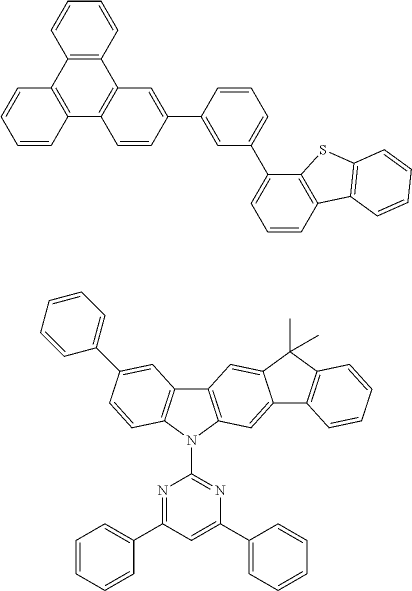 [SMILES: c1cc(-c2ccc3c4ccccc4c4ccccc4c3c2)cc(-c2cccc3c2sc2ccccc23)c1 ; CC1(C)c2ccccc2-c2cc3c(cc21)c1cc(-c2ccccc2)ccc1n3-c1nc(-c2ccccc2)cc(-c2ccccc2)n1]

According to the present invention, the dopant used in the manufacture of the organic electroluminescent device is preferably one or more phosphorescent dopants. The phosphorescent dopant material applied to the electroluminescent device according to the present invention is not limited, but preferably may be selected from complex compounds of iridium, osmium, copper and platinum; more preferably ortho-metallated complex compounds of iridium, osmium, copper and platinum; and even more preferably ortho-metallated iridium complex compounds.

According to the present invention, the dopant comprised in the organic electroluminescent device may be selected from compounds represented by the following formulas 7 to 9.

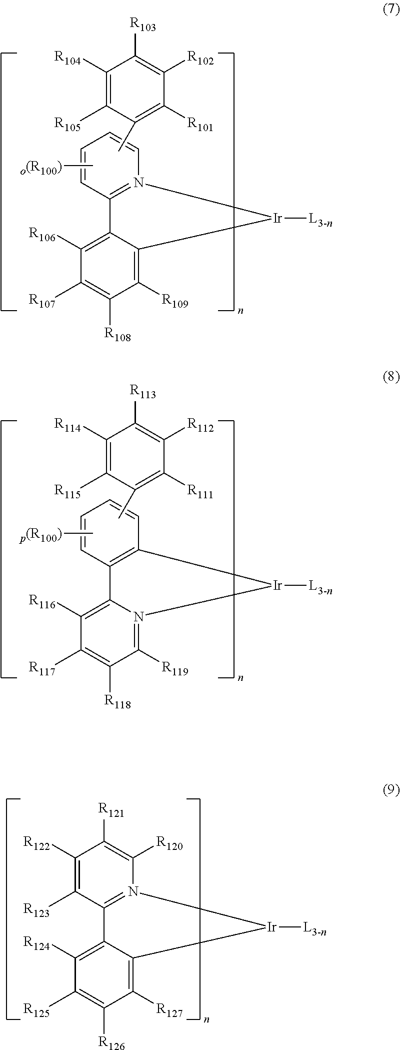

wherein L is selected from the following structures:

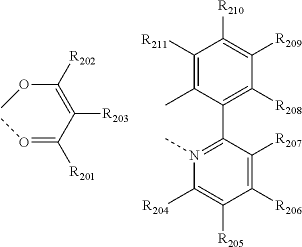

R₁₀₀ represents hydrogen, a substituted or unsubstituted (C1-C30)alkyl group, or a substituted or unsubstituted (C3-C30)cycloalkyl group; R₁₀₁ to R₁₀₉, and R₁₁₁ to R₁₂₃ each independently represent hydrogen, deuterium, a halogen, a (C1-C30)alkyl group unsubstituted or substituted with halogen(s), a substituted or unsubstituted (C3-C30)cycloalkyl group, a cyano group, or a substituted or unsubstituted (C1-C30)alkoxy group; R₁₂₀ to R₁₂₃ are linked to an adjacent substituent to form a fused ring, e.g. quinoline; R₁₂₄ to R₁₂₇ each independently represent hydrogen, deuterium, a halogen, a substituted or unsubstituted (C1-C30)alkyl group, or a substituted or unsubstituted (C6-C30)aryl group; where R₁₂₄ to R₁₂₇ are aryl groups, adjacent substituents may be linked to each other to form a fused ring, e.g. fluorene; R₂₀₁ to R₂₁₁ each independently represent hydrogen, deuterium, a halogen, a (C1-C30)alkyl group unsubstituted or substituted with halogen(s), or a substituted or unsubstituted (C3-C30)cycloalkyl group; o and p each independently represent an integer of 1 to 3; where o or p is an integer of 2 or more, each of R₁₀₀ is the same or different; and n is an integer of 1 to 3.

The phosphorescent dopant materials include the following:

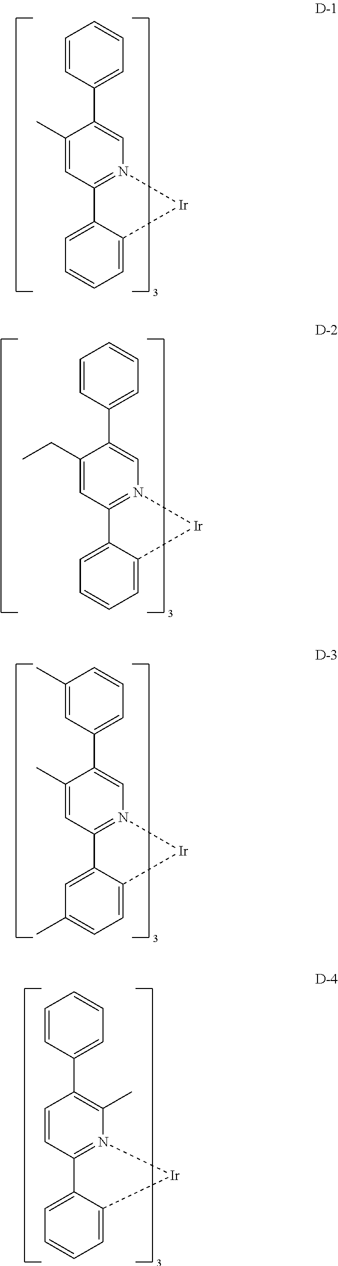

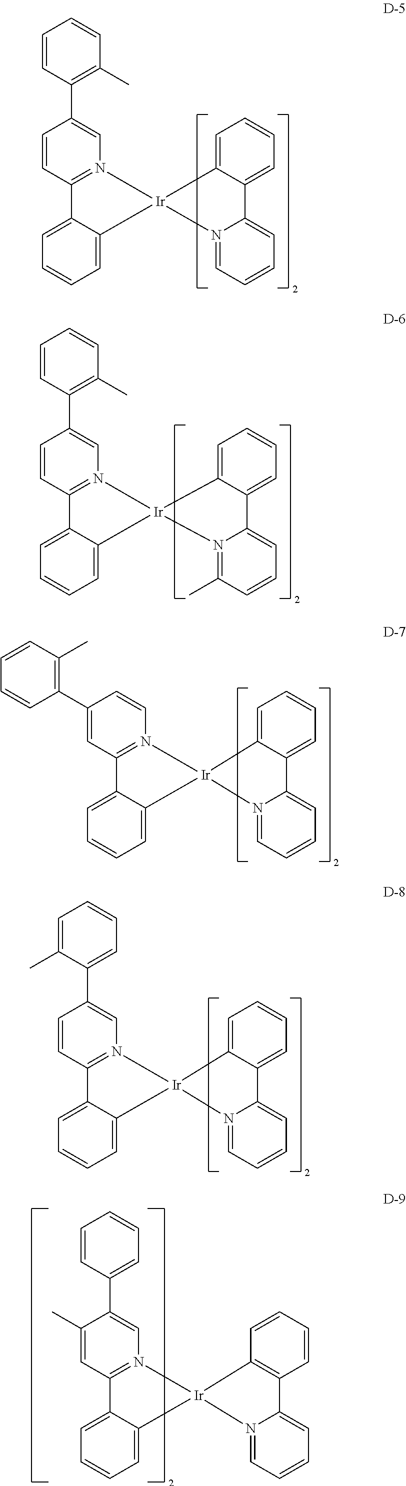

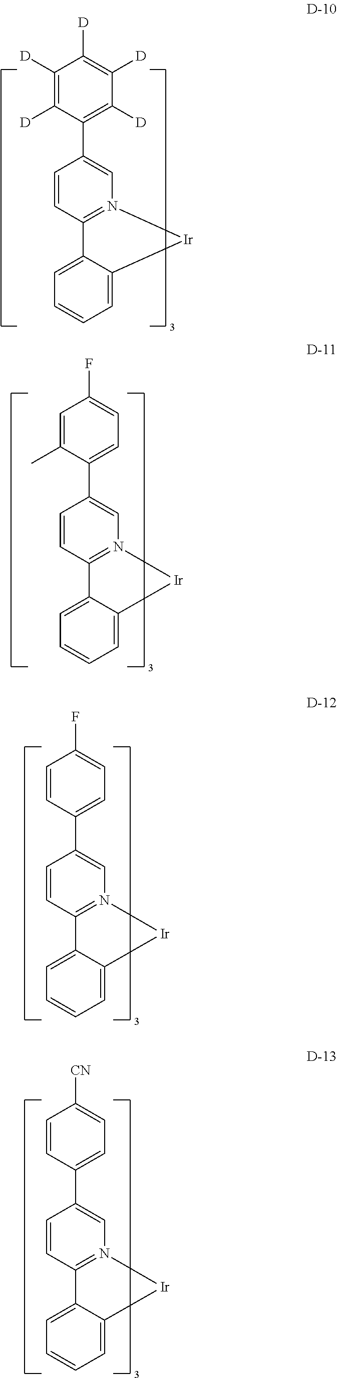

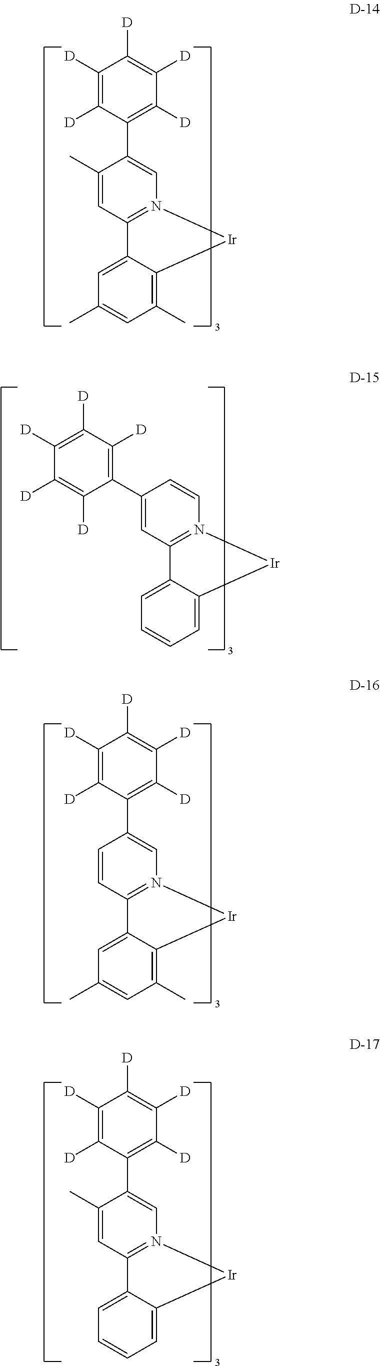

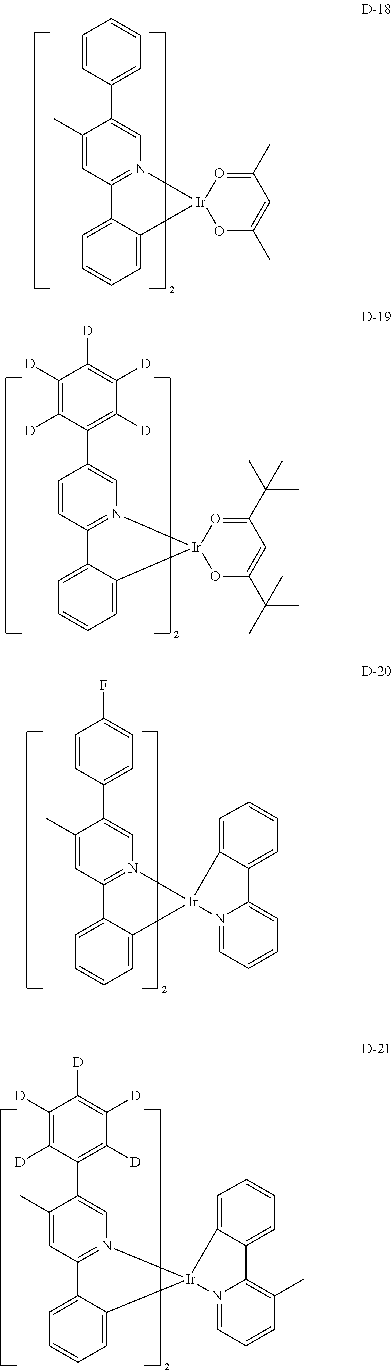

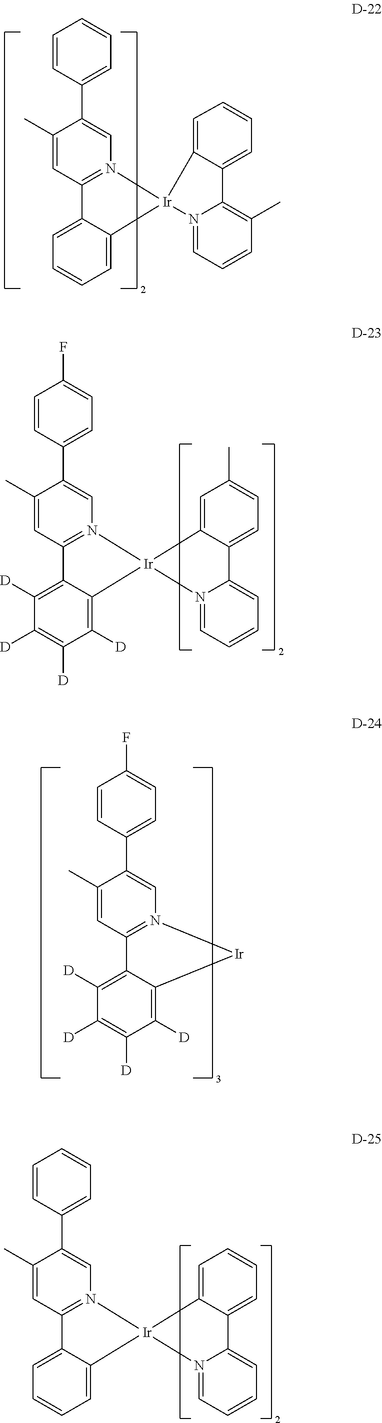

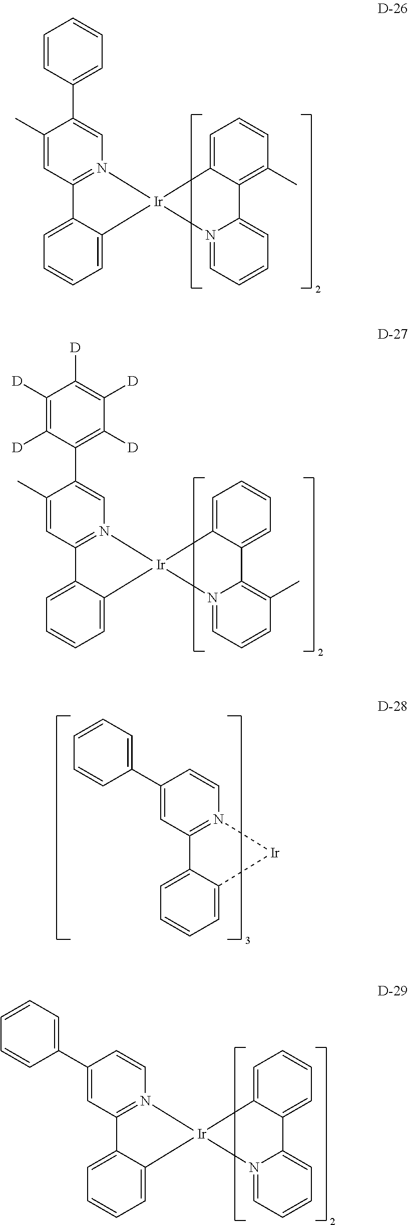

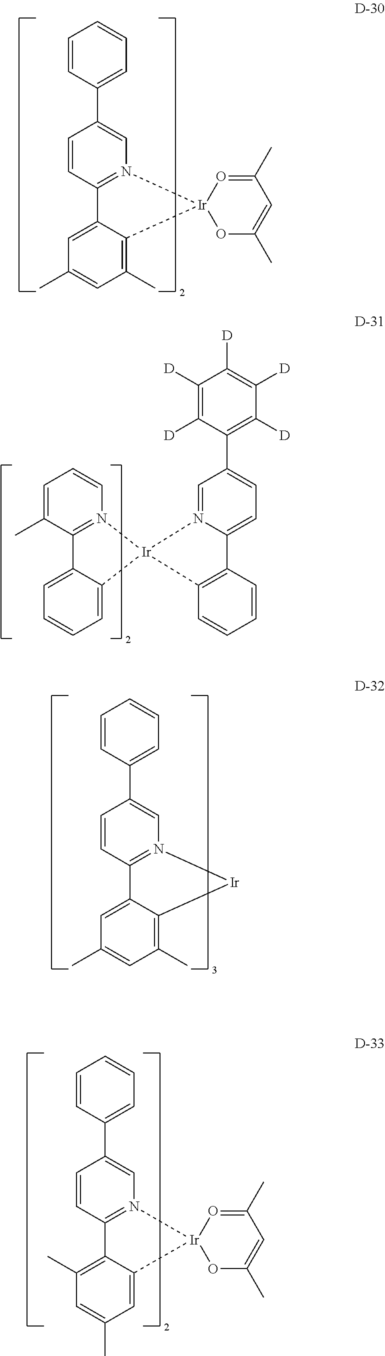

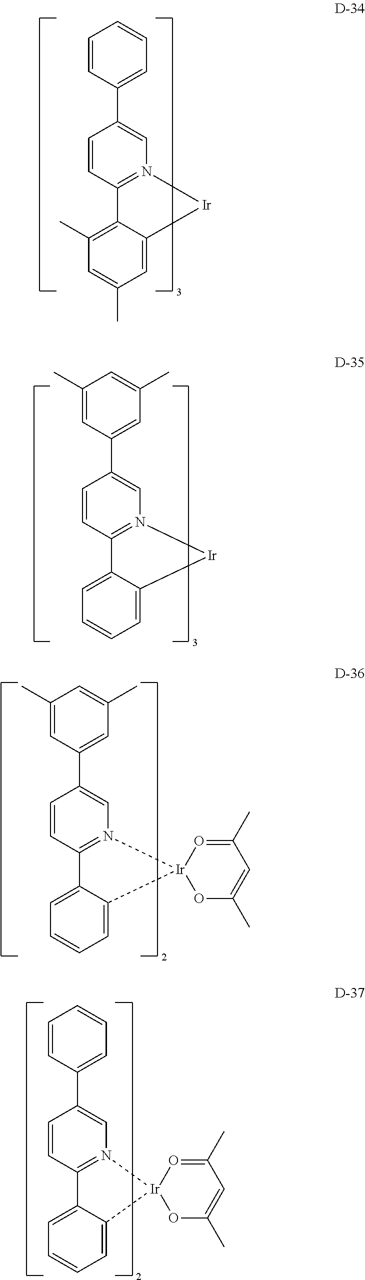

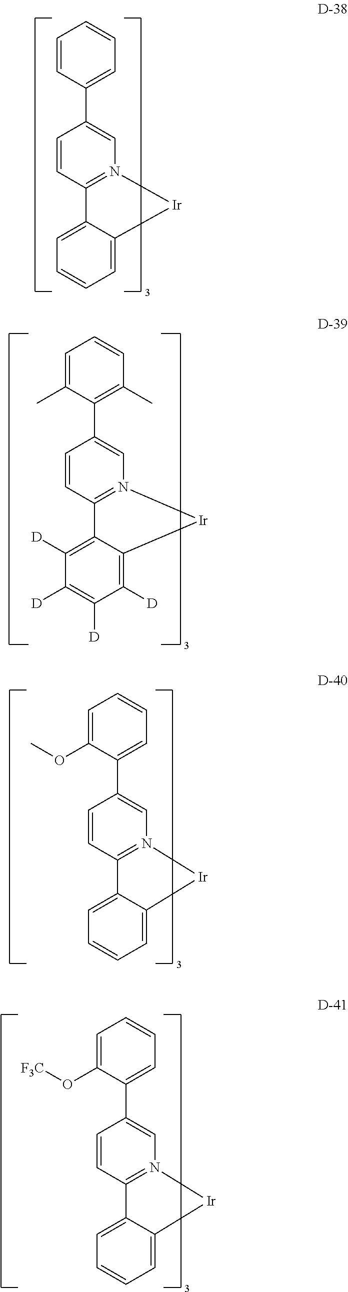

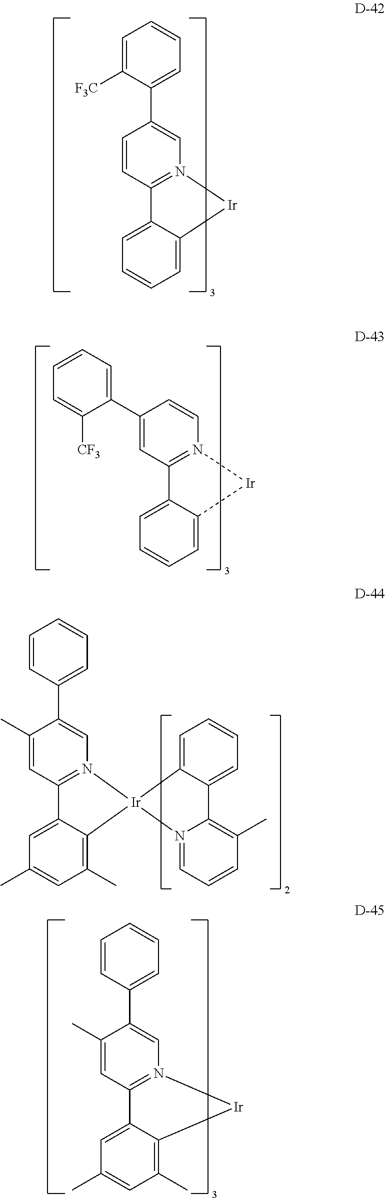

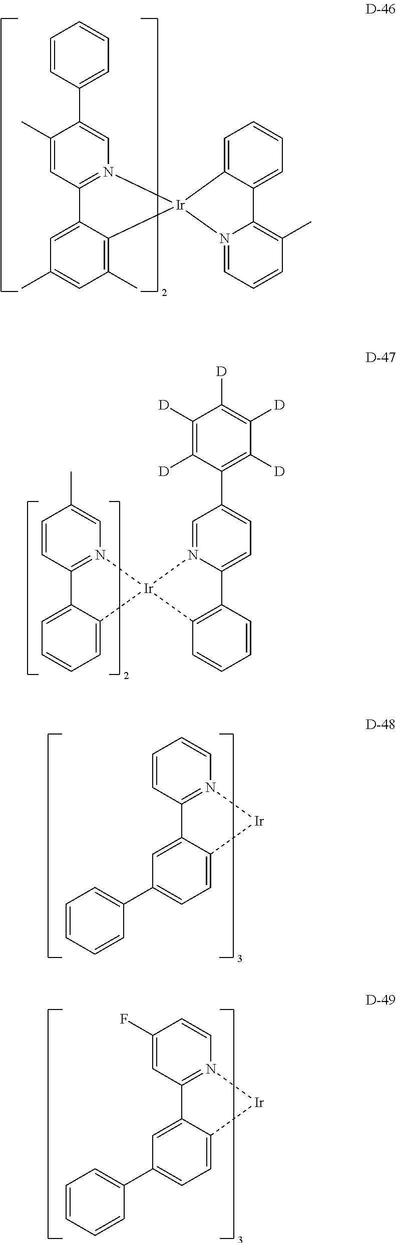

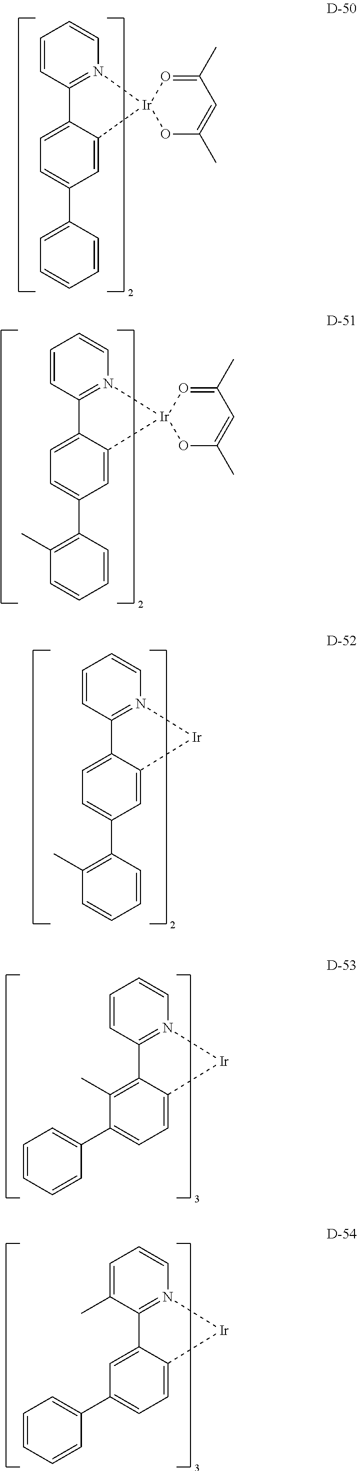

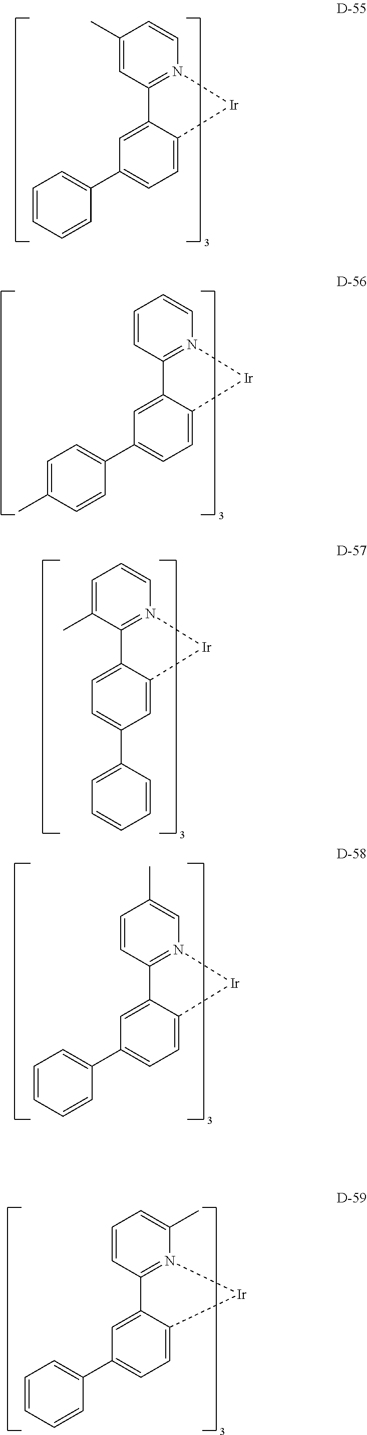

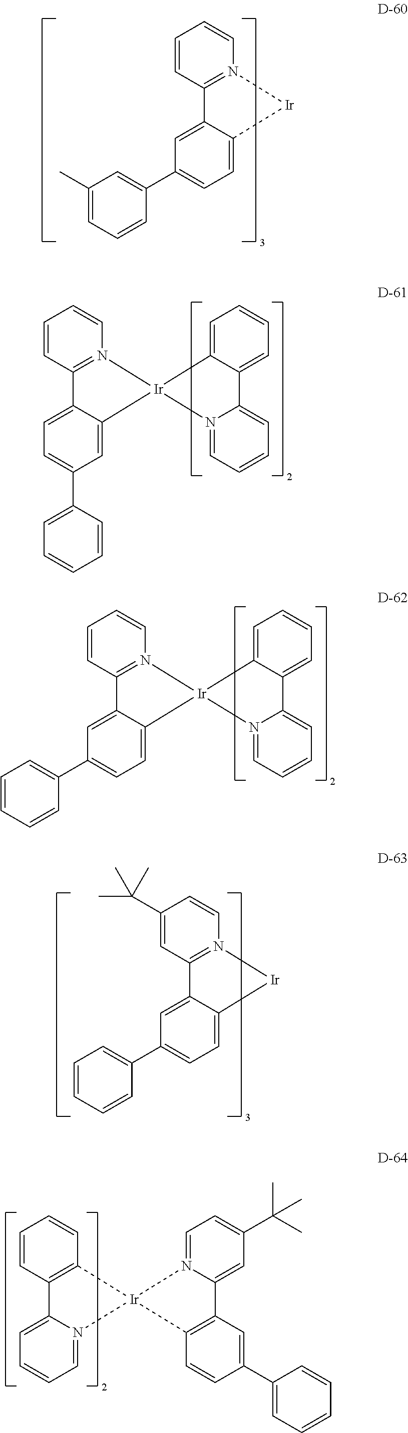

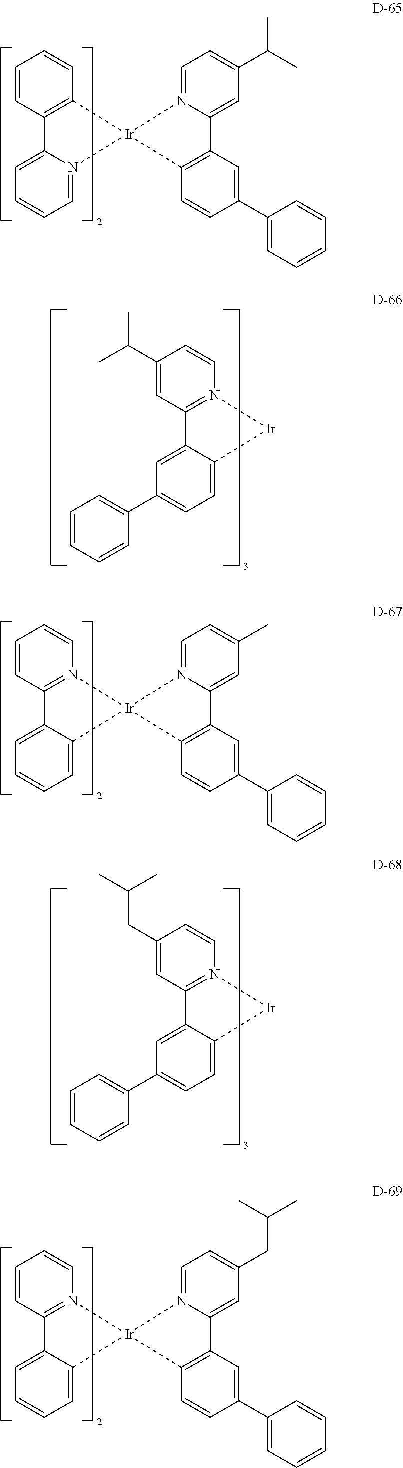

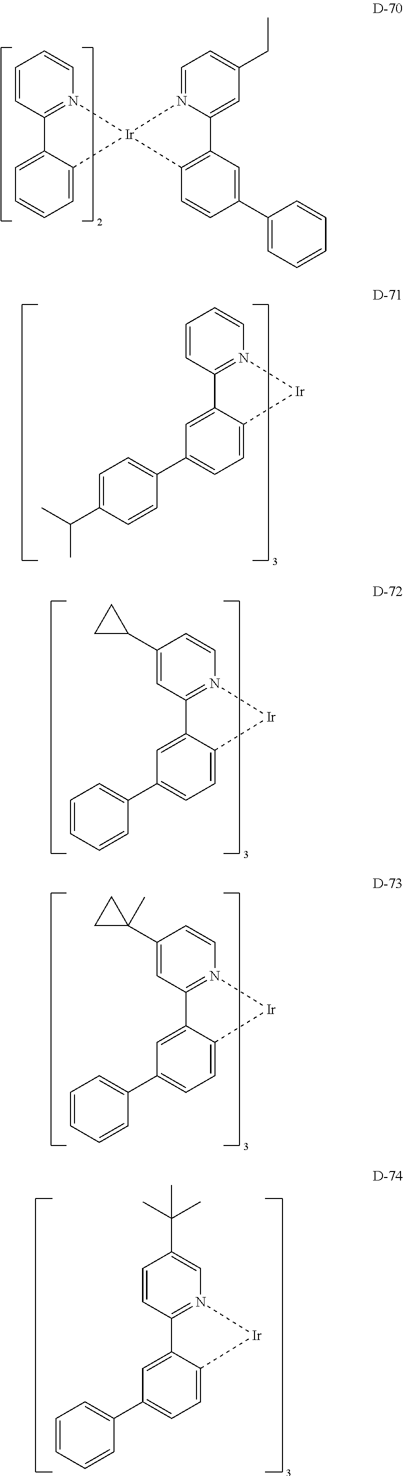

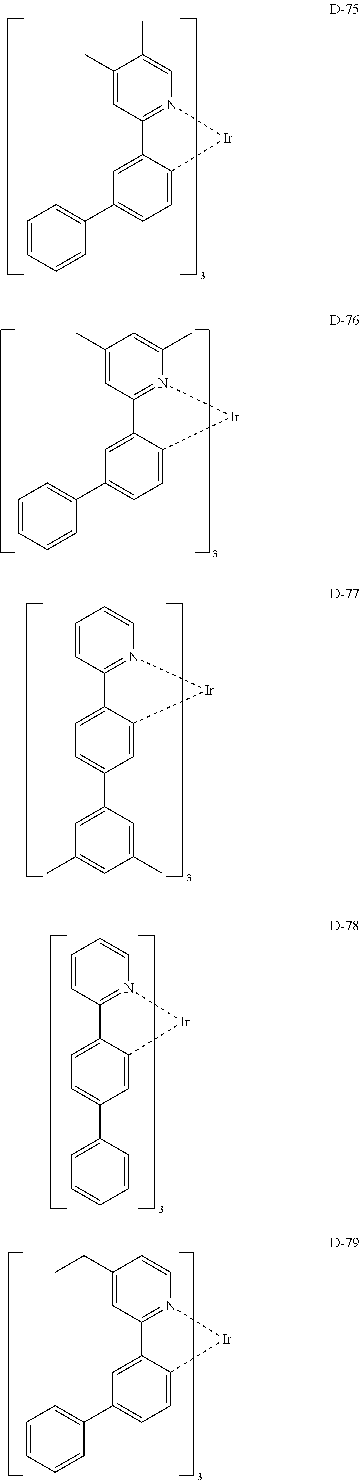

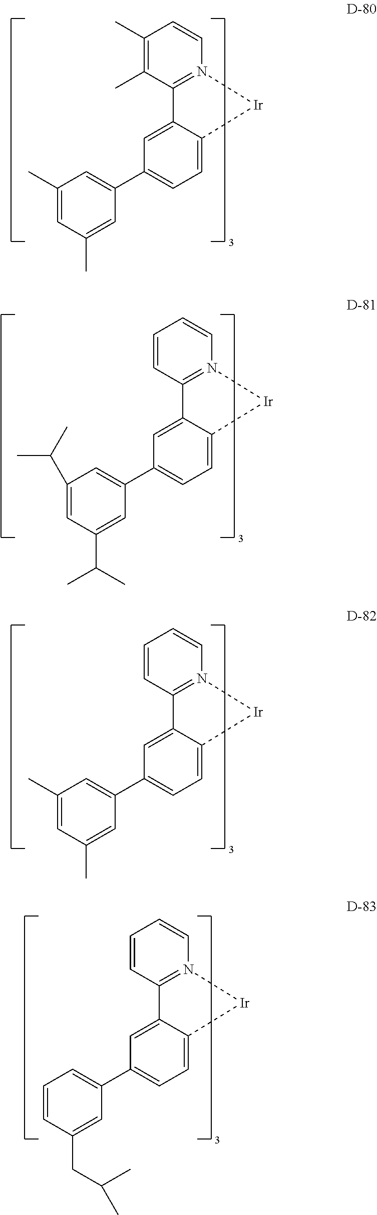

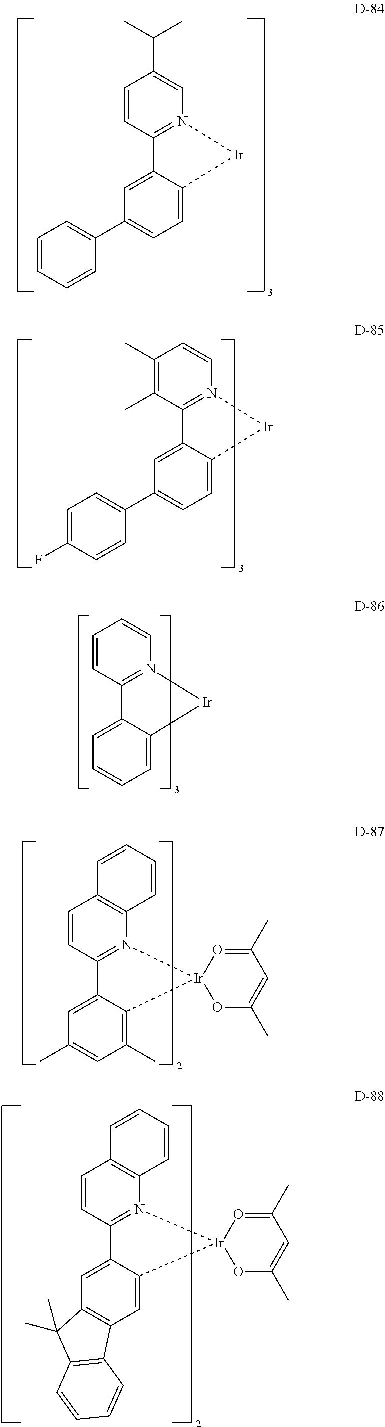

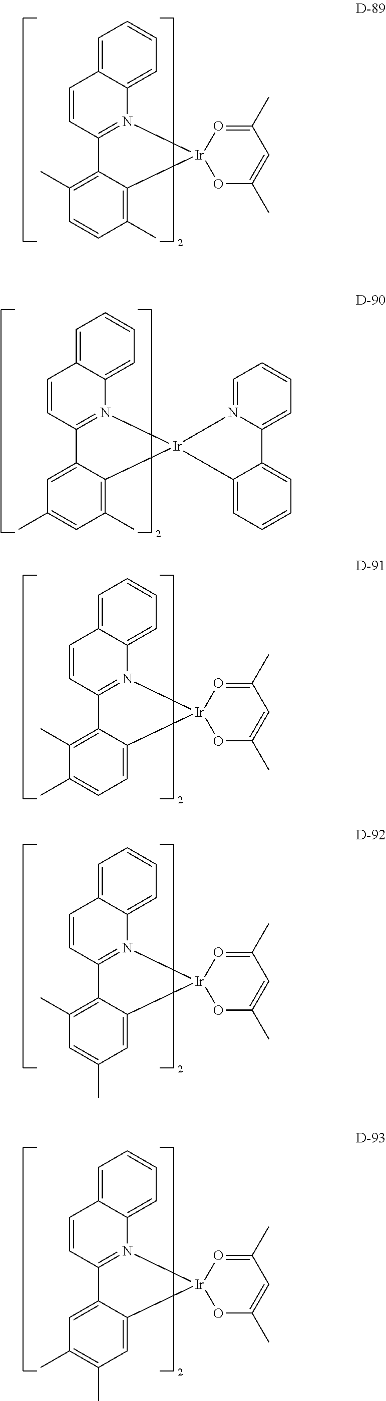

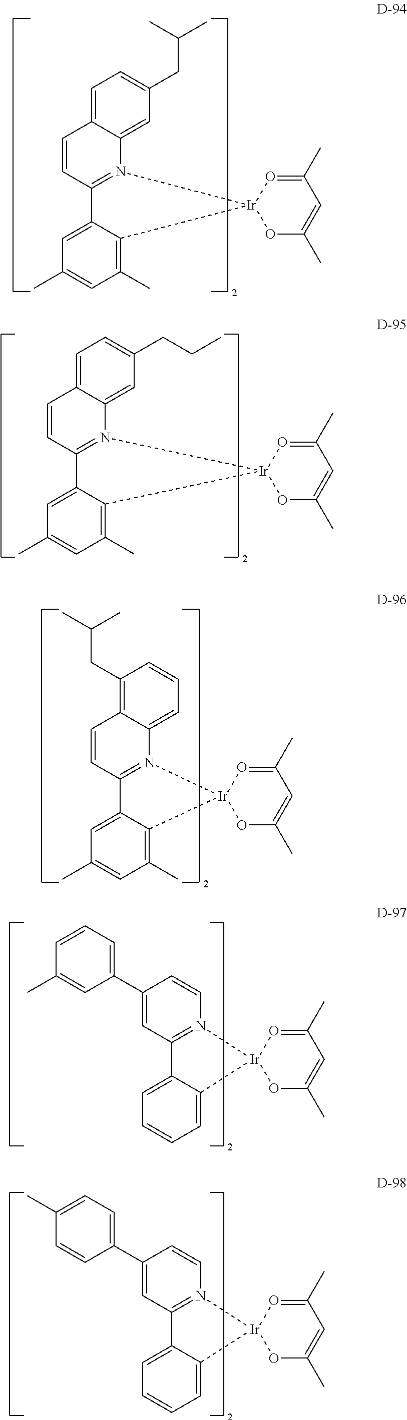

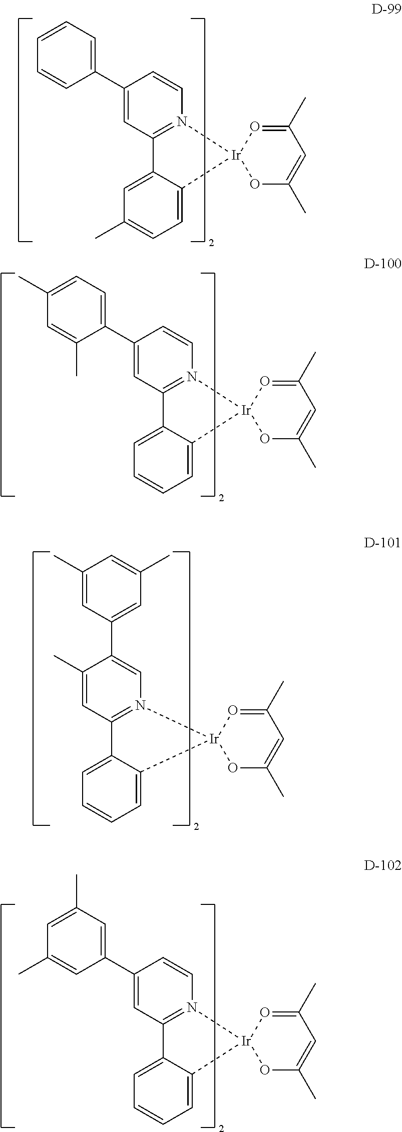

The organic layer of the organic electroluminescent device according to the present invention may further comprise, in addition to the organic electroluminescent compounds represented by formula 1, at least one compound selected from the group consisting of arylamine-based compounds and styrylarylamine-based compounds.

In the organic electroluminescent device according to the present invention, the organic layer may further comprise at least one metal selected from the group consisting of metals of Group 1, metals of Group 2, transition metals of the 4^{th} period, transition metals of the 5^{th} period, lanthanides and organic metals of d-transition elements of the Periodic Table, or at least one complex compound comprising said metal. The organic layer may comprise a light-emitting layer and a charge generating layer.

In addition, the organic electroluminescent device according to the present invention may emit white light by further comprising at least one light-emitting layer which comprises a blue electroluminescent compound, a red electroluminescent compound or a green electroluminescent compound known in the field, besides the organic electroluminescent compound according to the present invention. Also, if needed, a yellow or orange light-emitting layer can be comprised in the device.

According to the present invention, at least one layer (hereinafter, “a surface layer”) of the organic electroluminescent device preferably selected from a chalcogenide layer, a metal halide layer and a metal oxide layer; may be placed on an inner surface(s) of one or both electrode(s). Specifically, a chalcogenide(includes oxides) layer of silicon or aluminum is preferably placed on an anode surface of an electroluminescent medium layer, and a metal halide layer or a metal oxide layer is placed on a cathode surface of an electroluminescent medium layer. Such a surface layer provides operation stability for the organic electroluminescent device. Preferably, said chalcogenide includes SiOₓ(1≦X≦2), AlOₓ(1≦X≦1.5), SiON, SiAION, etc.; said metal halide includes LiF, MgF₂, CaF₂, a rare earth metal fluoride, etc.; and said metal oxide includes Cs₂O, Li₂O, MgO, SrO, BaO, CaO, etc.

Preferably, in the organic electroluminescent device according to the present invention, a mixed region of an electron transport compound and an reductive dopant, or a mixed region of a hole transport compound and an oxidative dopant may be placed on at least one surface of a pair of electrodes. In this case, the electron transport compound is reduced to an anion, and thus it becomes easier to inject and transport electrons from the mixed region to an electroluminescent medium. Further, the hole transport compound is oxidized to a cation, and thus it becomes easier to inject and transport holes from the mixed region to the electroluminescent medium. Preferably, the oxidative dopant includes various Lewis acids and acceptor compounds; and the reductive dopant includes alkali metals, alkali metal compounds, alkaline earth metals, rare-earth metals, and mixtures thereof. A reductive dopant layer may be employed as a charge generating layer to prepare an electroluminescent device having two or more electroluminescent layers and emitting white light.

As for the formation of the layers of the organic electroluminescent device according to the present invention, dry film-forming methods such as vacuum evaporation, sputtering, plasma and ion plating methods, or wet film-forming methods such as spin coating, dipping, flow coating methods can be used.

When applying a wet film-forming method, a thin film can be formed by dissolving or diffusing materials forming each layer into any suitable solvent such as ethanol, chloroform, tetrahydrofuran, dioxane, etc. The solvent can be any solvent where the materials forming each layer can be dissolved or diffused.

Hereinafter, the organic electroluminescent compound, the preparation method of the compound, and the luminescent properties of the device comprising the compound of the present invention will be explained in detail with reference to the following examples:

### EXAMPLE 1

### Preparation of Compound C-17

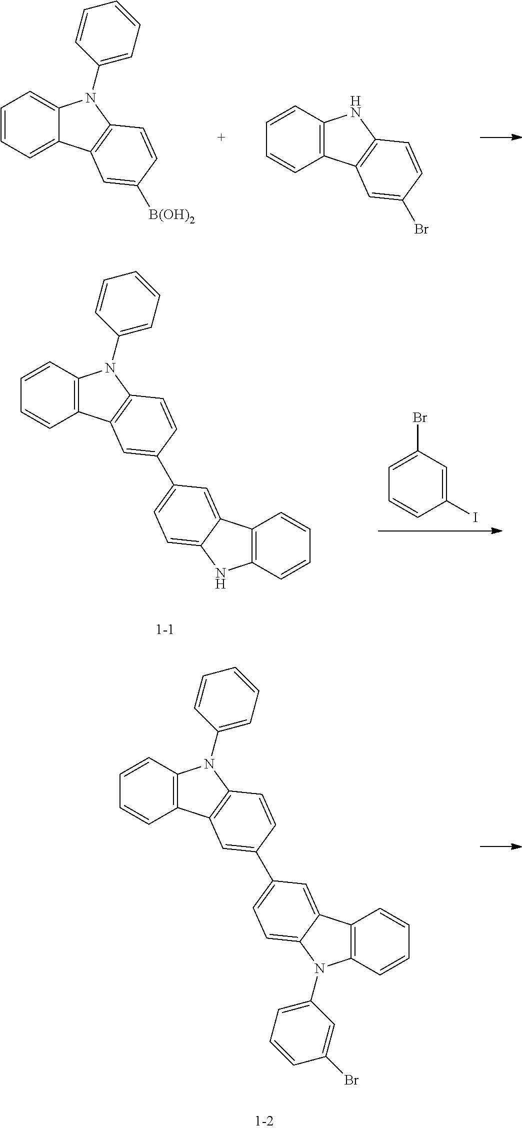 [SMILES: OB(O)c1ccc2c(c1)c1ccccc1n2-c1ccccc1 ; Brc1ccc2[nH]c3ccccc3c2c1 ; c1ccc(-n2c3ccccc3c3cc(-c4ccc5[nH]c6ccccc6c5c4)ccc32)cc1 ; Brc1cccc(I)c1 ; Brc1cccc(-n2c3ccccc3c3cc(-c4ccc5c(c4)c4ccccc4n5-c4ccccc4)ccc32)c1]

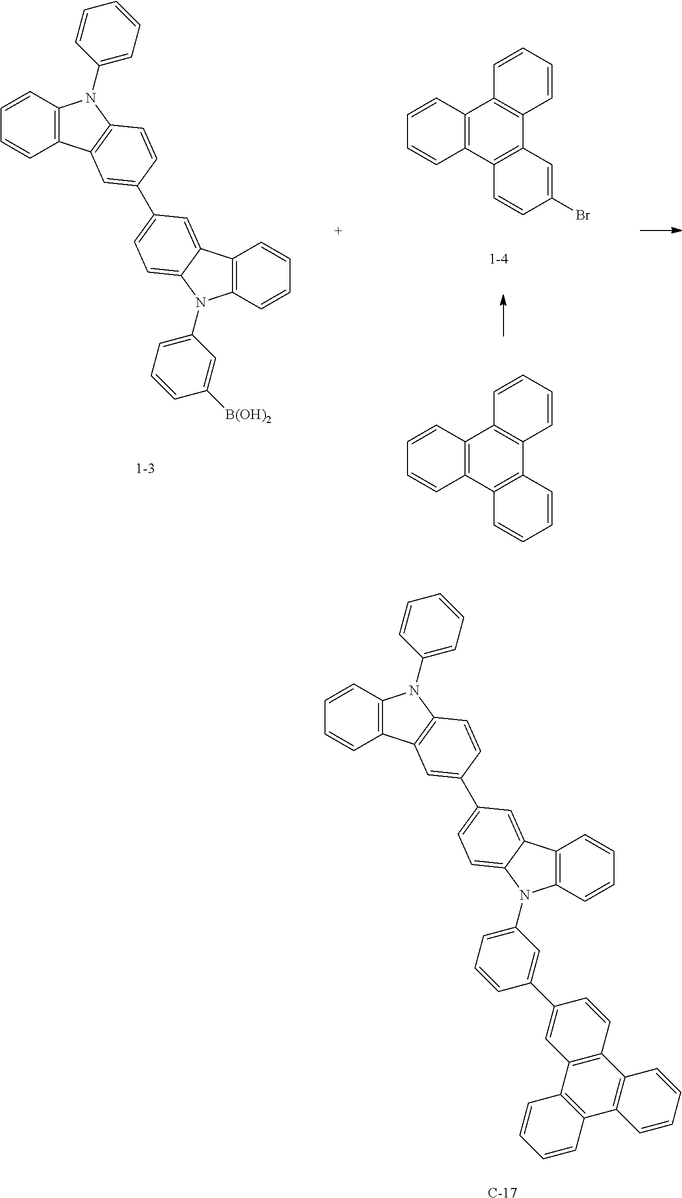

### Preparation of Compound 1-1

After mixing (9-phenyl-9H-carbazol-3-yl)boronic acid (36 g, 0.13 mol), 3-bromo-9H-carbazole (25.7 g, 0.11 mol), 2 M K₂CO₃ (125 mL), toluene (500 mL), and ethanol (125 mL), Pd(PPh₃)₄ (6.0 g, 0.005 mol) was added to the mixture. Then, the mixture was stirred for 5 hours at 120° C. After completing the reaction, the mixture was cooled to room temperature and distilled water (200 mL) was added, then the mixture was extracted with ethyl acetate (EA) (800 mL). Then, the organic layer was dried with anhydrous MgSO₄ to remove the remaining moisture, then distillated under reduced pressure, and then separated through a column to obtain compound 1-1 (38 g, 85%).

### Preparation of Compound 1-2

After mixing compound 1-1 (25.4 g, 0.062 mol), 1,3-dibromobenzene (44 g, 0.186 mol), CuI (5.9 g, 0.031 mmol), ethylene diamine (EDA) (4.1 mL, 0.062 mol), K₃PO₄ (40.5 g, 0.186 mol) and toluene (500 mL), the mixture was stirred for 12 hours at 120° C. After completing the reaction, the mixture was washed with distilled water and then extracted with EA. The remaining product was dried with anhydrous MgSO₄ to remove the remaining moisture, then distillated under reduced pressure and then separated through a column to obtain compound 1-2 (21.5 g, 61%).

### Preparation of Compound 1-3

After putting compound 1-2 (21.3 g, 37.80 mmol) in a flask, and vacuum drying the compound, nitrogen gas was filled and then tetrahydrofuran (THF) (400 mL) was added. The mixture was cooled to −78° C., then n-buLi (19.6mL, 49.14 mmol, 2.5 M in hexane) was slowly added to the mixture at the same temperature. After stirring the mixture for 1 hour, B(i-pro)₃ (6.3 mL, 56.70 mmol) was added to the mixture at the same temperature, then the mixture was stirred for 12 hours. After completing the reaction, 1 M HCl (36 mL) was added to the mixture, and after 10 minutes, distilled water was added. Then the mixture was extracted with EA. The organic layer was dried with anhydrous MgSO₄ to remove the remaining moisture, then distillated under reduced pressure, and then separated through a column to obtain compound 1-3 (14.5 g, 72%).

### Preparation of Compound 1-4

While slowly adding Br₂ (11.2 mL, 0.219 mol) and methylene chloride (MC) (2.1 L) to triphenylene (50 g, 0.219 mol), the mixture was stirred for 12 hours under room temperature. After completing the reaction, distilled water was added, then the mixture was extracted with EA. The organic layer was dried with anhydrous MgSO₄ to remove the remaining moisture, then distillated under reduced pressure, and then washed with hexane to obtain compound 1-4 (30 g, 44%).

### Preparation of Compound C-17

After mixing compound 1-4 (5 g, 0.016 mol), compound 1-3 (10.3 g, 0.019 mol), Pd(PPh₃)₄ (940 mg, 0.81 mmol), 2 M K₂CO₃ (25 mL), ethanol (25 mL) and toluene (50 mL), the mixture was stirred for 5 hours at 120° C. After completing the reaction, distilled water was added, and then the mixture was extracted with EA. Then, the organic layer was dried with anhydrous MgSO₄ to remove the remaining moisture, then distillated under reduced pressure, and then separated through a column to obtain compound C-17 (2.9 g, 26%).

MS/EIMS found 710.86; calculated 710.27

### DEVICE EXAMPLE 1

### Production of an OLED Device Using the Compound According to the Present Invention

An OLED device was produced using the compound according to the present invention. A transparent electrode indium tin oxide (ITO) thin film (15 Ω/sq) on a glass substrate for an organic light-emitting diode (OLED) device (Samsung Corning, Republic of Korea) was subjected to an ultrasonic washing with trichloroethylene, acetone, ethanol and distilled water, sequentially, and then was stored in isopropanol. Then, the ITO substrate was mounted on a substrate holder of a vacuum vapor depositing apparatus. 4,4′,4″-tris(N,N-(2-naphthyl)-phenylamino)triphenylamine was introduced into a cell of said vacuum vapor depositing apparatus, and then the pressure in the chamber of said apparatus was controlled to 10⁻⁶ torr. Thereafter, an electric current was applied to the cell to evaporate the above introduced material, thereby forming a hole injection layer having a thickness of 50 nm on the ITO substrate. Then, N,N′-di(4-biphenyl)-N,N′-di(4-biphenyl)-4,4′-diaminobiphenyl was introduced into another cell of said vacuum vapor depositing apparatus, and was evaporated by applying an electric current to the cell, thereby forming a hole transport layer having a thickness of 20 nm on the hole injection layer. Thereafter, compound C-17 was introduced into one cell of the vacuum vapor depositing apparatus, as a host material, and 9-(4-(4,6-diphenyl-1,3,5-triazin-2-yl)phenyl)-9H-carbazole was introduced into another cell as another host material, and the two materials were evaporated at the same rate, and was used as a host material. Compound D-41 was introduced as a dopant, and the dopant was evaporated and deposited in a doping amount of 15 wt % based on the total amount of the host and dopant to form a light-emitting layer having a thickness of 30 nm on the hole transport layer. Then, 2-(4-(9,10-di(naphthalen-2-yl)anthracen-2-yl)phenyl)-1-phenyl-1H-benzo[d]imidazole was introduced into a cell, and evaporated to form an electron transport layer having a thickness of 40 nm on the light-emitting layer. Then, after depositing lithium quinolate as an electron injection layer having a thickness of 2 nm on the electron transport layer, an Al cathode having a thickness of 150 nm was deposited by another vacuum vapor deposition apparatus on the electron injection layer. Thus, an OLED device was produced. All the materials used for producing the OLED device were purified by vacuum sublimation at 10⁻⁶ torr prior to use.

The produced OLED device showed a green emission having a luminance of 1260 cd/m² and a current density of 4.2 mA/cm² at a driving voltage of 5.1 V.

### COMPARATIVE EXAMPLE 1

### Production of an OLED Device Using Conventional Electroluminescent Compounds

An OLED device was produced in the same manner as in Device Example 1, except that 4,4′-bis(carbazol-9-yl)biphenyl (CBP), instead of the compound according to the present invention, was introduced into the cell of the vacuum vapor depositing apparatus as a host material, and compound D-41 was used as a dopant; and a hole blocking layer having a thickness of 10 nm was deposited between the light-emitting layer and the electron transport layer by using aluminum(III)bis(2-methyl-8-quinolinato)4-phenylphenolate (BAIq).

The produced OLED device showed a green emission having a luminance of 5015 cd/m² and a current density of 24.2 mA/cm² at a driving voltage of 7.9 V.

It is verified that the organic electroluminescent compounds according to the present invention have superior luminous efficiency over conventional materials. In addition, the organic electroluminescent devices using the compounds according to the present invention as a light-emitting host material have not only superior luminous efficiency but also can improve the power efficiency of the device and reduce overall power consumption by lowering driving voltages.

1. An organic electroluminescent compound represented by the following formula 1: 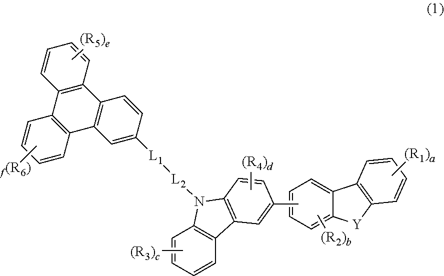
wherein
L₁ and L₂ each independently represent a single bond, a substituted or unsubstituted 3- to 30-membered heteroarylene group, or a substituted or unsubstituted (C6-C30)arylene group, provided that L₁ and L₂ are not simultaneously single bonds;
Y represents —O—, —S—, —CR₇R₈— or —NR₉—;
R₁ to R₉ each independently represent hydrogen, deuterium, a halogen, a substituted or unsubstituted (C1-C30)alkyl group, a substituted or unsubstituted (C6-C30)aryl group, a substituted or unsubstituted 3- to 30-membered heteroaryl group, a substituted or unsubstituted (C3-C30)cycloalkyl group, a substituted or unsubstituted 5- to 7-membered heterocycloalkyl group, a (C6-C30)cycloalkyl group fused with one or more aromatic rings, —NR₁₀R₁₁, —SR₁₂, —OR₁₃ or —SiR₁₄R₁₅R₁₆;
R₁₀ to R₁₆ each independently represent hydrogen, deuterium, a halogen, a substituted or unsubstituted (C1-C30)alkyl group, a substituted or unsubstituted (C6-C30)aryl group, or a substituted or unsubstituted 3- to 30-membered heteroaryl group;
a, c, e and f each independently represent an integer of 1 to 4; where a, c, e and f are integers of 2 or more, each of R₁, R₃, R₅ and R₆ is the same or different;
b and d each independently represent an integer of 1 to 3; where b and d are integers of 2 or more, each of R₂ and R₄ is the same or different; and
the heterocycloalkyl group, the heteroarylene group and the heteroaryl group contain at least one hetero atom selected from B, N, O, S, P(═O), Si and P.

2. The organic electroluminescent compound according to claim 1, wherein the aryl(ene), heteroaryl(ene), alkyl, cycloalkyl and heterocycloalkyl groups in L₁, L₂, and R₁ to R₁₆ can be further substituted with at least one selected from the group consisting of deuterium; a halogen; a (C1-C30)alkyl group substituted or unsubstituted with a halogen; a (C6-C30)aryl group substituted or unsubstituted with a halogen; a 3- to 30-membered heteroaryl group substituted or unsubstituted with a (C1-C30)alkyl or a (C6-C30)aryl; a (C3-C30)cycloalkyl group; a (C6-C30)cycloalkyl group fused with one or more aromatic rings; a 5- to 7-membered heterocycloalkyl group; RₐR_{b}R_{c}Si—; a carbazolyl group; —NRₐRₑ; —BR_{f}R_{g}; —PRₕRᵢ; —P(═O)RⱼRₖ; a (C6-C30)aryl(C1-C30)alkyl group; a (C1-C30)alkyl(C6-C30)aryl group; a (C1-C30)alkoxy group; and a (C6-C30)aryloxy group, wherein Rₐ to Rₖ each independently represent a (C1-C30)alkyl group, a (C6-C30)aryl group, or a 3- to 30-membered heteroaryl group.

3. The organic electroluminescent compound according to claim 1, wherein the
moiety, 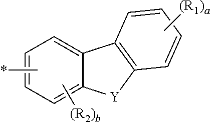
in formula 1 is selected from the following structures: 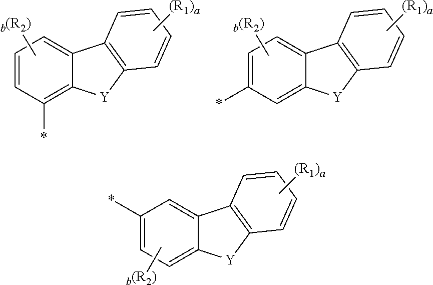
wherein R₁, R₂, Y, a and b are as defined in claim 1.

4. The organic electroluminescent compound according to claim 1, wherein
L₁ and L₂ each independently represent a single bond, a substituted or unsubstituted 3- to 30-membered heteroarylene group, or a substituted or unsubstituted (C6-C30)arylene group, provided that L₁ and L₂ are not simultaneously single bonds;
Y represents —O—, —S—, —CR₇R₈— or —NR₉—;
R₁ to R₉ each independently represent hydrogen, deuterium, a halogen, a substituted or unsubstituted (C1-C30)alkyl group, a substituted or unsubstituted (C6-C30)aryl group, or a substituted or unsubstituted 3- to 30- membered heteroaryl group; and
the heteroarylene and arylene groups in L₁ and L₂, and the alkyl, aryl and heteroaryl groups in R₁ to R₉ can be further substituted with at least one selected from the group consisting of deuterium; a halogen; a (C1-C30)alkyl group substituted or unsubstituted with a halogen; a (C6-C30)aryl group substituted or unsubstituted with a halogen; a 3- to 30-membered heteroaryl group substituted or unsubstituted with a (C1-C30)alkyl or a (C6-C30)aryl; a (C6-C30)aryl(C1-C30)alkyl group; and a (C1-C30)alkyl(C6-C30)aryl group.

5. The organic electroluminescent compound according to claim 1, wherein the compound represented by formula 1 is selected from the group consisting of:

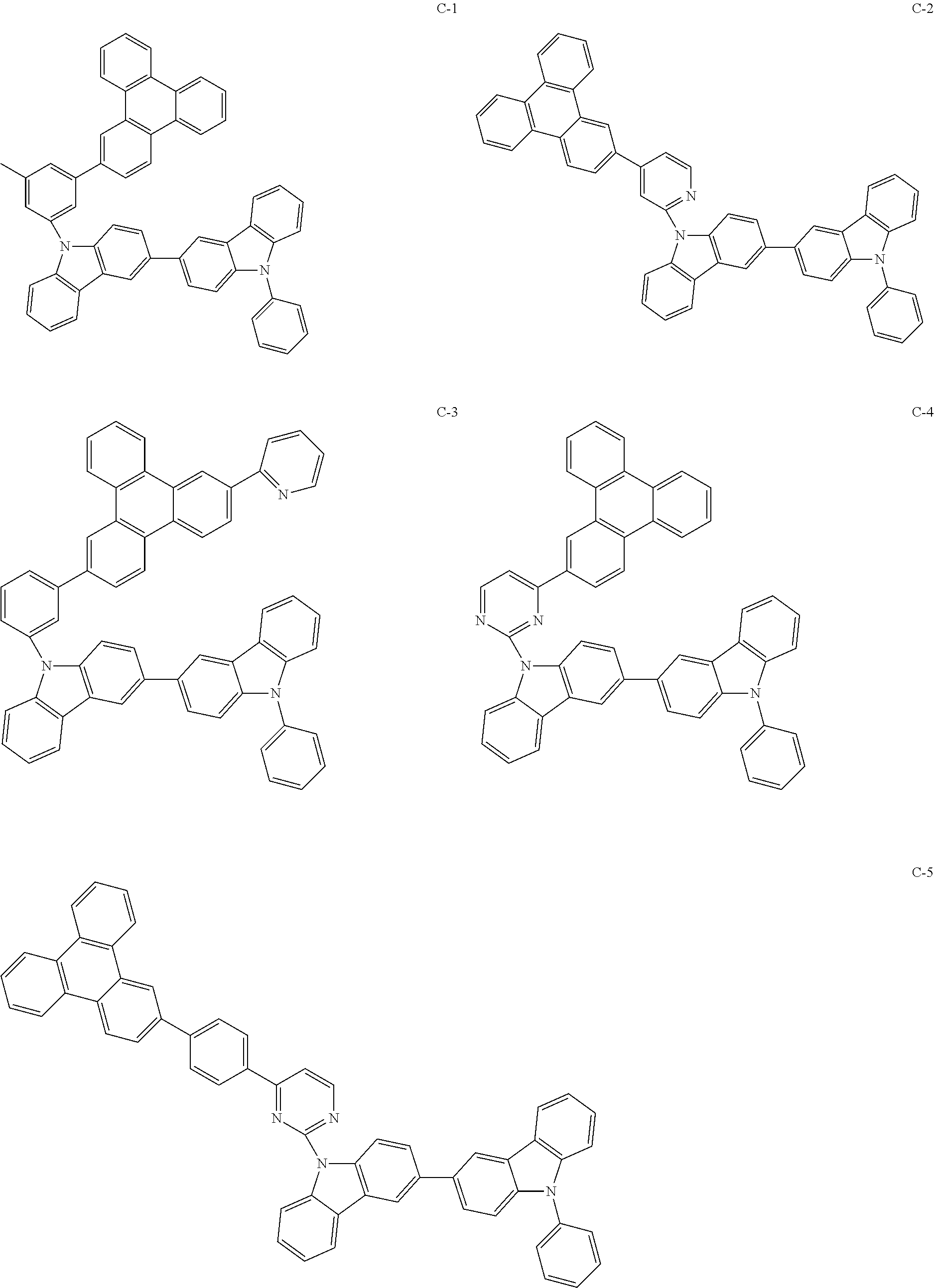 [SMILES: Cc1cc(-c2ccc3c4ccccc4c4ccccc4c3c2)cc(-n2c3ccccc3c3cc(-c4ccc5c(c4)c4ccccc4n5-c4ccccc4)ccc32)c1 ; c1ccc(-n2c3ccccc3c3cc(-c4ccc5c(c4)c4ccccc4n5-c4cc(-c5ccc6c7ccccc7c7ccccc7c6c5)ccn4)ccc32)cc1 ; c1ccc(-n2c3ccccc3c3cc(-c4ccc5c(c4)c4ccccc4n5-c4cccc(-c5ccc6c7ccc(-c8ccccn8)cc7c7ccccc7c6c5)c4)ccc32)cc1 ; c1ccc(-n2c3ccccc3c3cc(-c4ccc5c(c4)c4ccccc4n5-c4nccc(-c5ccc6c7ccccc7c7ccccc7c6c5)n4)ccc32)cc1 ; c1ccc(-n2c3ccccc3c3cc(-c4ccc5c(c4)c4ccccc4n5-c4nccc(-c5ccc(-c6ccc7c8ccccc8c8ccccc8c7c6)cc5)n4)ccc32)cc1]

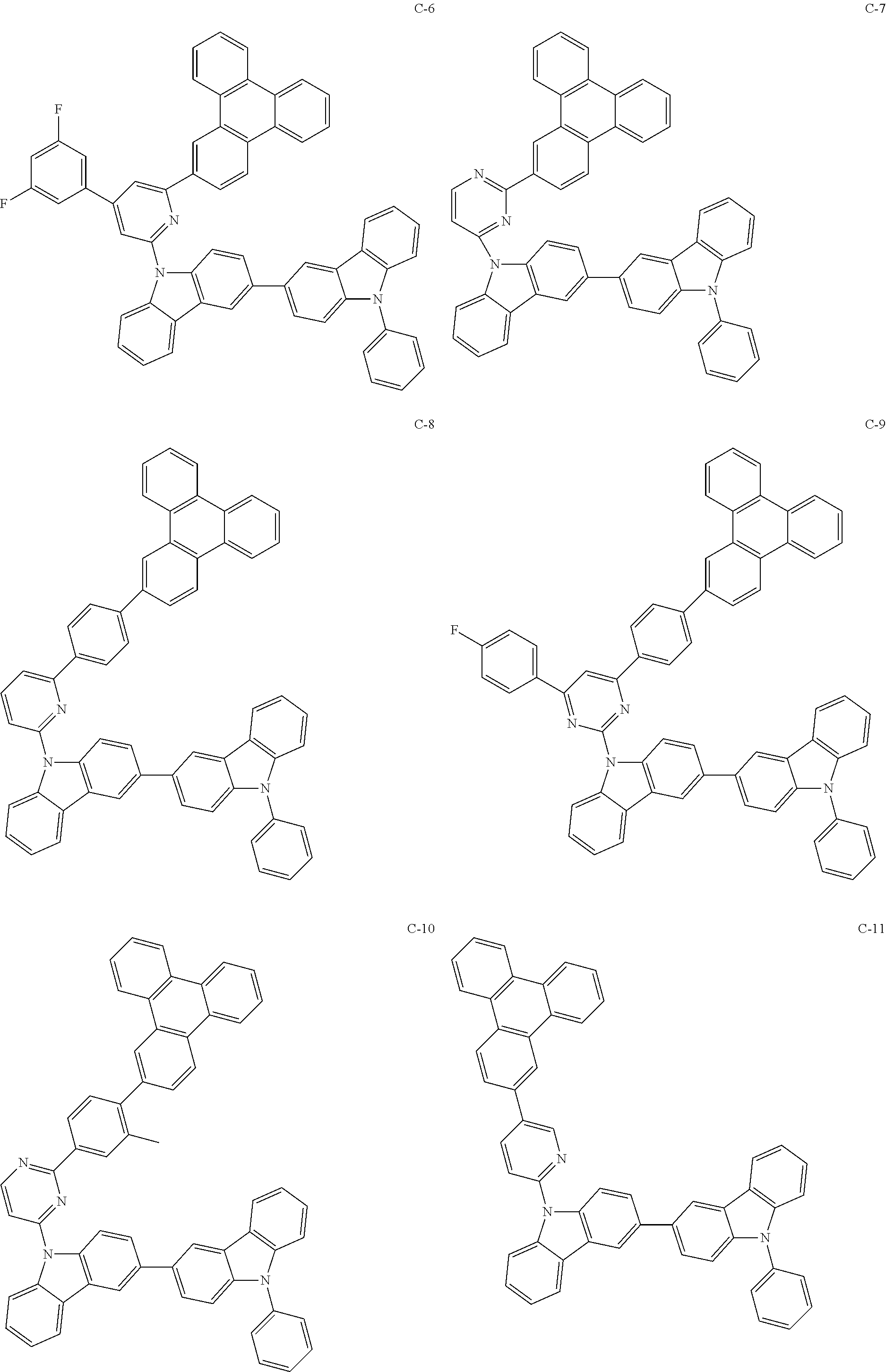

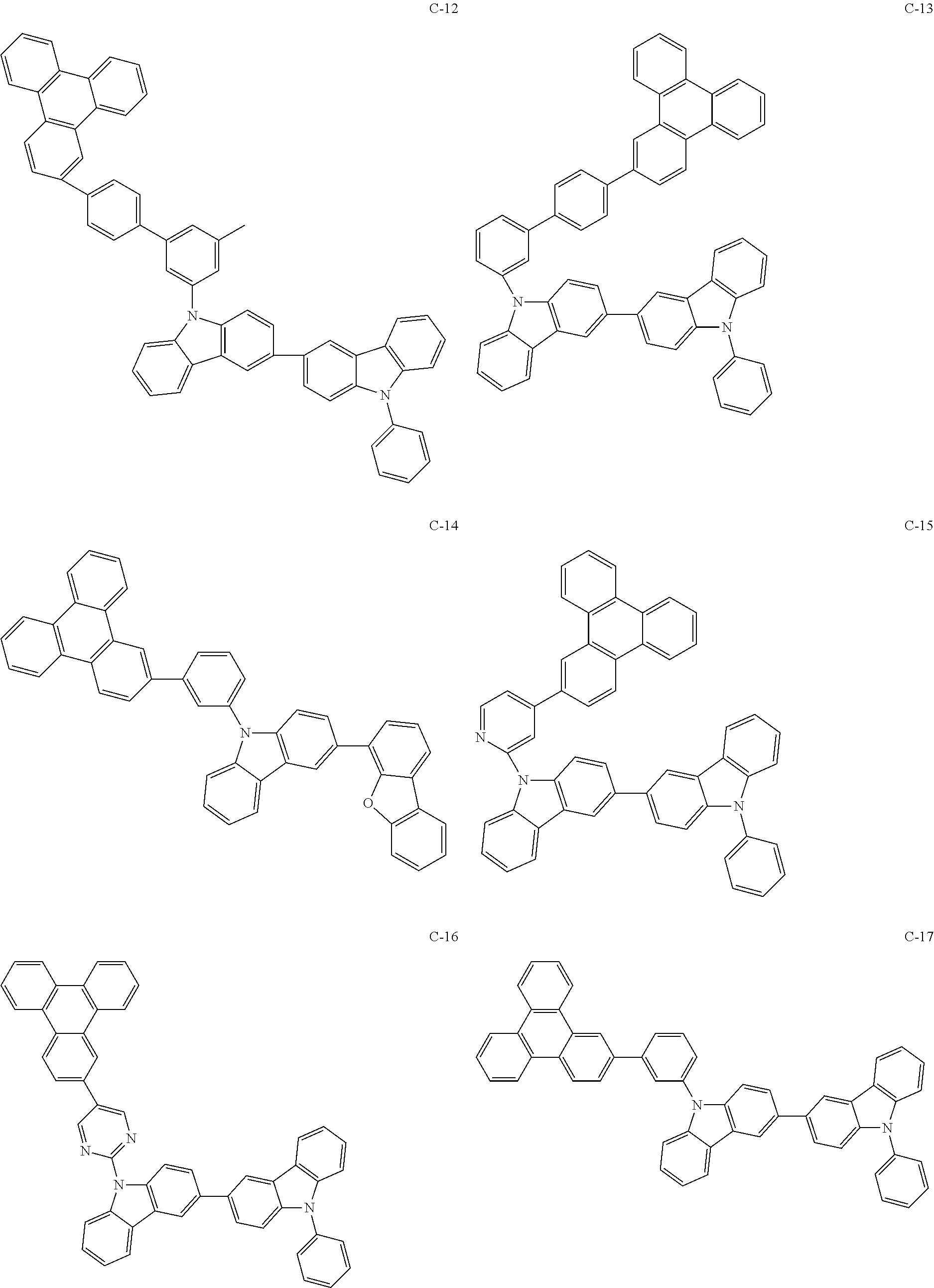

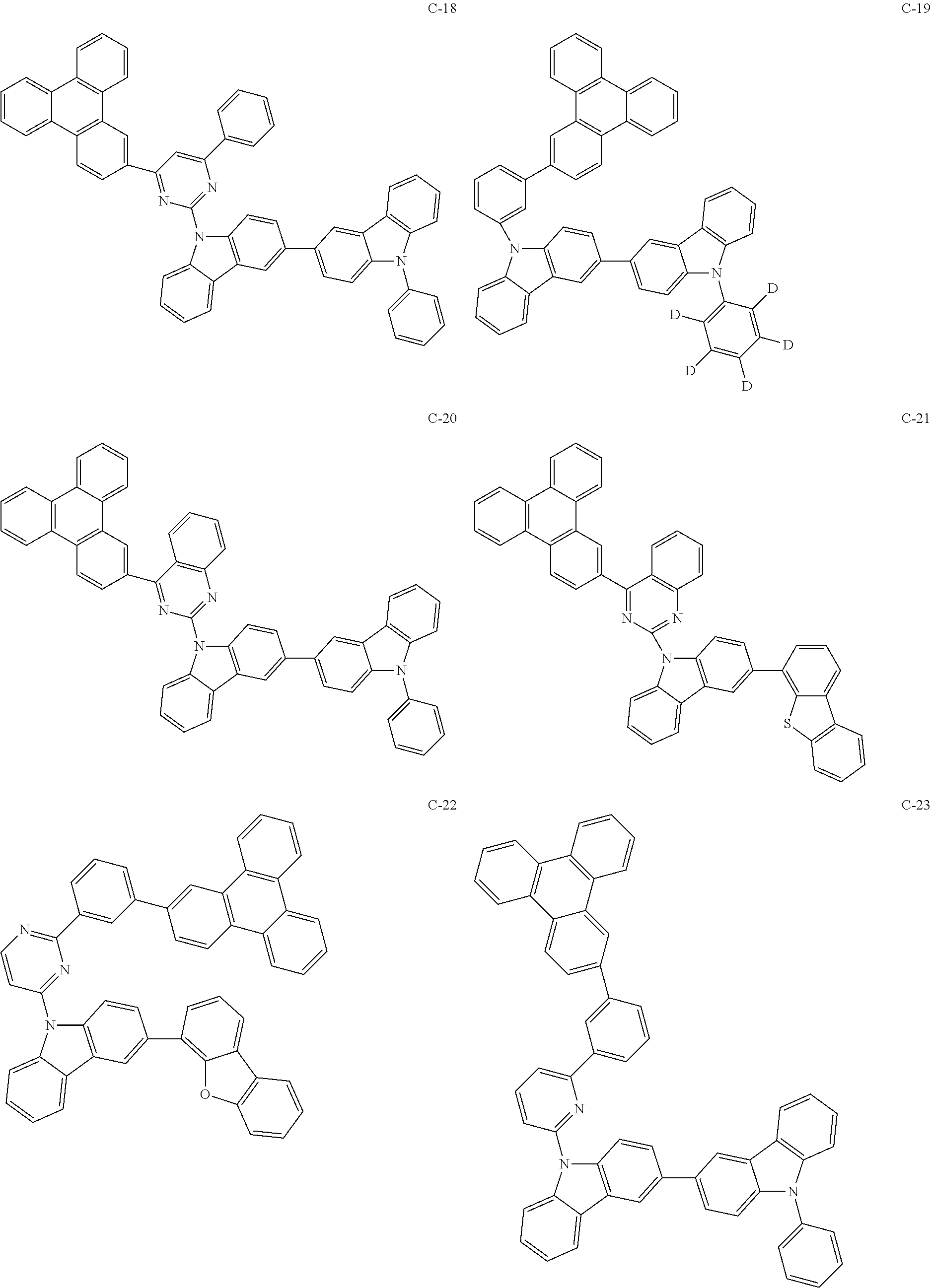

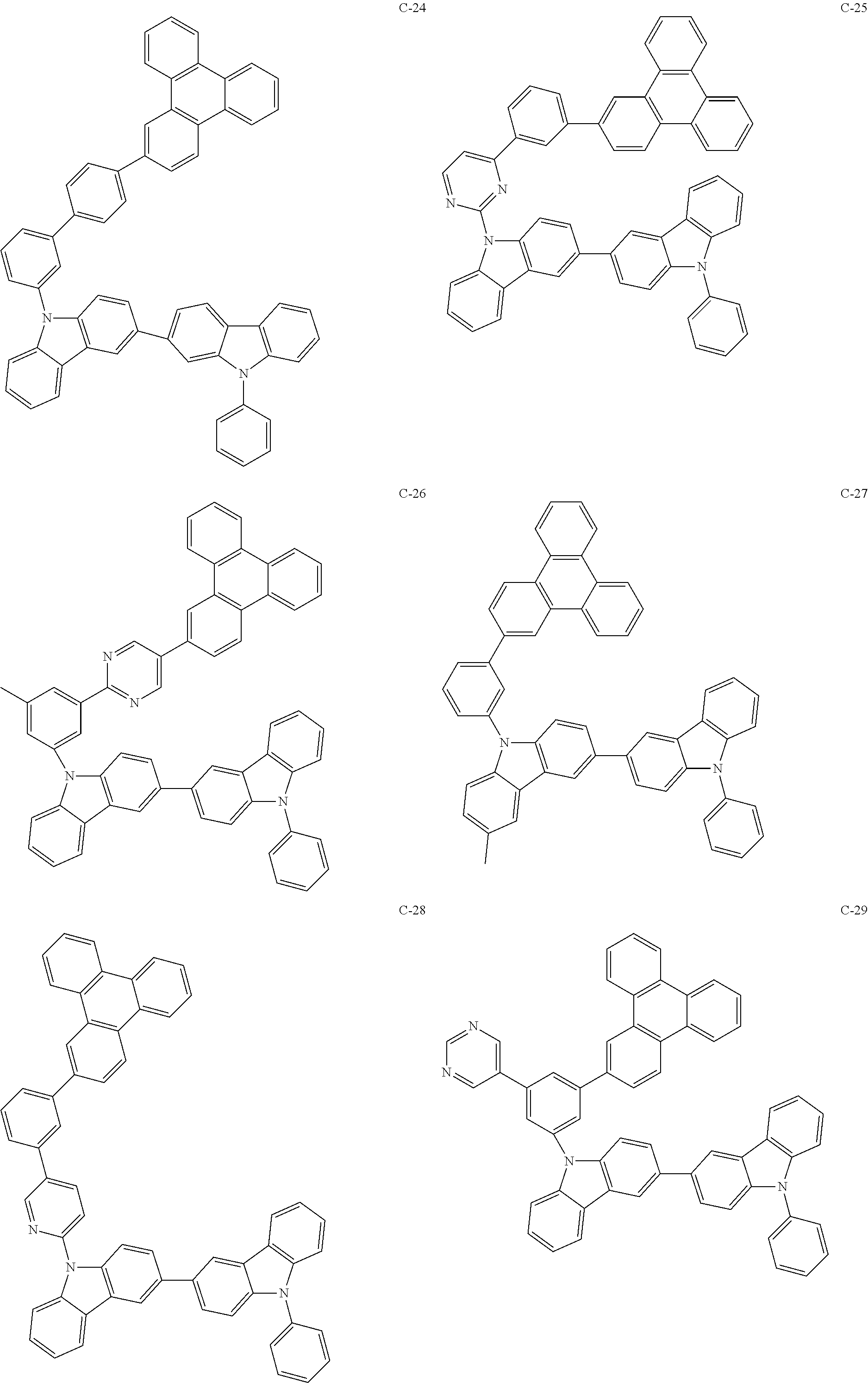

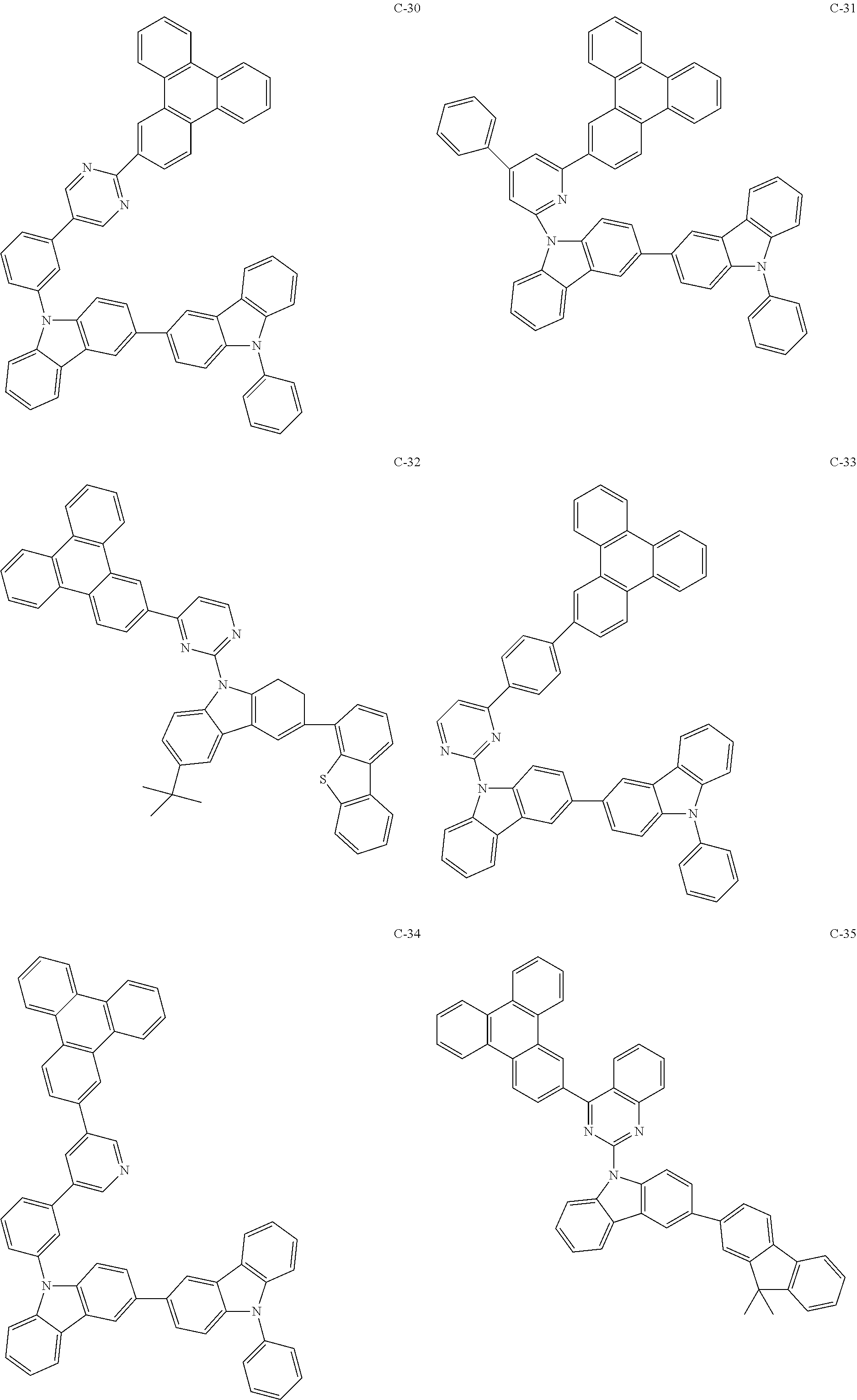

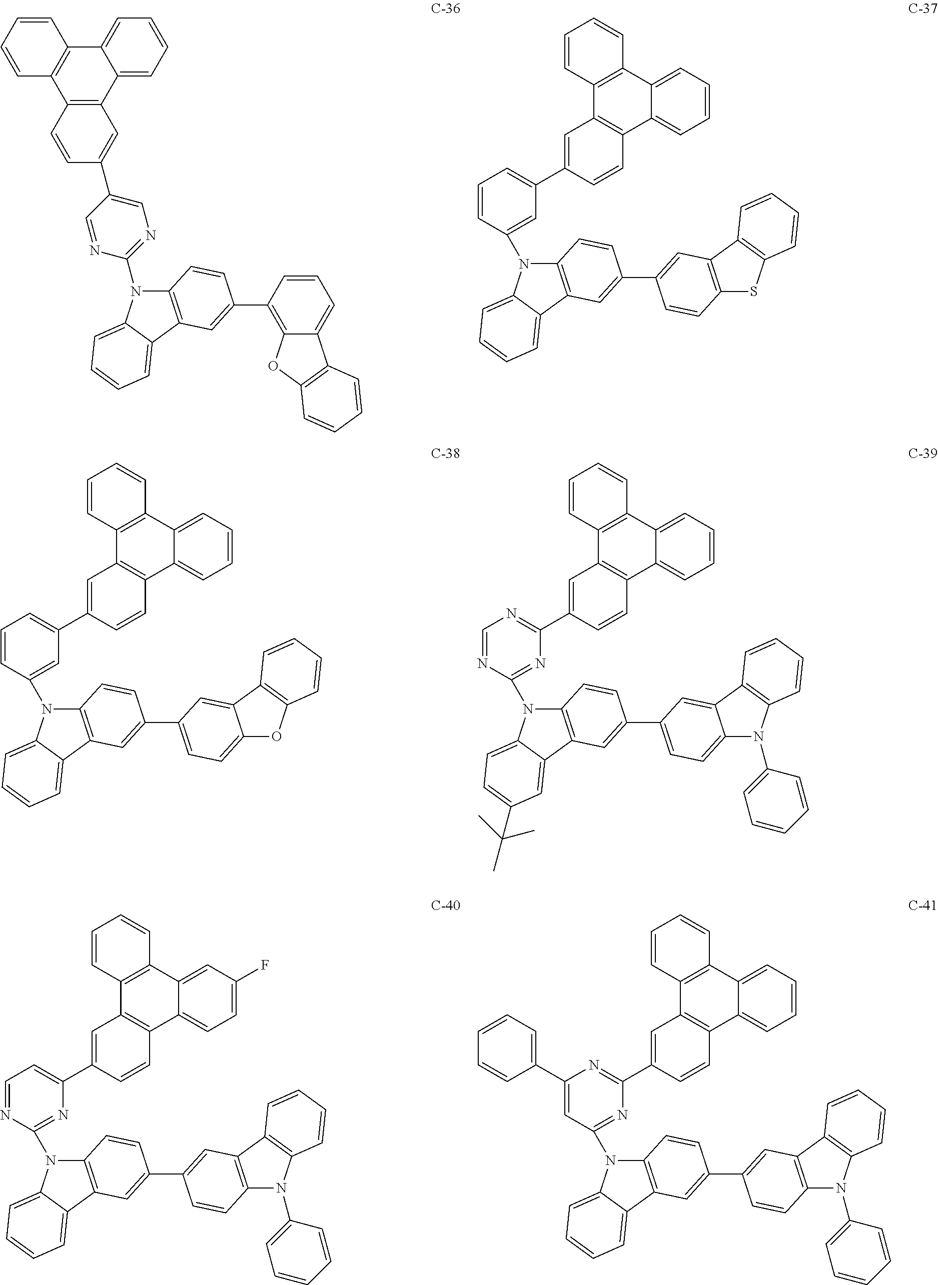

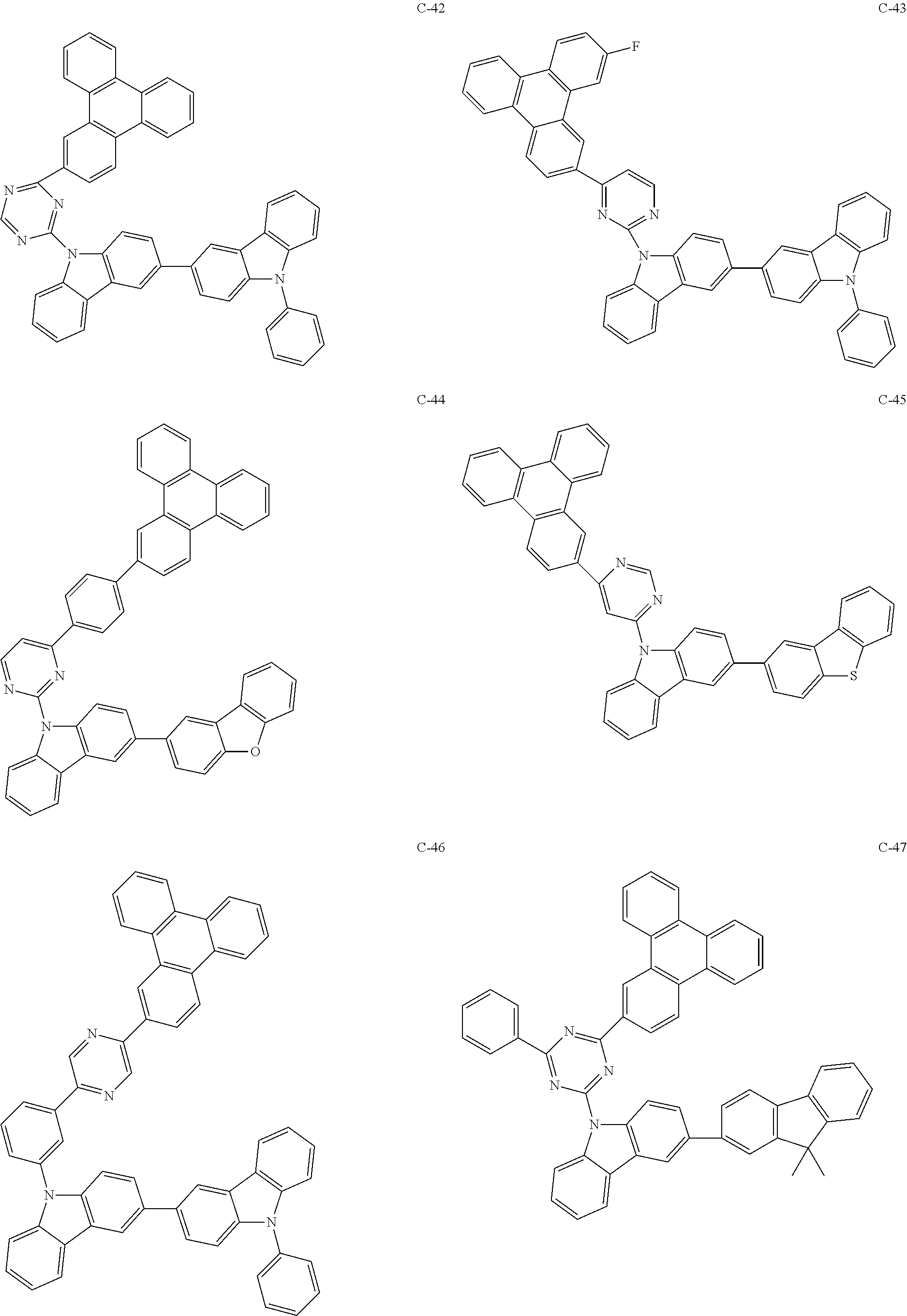

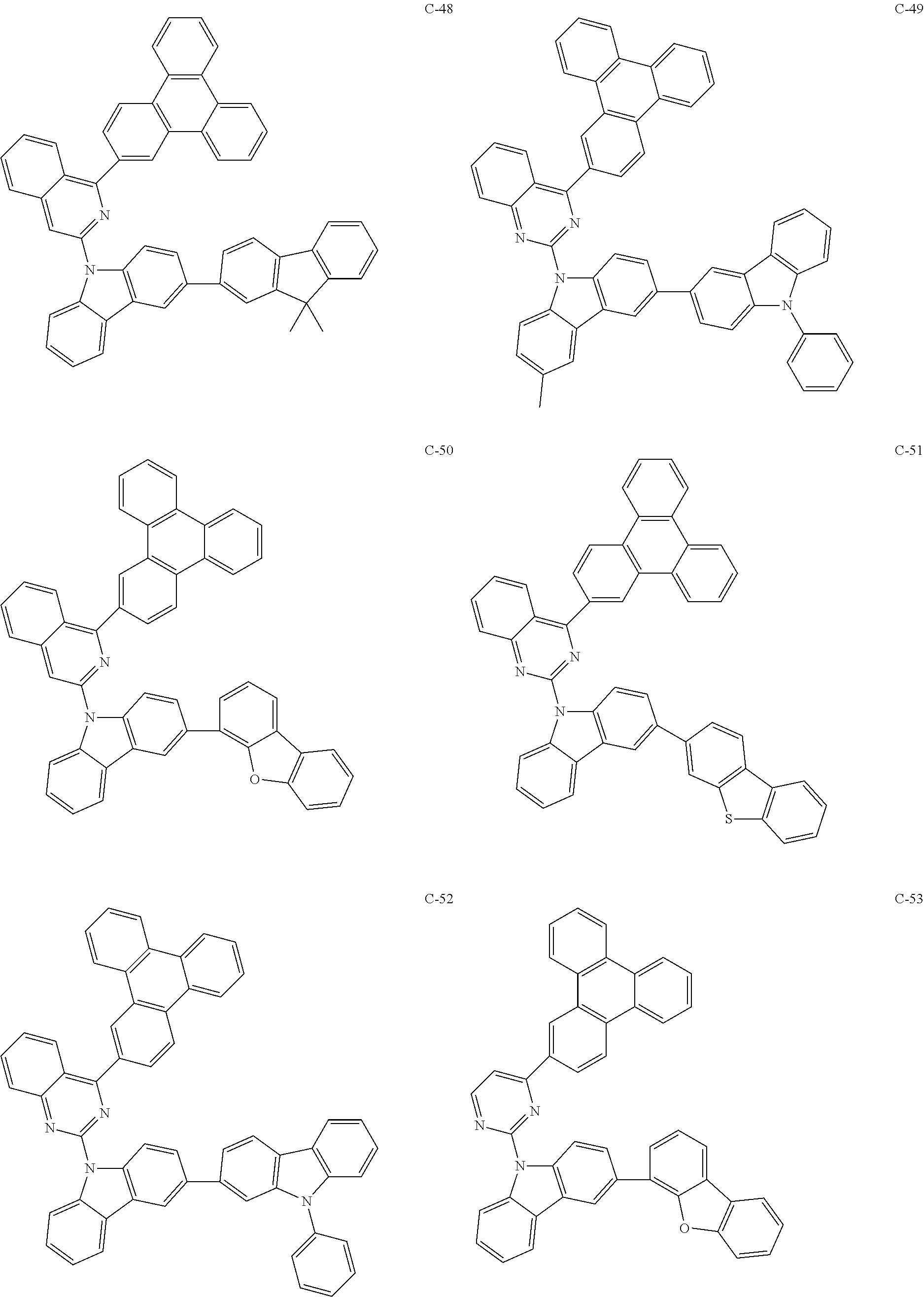

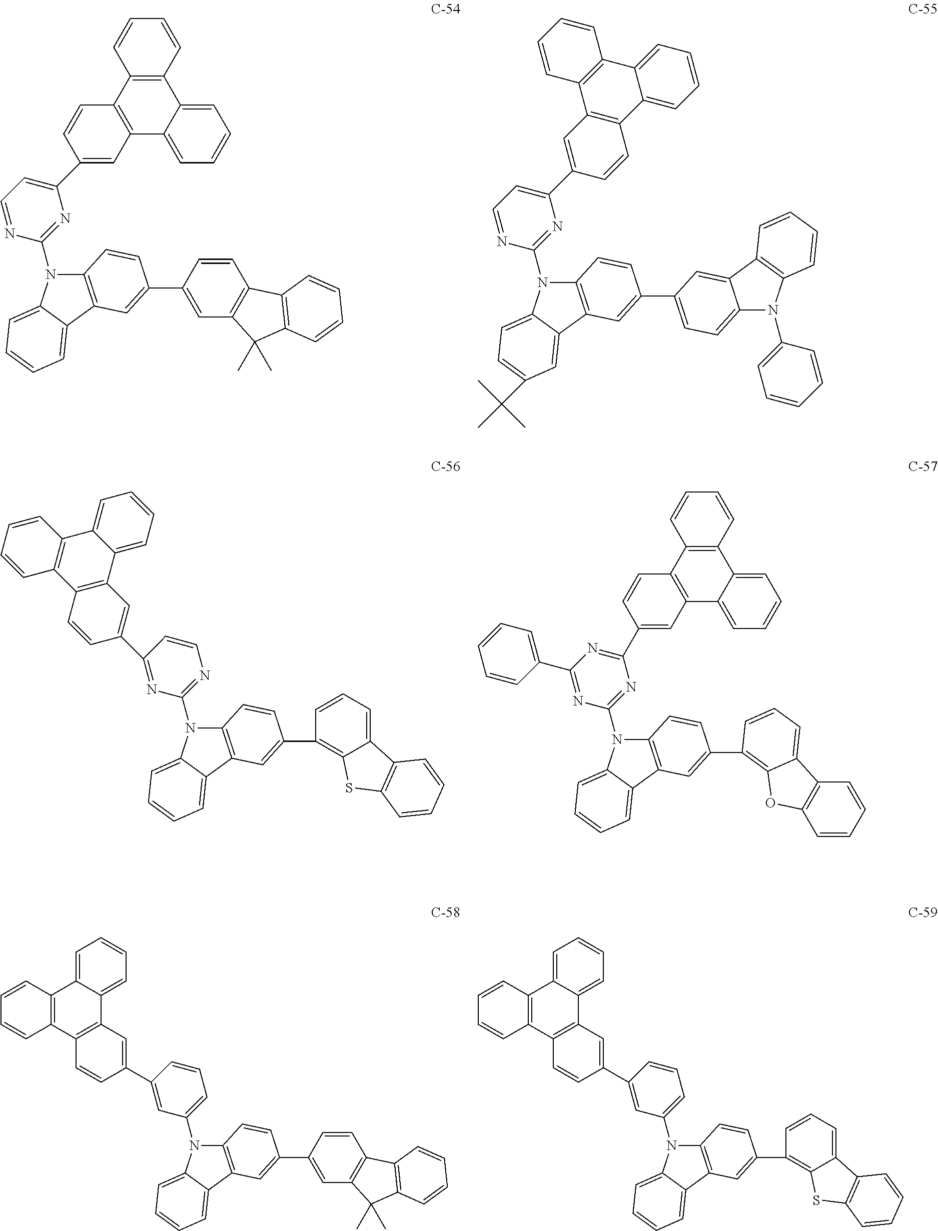

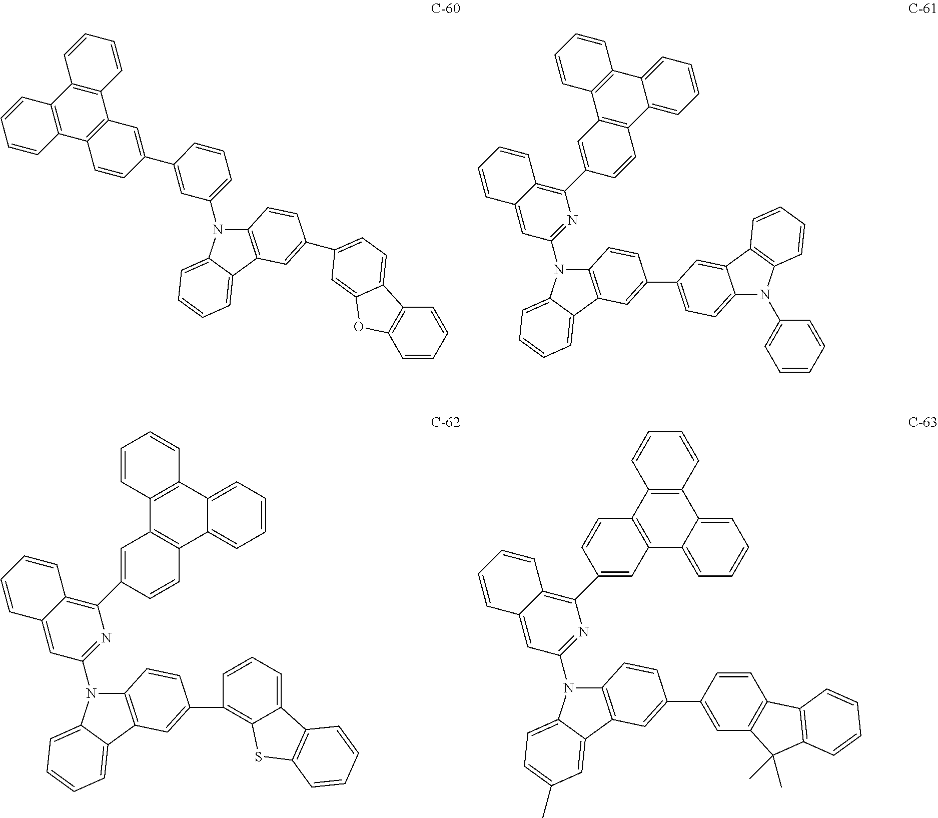 [SMILES: c1cc(-c2ccc3c4ccccc4c4ccccc4c3c2)cc(-n2c3ccccc3c3cc(-c4ccc5c(c4)oc4ccccc45)ccc32)c1 ; c1ccc(-n2c3ccccc3c3cc(-c4ccc5c(c4)c4ccccc4n5-c4cc5ccccc5c(-c5ccc6c7ccccc7c7ccccc7c6c5)n4)ccc32)cc1 ; c1ccc2c(-c3ccc4c5ccccc5c5ccccc5c4c3)nc(-n3c4ccccc4c4cc(-c5cccc6c5sc5ccccc56)ccc43)cc2c1 ; Cc1ccc2c(c1)c1cc(-c3ccc4c(c3)C(C)(C)c3ccccc3-4)ccc1n2-c1cc2ccccc2c(-c2ccc3c4ccccc4c4ccccc4c3c2)n1]

6. An organic electroluminescent device comprising the organic electroluminescent compound according to claim 1.
